(19) United States
(12) Patent Application Publication
(10) Pub. No.: US 2026/0032949 A1
(43) Pub. Date: Jan. 29, 2026

(54) SEMICONDUCTOR DEVICE AND MANUFACTURING METHOD FOR SEMICONDUCTOR DEVICE

(71) Applicant: ROHM CO., LTD., Kyoto-shi (JP)

(72) Inventors: Seigo MORI, Kyoto-shi (JP); Yuki NAKANO, Kyoto-shi (JP)

(73) Assignee: ROHM CO., LTD., Kyoto-shi (JP)

(21) Appl. No.: 19/342,952

(22) Filed: Sep. 29, 2025

Related U.S. Application Data
(63) Continuation of application No. PCT/JP2024/009793, filed on Mar. 13, 2024.

(30) Foreign Application Priority Data
Mar. 30, 2023 (JP) 2023-056616

(51) Int. Cl. H10D 30/66; H10D 30/01; H10D 62/10; H10D 62/832; H10D 64/66

(52) U.S. Cl. CPC H10D 30/66; H10D 30/0291; H10D 62/126; H10D 62/8325; H10D 64/663

(57) ABSTRACT

The semiconductor device includes a chip that includes SiC and has a main surface, a gate electrode that is arranged on the main surface, includes polysilicon, and has an electrode surface, a silicide portion that is partially formed in a surface portion of the electrode surface, and a polysilicon portion that is formed in a portion of the surface portion of the electrode surface other than the silicide portion.

### CROSS-REFERENCE TO RELATED APPLICATIONS

The present application is a bypass continuation of International Patent Application No. PCT/JP2024/009793 filed on Mar. 13, 2024, which claims priority to Japanese Patent Application No. 2023-056616 filed on Mar. 30, 2023 in the Japan Patent Office, and the entire contents of these applications are hereby incorporated herein by reference.

### BACKGROUND

### 1. Field of the Disclosure

The present disclosure relates to a semiconductor device and a manufacturing method for a semiconductor device.

### 2. Description of the Related Art

US2013/0234159A1 discloses a semiconductor device including a gate electrode. The gate electrode has a laminated structure including a semiconductor layer and a metal semiconductor compound layer (silicide).

### BRIEF DESCRIPTION OF DRAWINGS

FIG. 1 is a plan view illustrating a semiconductor device according to a specific embodiment.

FIG. 2 is a cross-sectional view taken along line II-II illustrated in FIG. 1.

FIG. 3 is a plan view illustrating a layout example of a first main surface.

FIG. 4 is an enlarged plan view showing a main portion of the first main surface.

FIG. 5 is an enlarged plan view illustrating another main portion of the first main surface.

FIG. 6 is a cross-sectional view taken along line VI-VI illustrated in FIG. 5.

FIG. 7 is an enlarged cross-sectional view illustrating a main portion of FIG. 6 together with a gate electrode according to a first example and a source pad electrode according to a first example.

FIG. 8 is a cross-sectional view taken along line VIII-VIII illustrated in FIG. 5.

FIG. 9 is an enlarged cross-sectional view illustrating a main portion of FIG. 8 together with a gate wiring according to the first example.

FIG. 10A is an enlarged cross-sectional view illustrating a gate electrode according to a second example.

FIG. 10B is an enlarged cross-sectional view illustrating a gate electrode according to a third example.

FIG. 10C is an enlarged cross-sectional view illustrating a gate electrode according to a fourth example.

FIG. 11A is an enlarged cross-sectional view illustrating a gate wiring according to a second example.

FIG. 11B is an enlarged cross-sectional view illustrating a gate wiring according to a third example.

FIG. 11C is an enlarged cross-sectional view illustrating a gate wiring according to a fourth example.

FIG. 12A is an enlarged cross-sectional view illustrating a source pad electrode according to a second example.

FIG. 12B is an enlarged cross-sectional view illustrating a source pad electrode according to a third example.

FIG. 12C is an enlarged cross-sectional view illustrating a source pad electrode according to a fourth example.

FIG. 12D is an enlarged cross-sectional view illustrating a source pad electrode according to a fifth example.

FIG. 13 is a schematic diagram illustrating a wafer.

FIGS. 14A to 14R are cross-sectional views illustrating a manufacturing method for the semiconductor device.

FIG. 15 is a cross-sectional view illustrating a first modification example of the semiconductor device.

FIG. 16 is a cross-sectional view illustrating a second modification example of the semiconductor device.

### DETAILED DESCRIPTION OF THE PREFERRED EMBODIMENTS

Hereinafter, specific embodiments will be described in detail with reference to attached drawings. The attached drawings are all schematic views and are not strictly illustrated, and relative positional relationships, scales, proportions, angles, etc., thereof do not always match. Identical reference signs are given to corresponding structures among the attached drawings, and duplicate descriptions thereof shall be omitted or simplified. For the structures, whose description has been omitted or simplified, the description given before the omission or simplification shall apply.

When the wording “substantially” is used in the present specification, the wording includes a numerical value (shape) equal to a numerical value (shape) of a comparison target and also includes numerical errors (shape errors) in a range of +10% with the numerical value (shape) of the comparison target as a reference. Although the wordings “first,” “second,” “third,” etc., arc used in the following description, these are indicators added to names of respective structures in order to clarify the order of description and are not added with an intention of restricting the names of the respective structures.

In the following description, a “p-type” or an “n-type” is used to indicate a conductivity type of a semiconductor (impurity). However, the “p-type” may be referred to as a “first conductivity type,” and the “n-type” may be referred to as a “second conductivity type.” As a matter of course, the “n-type” may be referred to as a “first conductivity type,” and the “p-type” may be referred to as a “second conductivity type.” The “p-type” is a conductivity type caused by a trivalent element, and the “n-type” is a conductivity type caused by a pentavalent element. The trivalent element is at least one of boron, aluminum, gallium, and indium. The pentavalent element is at least one of nitrogen, phosphorus, arsenic, antimony, and bismuth.

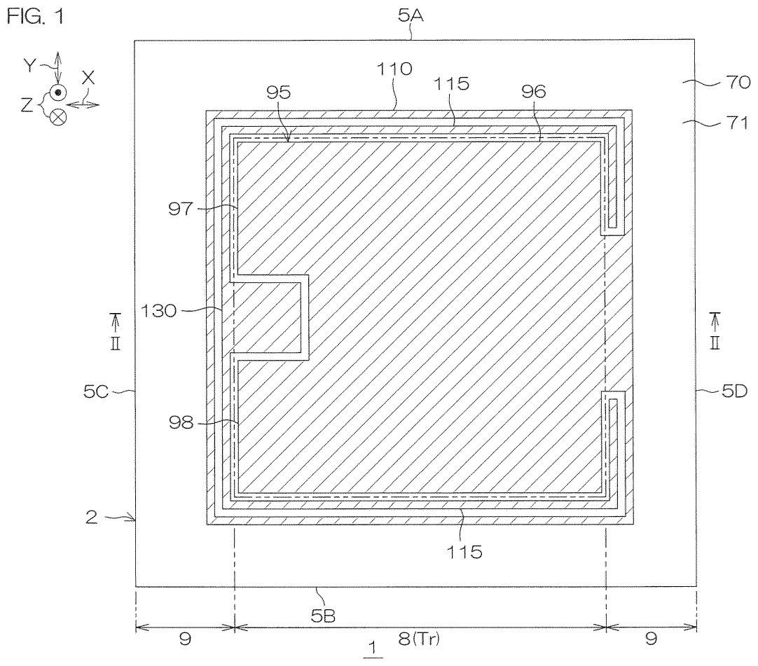

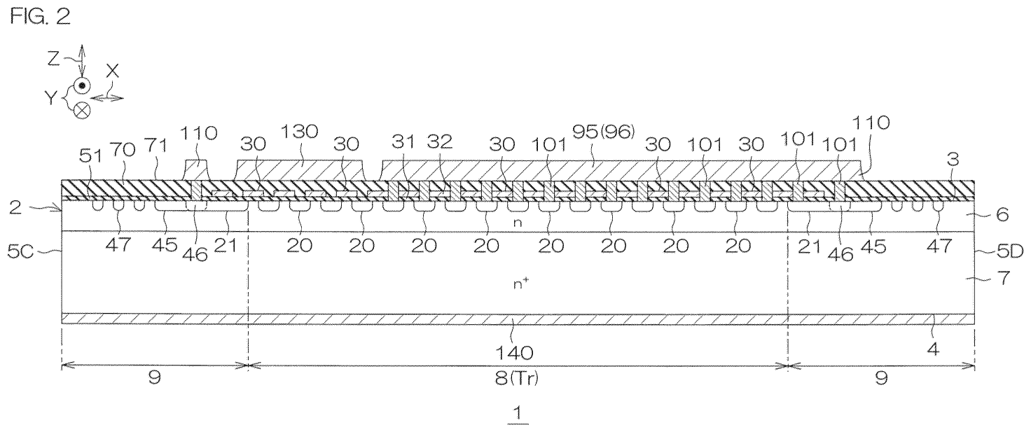

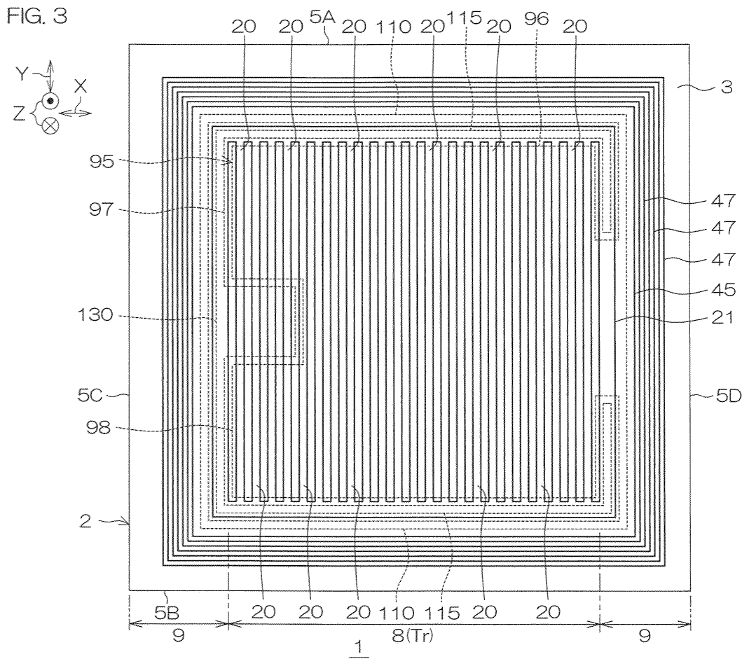

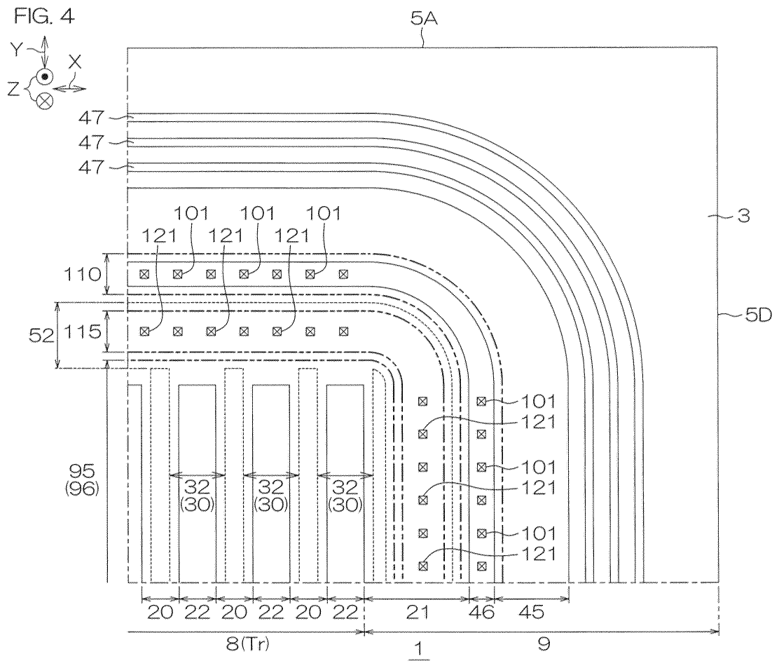

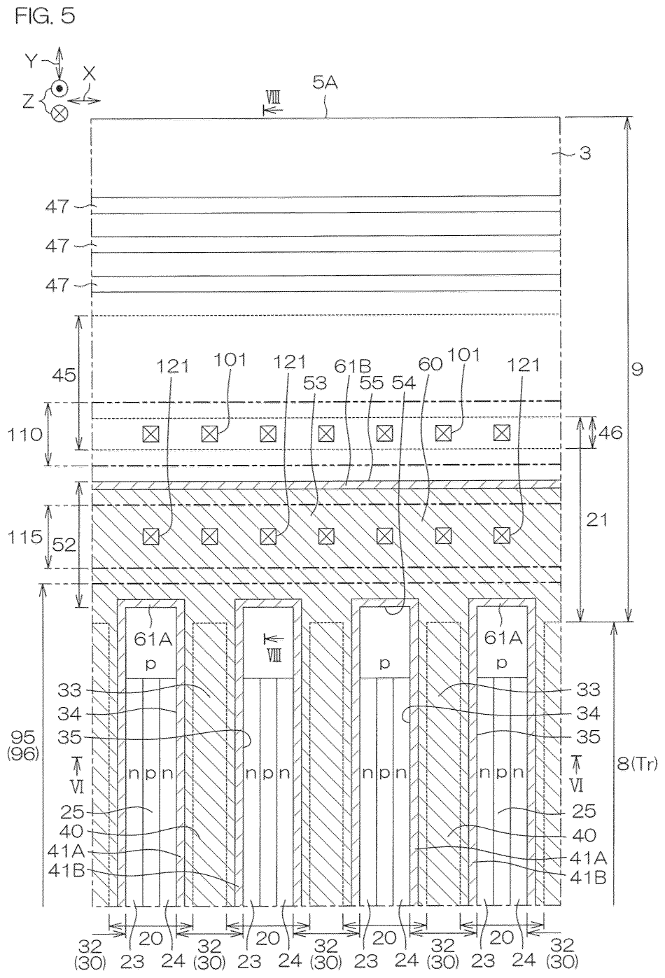

FIG. 1 is a plan view illustrating a semiconductor device 1 according to a specific embodiment. FIG. 2 is a cross-sectional view taken along line II-II illustrated in FIG. 1. FIG. 3 is a plan view illustrating a layout example of a first main surface 3. FIG. 4 is an enlarged plan view illustrating a main portion of the first main surface 3. FIG. 5 is an enlarged plan view illustrating another main portion of the first main surface 3.

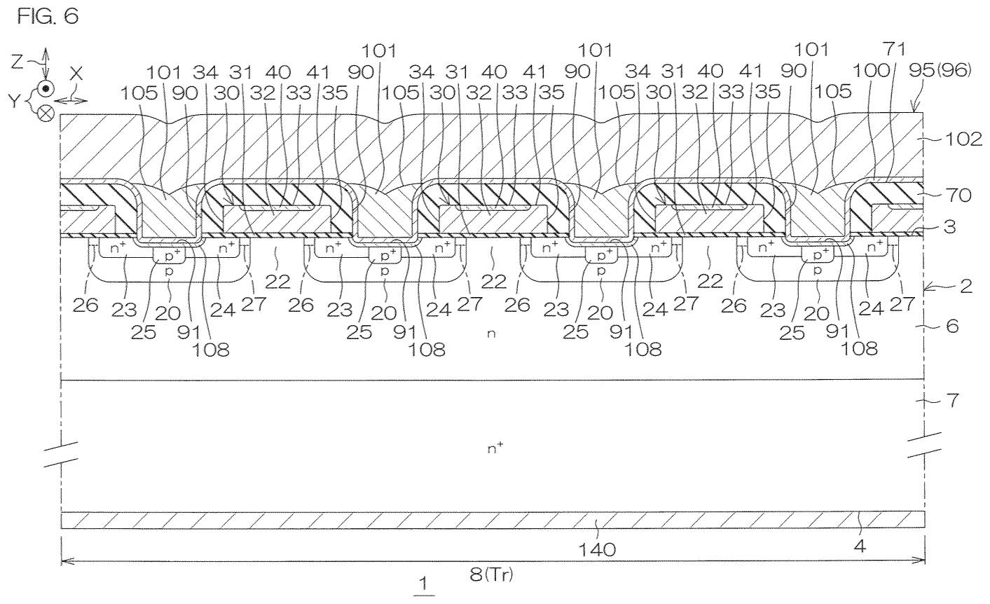

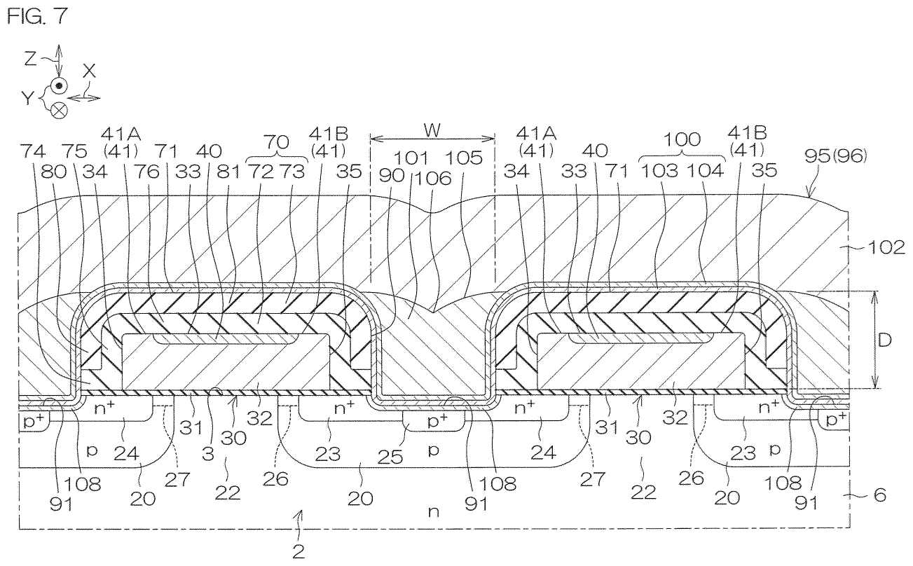

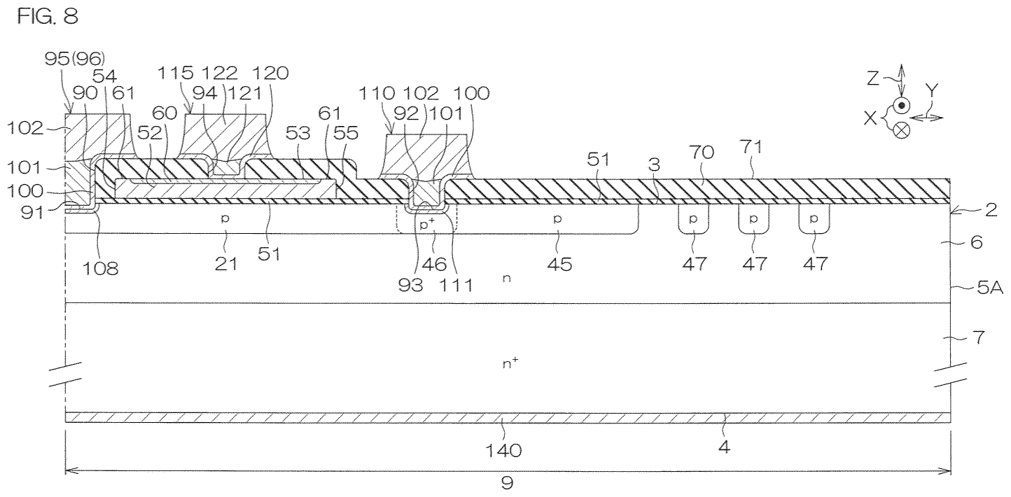

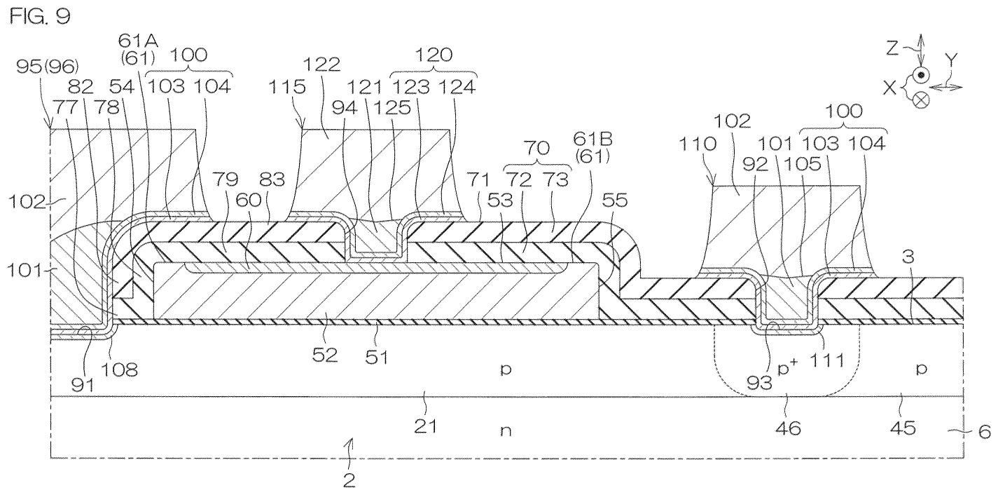

FIG. 6 is a cross-sectional view taken along line VI-VI illustrated in FIG. 5. FIG. 7 is an enlarged cross-sectional view illustrating a main portion of FIG. 6 together with a gate electrode 32 according to a first example and a source pad electrode 95 according to the first example. FIG. 8 is a cross-sectional view taken along line VIII-VIII illustrated in FIG. 5. FIG. 9 is an enlarged cross-sectional view illustrating a main portion of FIG. 8 together with a gate wiring 52 according to the first example.

Referring to FIG. 1 to FIG. 9, the semiconductor device 1 is a semiconductor switching device having an insulated-gate-type transistor structure Tr as an example of a device structure.

The transistor structure Tr has a vertical structure. The semiconductor device 1 is an SiC semiconductor device including a chip 2 made of an SiC single crystal. The chip 2 may be referred to as an “SiC chip” or as a “semiconductor chip.”

In this embodiment, the chip 2 is made of an SiC single crystal, which is a hexagonal crystal, and is formed in a rectangular parallelepiped shape. The hexagonal SiC single crystal includes a plurality of types of polytypes including 2 hexagonal (H)—SiC single crystal, 4H-SiC single crystal, 6H-SiC single crystal, etc. In this embodiment, an example in which the chip 2 is made of 4H-SiC single crystal is described, but the chip 2 may be made of another polytype.

The chip 2 has a first main surface 3 on one side, a second main surface 4 on the other side, and first to fourth side surfaces 5A to 5D connecting the first main surface 3 and the second main surface 4. In a plan view when viewed from a vertical direction Z (hereinafter, referred to simply as “plan view”), the first main surface 3 and the second main surface 4 are formed in quadrangle shapes. The vertical direction Z is also a thickness direction of the chip 2 and a normal direction to the first main surface 3 (the second main surface 4). The first main surface 3 and the second main surface 4 may be formed in a square shape or a rectangular shape in a plan view.

Preferably, the first main surface 3 and the second main surface 4 are formed by c-planes of the SiC single crystal. In this case, preferably, the first main surface 3 is formed by a silicon plane ((0001) plane) of the SiC single crystal, and the second main surface 4 is formed by a carbon plane ((000-1) plane) of the SiC single crystal.

The first side surface 5A and the second side surface 5B extend in a first direction X along the first main surface 3, and oppose each other in a second direction Y intersecting the first direction X along the first main surface 3. Specifically, the second direction Y is orthogonal to the first direction X. The third side surface 5C and the fourth side surface 5D extend in the second direction Y, and oppose each other in the first direction X.

In the following description, one side in the first direction X means the third side surface 5C side, and the other side in the first direction X means the fourth side surface 5D side. Also, one side in the second direction Y means the first side surface 5A side, and the other side in the second direction Y means the second side surface 5B side. In this embodiment, the first direction X is an m-axis direction ([1-100] direction) of the SiC single crystal, and the second direction Y is an a-axis direction ([11-20] direction) of the SiC single crystal. As a matter of course, the first direction X may be the a-axis direction of the SiC single crystal, and the second direction Y may be the m-axis direction of the SiC single crystal.

The chip 2 (the first main surface 3 and the second main surface 4) has an off angle by being inclined at a predetermined angle in a predetermined off direction with respect to the c-plane of the SiC single crystal. That is, a c-axis ((0001) axis) of the SiC single crystal is inclined by the off angle toward the off direction from the vertical axis. Also, the c-plane of the SiC single crystal is inclined by the off angle with respect to the horizontal plane.

Preferably, the off direction is the a-axis direction (that is, the second direction Y) of the SiC single crystal. The off angle may be larger than 0° and equal to or smaller than 10°. The off angle may have a value in at least one range among a range larger than 0° and equal to or smaller 1°, a range of 1° or larger and 2.5° or smaller, a range of 2.5° or larger and 5° or smaller, a range of 5° or larger and 7.5° or smaller, and a range of 7.5° or larger and 10° or smaller.

Preferably, the off angle is equal to or smaller than 5°. It is particularly preferable that the off angle is in a range of 2° or larger and 4.5° or smaller. The off angle is typically set in a range of 4°±0.1°. This description does not exclude an embodiment in which the off angle is 0° (that is, an embodiment in which the first main surface 3 is a just surface with respect to the c-plane).

The semiconductor device 1 includes an n-type first semiconductor region 6 that is formed in a region (surface layer portion) inside the chip 2 on the first main surface 3 side. The first semiconductor region 6 may be referred to as a “drift region,” a “drain drift region,” a “drain region,” or the like. A drain potential as a high potential (first potential) is to be applied to the first semiconductor region 6. The first semiconductor region 6 is formed in a layered shape extending along the first main surface 3, and is exposed from the first main surface 3 and the first to fourth side surfaces 5A to 5D. In this embodiment, the first semiconductor region 6 is made of an epitaxial layer (specifically, an SiC epitaxial layer).

The semiconductor device 1 includes an n-type second semiconductor region 7 that is formed in a region (surface layer portion) inside the chip 2 on the second main surface 4 side. The drain potential is to be applied to the second semiconductor region 7. The second semiconductor region 7 may be referred to as a “drain region” or the like. The second semiconductor region 7 has an n-type impurity concentration higher than that of the first semiconductor region 6, and is electrically connected to the first semiconductor region 6 inside the chip 2.

The second semiconductor region 7 is formed in a layered shape extending along the second main surface 4, and is exposed from the second main surface 4 and the first to fourth side surfaces 5A to 5D. In this embodiment, the second semiconductor region 7 is made of a semiconductor substrate (specifically, an SiC substrate). That is, the chip 2 has a laminated structure including the semiconductor substrate and the epitaxial layer. The second semiconductor region 7 has a thickness thicker than a thickness of the first semiconductor region 6.

The semiconductor device 1 includes an active region 8 that is set in the chip 2. The active region 8 is a region that has a device structure (transistor structure Tr) and in which an output current (drain current) is to be generated. The active region 8 is set in an inner portion of the chip 2 at an interval from a peripheral edge (the first to fourth side surfaces 5A to 5D) of the chip 2 in a plan view. The active region 8 is set in a polygonal shape (in this embodiment, a quadrangle shape) having four sides parallel to the peripheral edge of the chip 2 in a plan view. Preferably, a planar area of the active region 8 is equal to or larger than 50% and equal to or smaller than 90% of a planar area of the first main surface 3.

The semiconductor device 1 includes an outer peripheral region 9 that is set outside the active region 8 in the chip 2. The outer peripheral region 9 is provided in a region between the peripheral edge of the chip 2 and the active region 8 in a plan view. The outer peripheral region 9 extends in a band shape along the active region 8 and is set in a polygonal round shape (in this embodiment, a quadrangular round shape) that surrounds the active region 8 in a plan view.

The semiconductor device 1 includes a plurality of p-type body regions 20 that are formed in a surface layer portion of the first main surface 3 in the active region 8. A source potential as a low potential (second potential) different from the high potential (first potential) is to be applied to the body regions 20. The body regions 20 are arranged at an interval in the first direction X, and are respectively formed in a band shape extending in the second direction Y. That is, the body regions 20 are arranged in a stripe shape extending in the second direction Y.

The body regions 20 are formed at intervals from a bottom portion of the first semiconductor region 6 toward the first main surface 3 side, and oppose the second semiconductor region 7 across a portion of the first semiconductor region 6. Preferably, the body regions 20 are formed at intervals from an intermediate portion of the first semiconductor region 6 toward the first main surface 3 side. The body regions 20 are exposed from the first main surface 3.

Each of the body regions 20 may have a width of 1 μm or wider and 10 μm or narrower. The width of the body region 20 may have a value in at least one range among a range of 1 μm or wider and 2 μm or narrower, a range of 2 μm or wider and 3 μm or narrower, a range of 3 μm or wider and 4 μm or narrower, a range of 4 μm or wider and 5 μm or narrower, a range of 5 μm or wider and 6 μm or narrower, a range of 6 μm or wider and 7 μm or narrower, a range of 7 μm or wider and 8 μm or narrower, a range of 8 μm or wider and 9 μm or narrower, and a range of 9 μm or wider and 10 μm or narrower. Preferably, the width of the body region 20 is in a range of 2 μm or wider and 5 μm or narrower.

Each of the body regions 20 may have a thickness (depth) of 0.1 μm or thicker and 2.5 μm or thinner. The thickness of the body region 20 may have a value in at least one range among a range of 0.1 μm or thicker and 0.5 μm or thinner, a range of 0.5 μm or thicker and 1 μm or thinner, a range of 1 μm or thicker and 1.5 μm or thinner, a range of 1.5 μm or thicker and 2 μm or thinner, and a range of 2 μm or thicker and 2.5 μm or thinner. Preferably, the thickness of the body region is in a range of 0.5 μm or thicker and 1.5 μm or thinner.

The semiconductor device 1 includes a p-type outer body region 21 that is formed in the surface layer portion of the first main surface 3 in the outer peripheral region 9. Preferably, the outer body region 21 has a p-type impurity concentration substantially equal to the p-type impurity concentration of the body region 20. As a matter of course, the p-type impurity concentration of the outer body region 21 may be lower than the p-type impurity concentration of the body region 20, or may be higher than the p-type impurity concentration of the body region 20.

The outer body region 21 is formed at an interval from the peripheral edge (first to fourth side surfaces 5A to 5D) of the first main surface 3 toward the active region 8 side, and extends in a band shape along the active region 8. The outer body region 21 includes a portion extending in a band shape in the first direction X and a portion extending in a band shape in the second direction Y in a plan view, and defines the active region 8 from a directions.

In this embodiment, the outer body region 21 surrounds the active region 8 in a plan view, and is defined in a polygonal round shape (in this embodiment, a quadrangular round shape) having four sides parallel to the peripheral edge of the first main surface 3. That is, the outer body region 21 forms a boundary portion between the active region 8 and the outer peripheral region 9. The outer body region 21 may include an edge portion that connects the portion extending in the first direction X and the portion extending in the second direction Y in an arc shape (preferably, a quarter arc shape) in a plan view (refer to FIG. 4).

The outer body region 21 includes an inner edge portion on the active region 8 side and an outer edge portion on the peripheral edge side of the first main surface 3. The inner edge portion of the outer body region 21 is connected to the body regions 20 in a portion extending in the first direction X. Thereby, the outer body region 21 is electrically connected to the body regions 20.

Preferably, the outer body region 21 has a width wider than the width of the body region 20. The width of the body region 20 is a width in a direction orthogonal to the extending direction (that is, the first direction X). The width of the outer body region 21 is a width in a direction orthogonal to the extending direction. As a matter of course, the width of the outer body region 21 may be substantially equal to the width of the body region 20, or may be narrower than the thickness of the body region 20.

A ratio of the width of the outer body region 21 to the width of the body region 20 may be 1 or larger and 50 or smaller. The ratio of the width may have a value in at least one range among a range of 1 or larger and 10 or smaller, a range of 10 or larger and 20 or smaller, a range of 20 or larger and 30 or smaller, a range of 30 or larger and 40 or smaller, and a range of 40 or larger and 50 or smaller. Preferably, the ratio of the width is in a range of 10 or larger. Preferably, the ratio of the width is in a range of 20 or larger and 40 or smaller.

The outer body region 21 is formed at an interval from the bottom portion of the first semiconductor region 6 toward the first main surface 3 side, and opposes the second semiconductor region 7 across a portion of the first semiconductor region 6. Preferably, the outer body region 21 is formed at an interval from the intermediate portion of the first semiconductor region 6 toward the first main surface 3 side. The outer body region 21 is exposed from the first main surface 3.

Preferably, the outer body region 21 has a thickness (depth) substantially equal to the thickness (depth) of the body region 20. As a matter of course, the thickness of the outer body region 21 may be thinner than the thickness of the body region 20, or may be thicker than the thickness of the body region 20.

The semiconductor device 1 includes a plurality of n-type surface layer drift regions 22 formed in the surface layer portion of the first main surface 3. In this embodiment, each of the surface layer drift regions 22 includes a portion of the first semiconductor region 6. As a matter of course, the surface layer drift regions 22 may have an n-type impurity concentration higher than the n-type impurity concentration of the first semiconductor region 6, or may have an n-type impurity concentration lower than the n-type impurity concentration of the first semiconductor region 6.

The surface layer drift regions 22 are defined in regions between the of body regions 20 adjacent to each other in the first direction X. Specifically, the surface layer drift regions 22 are defined by the body regions 20 and the outer body region 21 in the surface layer portion of the first main surface 3.

The surface layer drift regions 22 are arranged at intervals in the first direction X, and are respectively formed in a band shape extending in the second direction Y. That is, the surface layer drift regions 22 are formed in a stripe shape extending in the second direction Y. The surface layer drift region 22 forms an n-type (pnp-type) JFET structure with the body regions 20 located on both sides.

The surface layer drift regions 22 may have a width of 0.1 μm or wider and 5 μm or narrower. The width of the surface layer drift region 22 may have a value in at least one range among a range of 0.1 μm or wider and 0.5 μm or narrower, a range of 0.5 μm or wider and 1 μm or narrower, a range of 1 μm or wider and 1.5 μm or narrower, a range of 1.5 μm or wider and 2 μm or narrower, a range of 2 μm or wider and 2.5 μm or narrower, a range of 2.5 μm or wider and 3 μm or narrower, a range of 3 μm or wider and 3.5 μm or narrower, a range of 3.5 μm or wider and 4 μm or narrower, a range of 4 μm or wider and 4.5 μm or narrower, and a range of 4.5 μm or wider and 5 μm or narrower.

The semiconductor device 1 includes a plurality of n-type source regions 23 and 24 that are respectively formed in the surface layer portions of the body regions 20. The source regions 23 and 24 have an n-type impurity concentration higher than the n-type impurity concentration of the first semiconductor region 6. The source potential is to be applied to the source regions 23 and 24.

The source regions 23 and 24 include first source regions 23 located on one side in the first direction X and second source regions 24 located on the other side in the first direction X in the surface layer portions of the body regions 20. In this embodiment, in the first direction X, one first source region 23 is formed on one end side of the body region 20, and one second source region 24 is formed on the other end side of the body region 20.

The first source region 23 is formed at an interval from one end of the body region 20 toward the other end side of the body region 20, and extend in a band shape along the extending direction of the body region 20. The first source region 23 is formed at an interval from the outer body region 21 in the second direction Y. That is, the first source region 23 is not formed in the outer body region 21. The first source region 23 is formed at an interval from a bottom portion of the body region 20 toward the first main surface 3 side, and opposes the first semiconductor region 6 across a portion of the body region 20.

The second source region 24 is formed at an interval from the first source region 23 toward the other end side of the body region 20. The second source region 24 is formed at an interval from the other end of the body region 20 toward one end side of the body region 20, and extend in a band shape along the extending direction of the body region 20. The second source region 24 is formed at an interval from the outer body region 21 in the second direction Y.

That is, the second source region 24 is not formed in the outer body region 21. The second source region 24 is formed at an interval from the bottom portion of the body region 20 toward the first main surface 3 side, and opposes the first semiconductor region 6 across a portion of the body region 20.

In a case where the first source regions 23 are formed in one body region 20, the first source regions 23 may be formed at intervals in the extending direction of the body region 20. In this case, each of the first source regions 23 may be formed in a band shape extending in the second direction Y. Similarly, in a case where the second source regions 24 are formed in one body region 20, the second source regions 24 may be formed at intervals in the extending direction of the body region 20. In this case, each of the second source regions 24 may be formed in a band shape extending in the second direction Y.

The semiconductor device 1 includes a plurality of p-type contact regions 25 that are respectively formed in the surface layer portions of the body regions 20 in the active region 8. The contact region 25 may be referred to as a “back gate region.” The source potential is to be applied to the contact regions 25. The contact region 25 has a p-type impurity concentration higher than the p-type impurity concentration of the body region 20.

In this embodiment, one contact region 25 is interposed in a region between the first source region 23 and the second source region 24 in the surface layer portion of the corresponding body region 20. The contact region 25 extends in a band shape along the extending direction of the body region 20 (the source regions 23 and 24).

The contact region 25 is formed at an interval from the outer body region 21 in the second direction Y. That is, the contact region 25 is not formed in the outer body region 21. The contact region 25 is formed at an interval from the bottom portion of the body region 20 toward the first main surface 3 side, and opposes the first semiconductor region 6 across a portion of the body region 20.

In a case where the contact regions 25 are formed in one body region 20, the contact regions may be formed at intervals in the extending direction of the body region 20. In this case, each of the contact regions 25 may be formed in a band shape extending in the second direction Y.

The semiconductor device 1 includes a plurality of p-type channel regions 26 and 27 that are formed in the surface layer portion of the first main surface 3. The channel regions 26 and 27 are respectively defined in the surface layer portions of the body regions 20 in regions between end portions of the body regions 20 (the surface layer drift regions 22) and peripheral edges of the source regions 23 and 24.

In this embodiment, the channel regions 26 and 27 are arranged at an interval in the first direction X, and are respectively formed in a band shape extending in the second direction Y. That is, the channel regions 26 and 27 are arranged in a stripe shape extending in the second direction Y.

The channel regions 26 and 27 include a plurality of first channel regions 26 and a plurality of second channel regions 27. The first channel regions 26 are respectively defined in regions between the one ends (surface layer drift regions 22) of the body regions 20 and the first source regions 23, and form a current path extending in the horizontal direction. The second channel regions 27 are respectively defined in regions between the other ends (surface layer drift regions 22) of the body regions 20 and the second source regions 24, and form a current path extending in the horizontal direction.

The semiconductor device 1 includes a plurality of gate structures 30 of a planar-electrode-type that are arranged on the first main surface 3 in the active region 8. The gate structures 30 are arranged at intervals in the first direction X, and are respectively formed in a band shape extending in the second direction Y. That is, the gate structures 30 are arranged in a stripe shape extending in the second direction Y. The extending direction of the gate structures 30 coincides with the off direction of the SiC single crystal.

Each of the gate structures 30 is arranged on at least one channel region 26 and 27. In this embodiment, each of the gate structures 30 is arranged across one surface layer drift region 22 such that the gate structure 30 straddles two adjacent body regions 20, and covers the channel regions 26 and 27.

Specifically, each of the gate structures 30 is arranged to straddle the first source region 23 on one body region 20 side and the second source region 24 on the other body region 20 side, and covers the surface layer drift region 22, the first source region 23, the second source region 24, the first channel region 26, and the second channel region 27.

Hereinafter, a configuration of one gate structure 30 will be described. The gate structure has a laminated structure including an insulating film 31 and a gate electrode 32. The gate structure 30 does not have a side wall structure (spacer) made of an insulator (for example, silicon oxide and/or silicon nitride) on the gate electrode 32 side. That is, the gate structure 30 has a configuration that allows a narrow pitch arrangement.

The insulating film 31 may include at least one among a silicon oxide film, a silicon nitride film, and a silicon oxynitride film. In this embodiment, the insulating film 31 has a single layer structure including a silicon oxide film. It is particularly preferable that the insulating film 31 includes a silicon oxide film made of an oxide of the chip 2.

The insulating film 31 covers the first main surface 3 in a film shape, and is arranged on at least one channel region 26 and 27. In this embodiment, the insulating film 31 is arranged across one surface layer drift region 22 such that the insulating film 31 straddles two adjacent body regions 20, and covers the channel regions 26 and 27.

Specifically, the insulating film 31 is arranged to straddle the first source region 23 on one body region 20 side and the second source region 24 on the other body region 20 side, and covers the surface layer drift region 22, the first source region 23, the second source region 24, the first channel region 26, and the second channel region 27.

The insulating film 31 partially covers the first source region 23 at an interval from the contact region 25, and exposes a portion of the first source region 23 and the contact region 25 from the first main surface 3. The insulating film 31 partially covers the second source region 24 at an interval from the contact region 25, and exposes a portion of the second source region 24 and the contact region 25 from the first main surface 3.

The insulating film 31 may have a thickness in a range of 10 nm or thicker and 150 nm or thinner. The thickness of the insulating film 31 may have a value in at least one range among a range of 10 nm or thicker and 25 nm or thinner, a range of 25 nm or thicker and 50 nm or thinner, a range of 50 nm or thicker and 75 nm or thinner, a range of 75 nm or thicker and 100 nm or thinner, a range of 100 nm or thicker and 125 nm or thinner, and a range of 125 nm or thicker and 150 nm or thinner. Preferably, the thickness of the insulating film 31 is in a range of 25 nm or thicker and 75 nm or thinner.

The gate electrode 32 is arranged on the insulating film 31, and opposes at least one channel region 26 and 27 across the insulating film 31. A gate potential as a control potential is to be applied to the gate electrode 32. The gate electrode 32 controls inversion and non-inversion of at least one channel region 26 and 27 in response to the gate potential.

The gate electrode 32 includes a semiconductor polycrystal having conductivity. The gate electrode 32 may include either one or both of p-type conductive polysilicon and n-type conductive polysilicon. The conductivity type of the gate electrode 32 is adjusted according to a gate threshold voltage to be achieved. The gate electrode 32 may be referred to as a “polysilicon gate,” a “poly gate,” or the like.

The gate electrode 32 is formed in a band shape extending in the second direction Y. That is, the extending direction of the gate electrode 32 coincides with the off direction of the SiC single crystal. In this embodiment, the gate electrode 32 is formed at intervals inwardly from both end portions of the insulating film 31 in the first direction X, and exposes the both end portions of the insulating film 31. The gate electrode 32 is arranged on the insulating film 31 such that the gate electrode 32 straddles two adjacent body regions 20 across one surface layer drift region 22, and opposes the channel regions 26 and 27 across the insulating film 31.

Specifically, the gate electrode 32 is arranged to straddle the first source region 23 on one body region 20 side and the second source region 24 on the other body region 20 side, and opposes the surface layer drift region 22, the first source region 23, the second source region 24, the first channel region 26, and the second channel region 27 across the insulating film 31.

The gate electrode 32 has an electrode surface 33, a first side wall 34 on one side in the first direction X, and a second side wall 35 on the other side in the first direction X. The electrode surface 33 extends along the insulating film 31 (first main surface 3). The electrode surface 33 may extend to be substantially parallel to the insulating film 31 (first main surface 3).

The first side wall 34 is formed at an interval from one end portion of the insulating film 31 toward the other end portion side of the insulating film 31 in the first direction X, and extends in the vertical direction Z. The second side wall 35 is formed at an interval from the other end portion of the insulating film 31 toward one end portion side of the insulating film 31 in the first direction X, and extends in the vertical direction Z.

The first side wall 34 and the second side wall 35 may extend to be perpendicular to the insulating film 31. That is, the gate electrode 32 may be formed in a quadrangular shape (flat rectangular shape) in a cross-sectional view. The first side wall 34 and the second side wall 35 may be inclined obliquely toward the electrode surface 33. That is, the gate electrode 32 may be formed in a tapered shape (preferably, an isosceles trapezoidal shape) in a cross-sectional view.

The gate electrode 32 may have a width in a range of 1 μm or wider and 10 μm or narrower. The width of the gate electrode 32 is a width in a direction orthogonal to the extending direction (that is, the first direction X). The width of the gate electrode 32 may have a value in at least one range among a range of 1 μm or wider and 2.5 μm or narrower, a range of 2.5 μm or wider and 5 μm or narrower, a range of 5 μm or wider and 7.5 μm or narrower, and a range of 7.5 μm or wider and 10 μm or narrower. Preferably, the width of the gate electrode 32 is in a range of 1 μm or wider and 5 μm or narrower.

The gate electrode 32 may have a thickness in a range of 0.1 μm or thicker and 2 μm or thinner. The thickness of the gate electrode 32 may have a value in at least one range among a range of 0.1 μm or thicker and 0.5 μm or thinner, a range of 0.5 μm or thicker and 1 μm or thinner, a range of 1 μm or thicker and 1.5 μm or thinner, and a range of 1.5 μm or thicker and 2 μm or thinner. Preferably, the thickness of the gate electrode 32 is in a range of 0.2 μm or thicker and 1 μm or thinner.

Referring to FIG. 6 and FIG. 7, the gate structure 30 includes a first silicide portion 40 that is partially formed in a surface portion of the electrode surface 33 of each gate electrode 32. That is, each gate electrode 32 includes the first silicide portion 40 that is formed in a surface portion of the electrode surface 33. The first silicide portion 40 is a polycide portion obtained by performing silicide processing on the polysilicon of the gate electrode 32. The first silicide portion may be referred to as a “first metal semiconductor compound layer,” a “first silicide layer (polycide layer),” a “first silicide region (polycide region),” or the like.

The first silicide portion 40 may include at least one among Ti silicide, Ni silicide, Co silicide, Mo silicide, and W silicide. Preferably, the first silicide portion 40 is made of Ti silicide, Ni silicide, or Co silicide. Hereinafter, a configuration (layout) of the first silicide portion 40 in one gate electrode 32 will be described.

The first silicide portion 40 is formed at an interval inwardly from at least one of the first side wall 34 and the second side wall 35 of the gate electrode 32, and exposes at least one of a peripheral edge portion of the electrode surface 33 on the first side wall 34 side and a peripheral edge portion of the electrode surface 33 on the second side wall 35 side. In this embodiment, the first silicide portion 40 is formed at intervals inwardly from both of the first side wall 34 and the second side wall 35, and exposes both of the peripheral edge portion of the electrode surface 33 on the first side wall 34 side and the peripheral edge portion of the electrode surface 33 on the second side wall 35 side.

That is, the first silicide portion 40 is not exposed from both of the first side wall 34 and the second side wall 35. The first silicide portion 40 is formed at intervals inwardly from both of the first side wall 34 and the second side wall 35 in the entire surface portion of the electrode surface 33 in a plan view. In this embodiment, the first silicide portion 40 has a flat surface with respect to the electrode surface 33.

The first silicide portion 40 is formed at an interval from the insulating film 31 toward the electrode surface 33 side in the thickness direction, and opposes the insulating film 31 across a portion of the gate electrode 32 (polysilicon). Preferably, the first silicide portion 40 is formed at an interval from an intermediate portion of the gate electrode 32 toward the electrode surface 33 side in the thickness direction. As a matter of course, in a case where the gate electrode 32 has a relatively thin thickness, the first silicide portion 40 may have a bottom portion located on the insulating film 31 side with respect to the intermediate portion of the gate electrode 32.

The first silicide portion 40 is formed in a band shape extending along the gate electrode 32 in a plan view. That is, the extending direction of the first silicide portion 40 coincides with the off direction of the SiC single crystal. The first silicide portion 40 opposes one surface layer drift region 22 in a lamination direction. The first silicide portion 40 may be formed at an interval from two adjacent body regions 20 toward the surface layer drift region 22 side in a plan view, and may oppose only one surface layer drift region 22 in the lamination direction.

The first silicide portion 40 may be arranged across one surface layer drift region 22 in a plan view such that the first silicide portion 40 straddles two adjacent body regions 20. In this case, the first silicide portion 40 may be formed at intervals from the first source region 23 on one body region 20 side and the second source region 24 on the other body region 20 side toward the surface layer drift region 22 side, and may oppose the surface layer drift region 22, the first channel region 26, and the second channel region 27 in the lamination direction.

In this embodiment, the first silicide portion 40 is formed to straddle the first source region 23 on one body region 20 side and the second source region 24 on the other body region 20 side, and opposes the surface layer drift region 22, the first source region 23, the second source region 24, the first channel region 26, and the second channel region 27 in the lamination direction.

In view of responsiveness of the switching speed, preferably, the first silicide portion 40 opposes one or both (preferably, both) of the first channel region 26 and the second channel region 27. Preferably, the first silicide portion 40 opposes the entire region of the first channel region 26 in the lamination direction in a cross-sectional view. Preferably, the first silicide portion 40 opposes the entire region of the second channel region 27 in the lamination direction in a cross-sectional view.

The first silicide portion 40 may be formed at an interval of 0.1 μm or wider and 2.5 μm or narrower inwardly from the first side wall 34 (second side wall 35). The interval of the first silicide portion 40 may have a value in at least one range among a range of 0.1 μm or wider and 0.25 μm or narrower, a range of 0.25 μm or wider and 0.5 μm or narrower, a range of 0.5 μm or wider and 0.75 μm or narrower, a range of 0.75 μm or wider and 1 μm or narrower, a range of 1 μm or wider and 1.25 μm or narrower, a range of 1.25 μm or wider and 1.5 μm or narrower, a range of 1.5 μm or wider and 1.75 μm or narrower, a range of 1.75 μm or wider and 2 μm or narrower, a range of 2 μm or wider and 2.25 μm or narrower, and a range of 2.25 μm or wider and 2.5 μm or narrower. Preferably, the interval of the first silicide portion 40 is in a range of 0.2 μm or wider and 1 μm or narrower. It is particularly preferable that the interval of the first silicide portion 40 is in a range of 0.5 μm or narrower.

The gate structure 30 includes first polysilicon portion 41 that is formed in a portion other than the first silicide portion 40 in the electrode surface 33 of each gate electrode 32. That is, each gate electrode 32 includes the first silicide portion 40 and the first polysilicon portion 41 that is formed in the surface portion of the electrode surface 33. The first polysilicon portion 41 may be referred to as a “first polysilicon layer,” a “first polysilicon region,” or the like. Hereinafter, a configuration (layout) of the first polysilicon portion 41 in one gate electrode 32 will be described.

The first polysilicon portion 41 adopts various layouts according to the layout of the first silicide portion 40. In a case where the first silicide portion 40 is formed at an interval inwardly from at least one of the first side wall 34 and the second side wall 35 of the gate electrode 32, the first polysilicon portion 41 is formed in a region on at least one side of the first side wall 34 and the second side wall 35 in the electrode surface 33.

In this embodiment, the first silicide portion 40 is formed at intervals inwardly from both of the first side wall 34 and the second side wall 35 of the gate electrode 32. Therefore, the first polysilicon portion 41 include a first polysilicon portion 41A on one side that is defined in a region on the first side wall 34 side with respect to the first silicide portion 40 and a first polysilicon portion 41B on the other side that is defined in a region on the second side wall 35 side with respect to the first silicide portion 40 (refer to FIG. 5 and FIG. 7).

The first polysilicon portion 41A on one side forms the first side wall 34 of the gate electrode 32 in addition to the peripheral edge portion on one side of the electrode surface 33. The first polysilicon portion 41A on one side extends in a band shape in the second direction Y along the first silicide portion 40. The first polysilicon portion 41A on one side forms the first side wall 34 in the entire region of the gate electrode 32 in a plan view.

The first polysilicon portion 41A on one side opposes the first source region 23 in the lamination direction. The first polysilicon portion 41A on one side may oppose only the first source region 23 in the lamination direction. The first polysilicon portion 41A on one side may oppose the first source region 23 and the first channel region 26 in the lamination direction. The one first polysilicon portion 41A on one side may oppose the surface layer drift region 22, the first source region 23, and the first channel region 26 in the lamination direction.

In view of responsiveness of the switching speed, preferably, the first polysilicon portion 41A on one side is formed at an interval from the first channel region 26 toward the first side wall 34 side in a plan view. That is, preferably, the first polysilicon portion 41A on one side does not oppose the first channel region 26 in the lamination direction in a cross-sectional view.

The first polysilicon portion 41B on the other side forms the second side wall 35 of the gate electrode 32 in addition to the peripheral edge portion on the other side of the electrode surface 33. The first polysilicon portion 41B on the other side opposes the first polysilicon portion 41A on one side in the first direction X across the first silicide portion 40, and extends in a band shape in the second direction Y along the first silicide portion 40. That is, the first polysilicon portion 41B on the other side extends substantially parallel to the first polysilicon portion 41A on one side. The first polysilicon portion 41B on the other side forms the second side wall 35 in the entire region of the gate electrode 32 in a plan view.

The first polysilicon portion 41B on the other side opposes the second source region 24 in the lamination direction. The first polysilicon portion 41B on the other side may oppose only the second source region 24 in the lamination direction. The first polysilicon portion 41B on the other side may oppose the second source region 24 and the second channel region 27 in the lamination direction. The one first polysilicon portion 41B on the other side may oppose the surface layer drift region 22, the second source region 24, and the second channel region 27 in the lamination direction.

In view of responsiveness of the switching speed, preferably, the first polysilicon portion 41B on the other side is formed at an interval from the second channel region 27 toward the second side wall 35 side in a plan view. That is, preferably, the first polysilicon portion 41B on the other side does not oppose the second channel region 27 in the lamination direction in a cross-sectional view.

In this embodiment, the first polysilicon portion 41 has a flat surface with respect to the electrode surface 33. That is, the first polysilicon portion 41 forms the flat electrode surface 33 together with the first silicide portion 40. A width of the first polysilicon portion 41 corresponds to the interval of the first silicide portion 40 described above.

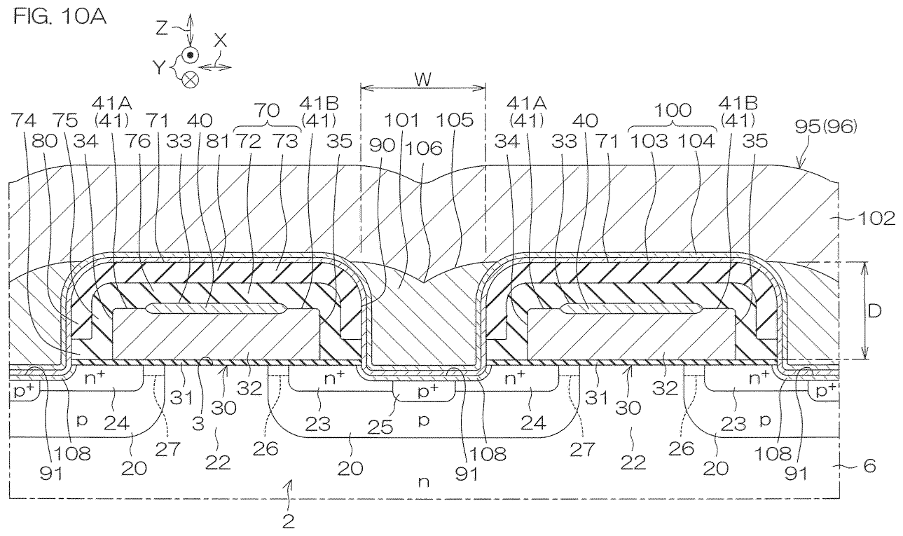

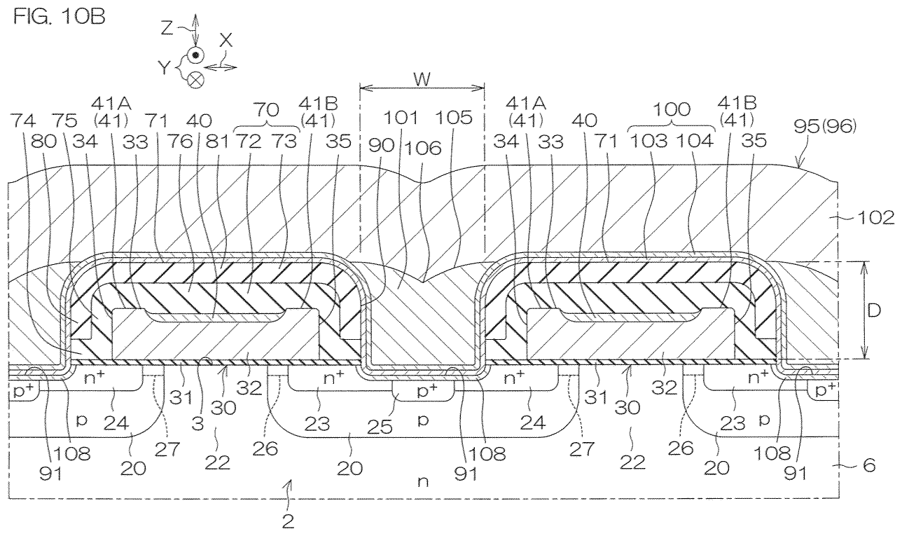

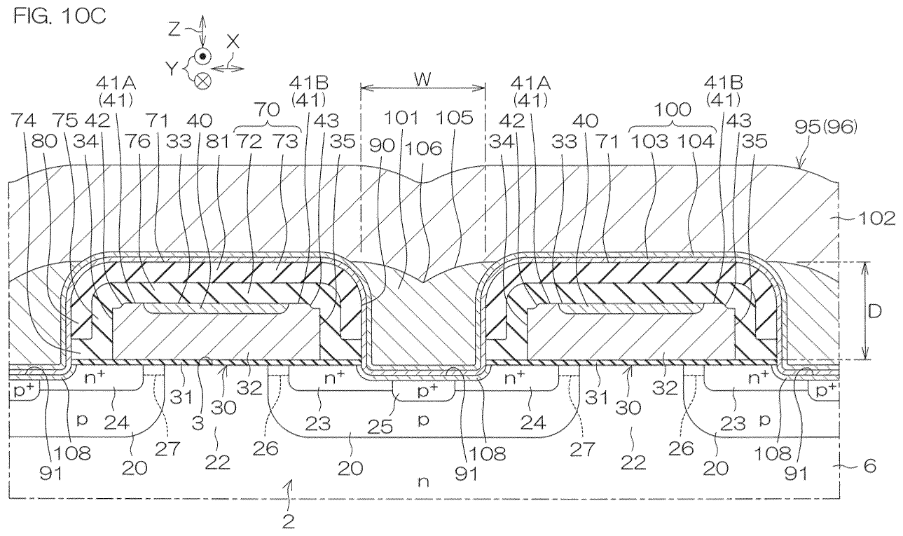

The gate electrode 32 (the first silicide portion 40 and the first polysilicon portion 41) may have a layout illustrated in FIG. 10A to FIG. 10C. FIG. 10A to FIG. 10C are enlarged cross-sectional views illustrating the gate electrode 32 according to a second example, a third example, and a fourth example.

The gate electrode 32 does not necessarily include any one of the configurations of the first to fourth examples (FIG. 7, and FIG. 10A to FIG. 10C). The gate electrode 32 may simultaneously include at least two features of the configurations of the first to fourth examples. Each of the gate electrodes 32 according to the first to fourth examples is obtained by adjusting process conditions in a producing process.

Referring to FIG. 10A (second example), the first silicide portion 40 may include a portion that protrudes upwardly from the electrode surface 33 (opposite to the first main surface 3). The first silicide portion 40 may protrude upwardly in the entire region of the electrode surface 33. The first polysilicon portion 41 may include a portion that is located on the first main surface 3 (the insulating film 31) side with respect to an upper end of the first silicide portion 40. The first polysilicon portion 41 may be located on the first main surface 3 (the insulating film 31) side with respect to the upper end of the first silicide portion 40 in the entire region of the electrode surface 33.

Referring to FIG. 10B (third example), the first silicide portion 40 may include a portion that is recessed toward the first main surface 3 (insulating film 31) side from the electrode surface 33. The first silicide portion 40 may be recessed toward the first main surface 3 (insulating film 31) side from the electrode surface 33 in the entire region of the electrode surface 33. The first polysilicon portion 41 may include a portion that protrudes upwardly (opposite to the first main surface 3) from the first silicide portion 40. The first polysilicon portion 41 may protrude upwardly from the first silicide portion 40 in the entire region of the electrode surface 33.

Referring to FIG. 10C (fourth example), the gate electrode 32 may include at least one (in this embodiment, both) of a first electrode recess 42 and a second electrode recess 43. FIG. 10C illustrates an example in which the first electrode recess 42 and the second electrode recess 43 are applied to the gate electrode 32 (refer to FIG. 7) according to the first example. On the other hand, one or both of the first electrode recess 42 and the second electrode recess 43 may be applied to the gate electrode 32 (refer to FIG. 10A) according to the second example or the gate electrode 32 (refer to FIG. 10B) according to the third example.

The first electrode recess 42 is recessed toward the first main surface 3 (insulating film 31) side at a corner portion connecting the electrode surface 33 and the first side wall 34. The first electrode recess 42 is formed in a band shape extending along the gate electrode 32 (first side wall 34). Preferably, a bottom portion of the first electrode recess 42 is formed at an interval from the intermediate portion of the gate electrode 32 toward the electrode surface 33 side. In a case where the gate electrode 32 has a relatively thin thickness, the bottom portion of the first electrode recess 42 may have a bottom portion located on the insulating film 31 side with respect to the intermediate portion of the gate electrode 32.

The second electrode recess 43 is recessed toward the first main surface 3 (insulating film 31) side at a corner portion connecting the electrode surface 33 and the second side wall 35. The second electrode recess 43 is formed in a band shape extending along the gate electrode 32 (second side wall 35). Preferably, a bottom portion of the second electrode recess 43 is formed at an interval from the intermediate portion of the gate electrode 32 toward the electrode surface 33 side.

In a case where the gate electrode 32 has a relatively thin thickness, the bottom portion of the second electrode recess 43 may have a bottom portion located on the insulating film 31 side with respect to the intermediate portion of the gate electrode 32. Preferably, a depth of the second electrode recess 43 is substantially equal to a depth of the first electrode recess 42.

The first silicide portion 40 is formed in the surface portion of the electrode surface 33 at an interval inwardly from the first electrode recess 42 and the second electrode recess 43, and exposes both of the first electrode recess 42 and the second electrode recess 43. A bottom portion of the first silicide portion 40 may be located on the electrode surface 33 side with respect to a depth position of a bottom portion of the first electrode recess 42 (second electrode recess 43). The bottom portion of the first silicide portion 40 may be located on the first main surface 3 (insulating film 31) side with respect to a depth position of the bottom portion of the first electrode recess 42 (second electrode recess 43).

Preferably, a distance between the first silicide portion 40 and the first electrode recess 42 (second electrode recess 43) is longer than a width of the first electrode recess 42 (second electrode recess 43). As a matter of course, the distance between the first silicide portion 40 and the first electrode recess 42 (second electrode recess 43) may be shorter than the width of the first electrode recess 42 (second electrode recess 43).

The first polysilicon portion 41A on one side includes a portion that is exposed from the first electrode recess 42. In this embodiment, the first polysilicon portion 41A on one side is formed in the entire region of the first electrode recess 42. The first polysilicon portion 41A on one side includes a portion that is located in a region between the first silicide portion 40 and the first electrode recess 42.

The first polysilicon portion 41B on the other side includes a portion that is exposed from the second electrode recess 43. In this embodiment, the first polysilicon portion 41B on the other side is formed in the entire region of the second electrode recess 43. The first polysilicon portion 41B on the other side includes a portion that is located in a region between the first silicide portion and the second electrode recess 43.

The gate electrode 32 does not necessarily include both of the first electrode recess 42 and the second electrode recess 43 at the same time. For example, the gate electrode 32 may include only the first electrode recess 42, and may not include the second electrode recess 43. For example, the gate electrode 32 may include only the second electrode recess 43 and may not include the first electrode recess 42.

Referring to FIG. 4, FIG. 5, and FIG. 8, the semiconductor device 1 includes a p-type terminal region 45 that is formed in the first main surface 3 in the outer peripheral region 9. The terminal region 45 may be referred to as a “well region,” a “terminal well region,” or the like.

The terminal region 45 may have a p-type impurity concentration different from the p-type impurity concentration of the body region 20. The p-type impurity concentration of the terminal region 45 may be higher than the p-type impurity concentration of the body region 20. The p-type impurity concentration of the terminal region 45 may be lower than the p-type impurity concentration of the body region 20. As a matter of course, the p-type impurity concentration of the terminal region 45 may be substantially equal to the p-type impurity concentration of the body region 20.

The terminal region 45 may have a p-type impurity concentration different from the p-type impurity concentration of the outer body region 20. The p-type impurity concentration of the terminal region 45 may be higher than the p-type impurity concentration of the outer body region 21. The p-type impurity concentration of the terminal region 45 may be lower than the p-type impurity concentration of the outer body region 21. As a matter of course, the p-type impurity concentration of the terminal region 45 may be substantially equal to the p-type impurity concentration of the outer body region 21.

The terminal region 45 is formed in a region between the peripheral edge of the first main surface 3 and the outer body region 21 at an interval inwardly from the peripheral edge of the first main surface 3. The terminal region 45 extends in a band shape along the outer body region 21 in a plan view. The terminal region 45 includes a portion extending in a band shape in the first direction X and a portion extending in a band shape in the second direction Y in a plan view, and defines the active region 8 from a plurality of directions.

In this embodiment, the terminal region 45 surrounds the outer body region 21 in a plan view, and is defined in a polygonal round shape (in this embodiment, a quadrangular round shape) having four sides parallel to the peripheral edge of the first main surface 3. The terminal region may include an edge portion that connects the portion extending in the first direction X and the portion extending in the second direction Y in an arc shape (preferably, a quarter arc shape) in a plan view (refer to FIG. 4).

The terminal region 45 is formed at an interval from a bottom portion of the first semiconductor region 6 toward the first main surface 3 side, and opposes the second semiconductor region 7 across a portion of the first semiconductor region 6. Preferably, the terminal region 45 is formed at an interval from an intermediate portion of the first semiconductor region 6 toward the first main surface 3 side. The terminal region 45 may have a thickness (depth) substantially equal to the thickness (depth) of the outer body region 21. The thickness of the terminal region 45 may be thicker than the thickness of the outer body region 21, or may be thinner than the thickness of the outer body region 21.

The terminal region 45 includes an inner edge portion on the active region 8 side and an outer edge portion on the peripheral edge side of the first main surface 3. The inner edge portion of the terminal region 45 is connected to the outer edge portion of the outer body region 21. Thereby, the terminal region 45 is electrically connected to the outer body region 21. That is, in this embodiment, the terminal region 45 is electrically connected to the body regions 20 via the outer body region 21. In this embodiment, the inner edge portion of the terminal region 45 is connected to the outer edge portion of the outer body region 21 over the entire periphery.

The terminal region 45 (inner edge portion) includes an overlap region 46 overlapping the outer edge portion of the outer body region 21. The overlap region 46 is a high concentration region including the outer edge portion of the outer body region 21 and the inner edge portion of the terminal region 45. That is, the overlap region 46 includes both of the p-type impurity of the outer body region 21 and the p-type impurity of the terminal region 45, and has a p-type impurity concentration higher than both of the p-type impurity concentration of the outer body region 21 and the p-type impurity concentration of the terminal region 45.

The p-type impurity concentration of the overlap region 46 is higher than the p-type impurity concentration of the body region 20. The p-type impurity concentration of the overlap region 46 may be lower than the p-type impurity concentration of the contact region 25. As a matter of course, the p-type impurity concentration of the overlap region 46 may be higher than the p-type impurity concentration of the contact region 25.

The overlap region 46 extends in a band shape along the outer body region 21 in a plan view. The overlap region 46 includes a portion extending in a band shape in the first direction X and a portion extending in a band shape in the second direction Y in a plan view, and defines the active region 8 from a plurality of directions. In this embodiment, the overlap region 46 is defined in a polygonal round shape (in this embodiment, a quadrangular round shape) having four sides parallel to the peripheral edge of the first main surface 3.

The overlap region 46 may include an edge portion that connects the portion extending in the first direction X and the portion extending in the second direction Y in an arc shape (preferably, a quarter arc shape) in a plan view (refer to FIG. 4). Preferably, a width of the overlap region 46 is wider than the width of the body region 20. As a matter of course, the width of the overlap region 46 may be narrower than the width of the body region 20.

The semiconductor device 1 may include a p-type well region (46) having a relatively high concentration instead of the overlap region 46. In this case, the well region (46) has a p-type impurity concentration higher than both of the p-type impurity concentration of the outer body region 21 and the p-type impurity concentration of the terminal region 45. The p-type impurity concentration of the well region (46) is higher than the p-type impurity concentration of the body region 20.

The p-type impurity concentration of the well region (46) may be substantially equal to the p-type impurity concentration of the contact region 25. As a matter of course, the p-type impurity concentration of the well region (46) may be lower than the p-type impurity concentration of the contact region 25, or may be higher than the p-type impurity concentration of the contact region 25.

The well region (46) may be formed in any one or both of the surface layer portion of the outer body region 21 and the surface layer portion of the terminal region 45. Such a configuration is effective in a case where the terminal region 45 has a p-type impurity concentration substantially equal to the p-type impurity concentration of the outer body region 21 and is formed as a portion (lead-out portion) of the outer body region 21.

The semiconductor device 1 includes at least one p-type field region 47 that is formed in the surface layer portion of the first main surface 3 in the outer peripheral region 9. A plurality of the field regions 47 may be formed in an electrically floating state. The field regions 47 may be fixed to the source potential.

The number of the field region 47 is arbitrary. The number of the field region 47 may be 1 or more and 20 or less. The number of the field regions 47 may have a value in at least one range among a range of 1 or more and 5 or less, a range of 5 or more and 10 or less, a range of 10 or more and 15 or less, and a range of 15 or more and 20 or less. The number of the field regions 47 is typically 1 or more and 8 or less. In this embodiment, the semiconductor device 1 includes three field regions 47.

The field regions 47 are formed in regions between the peripheral edge of the first main surface 3 and the active region 8 at an interval inwardly from the peripheral edge of the first main surface 3. Specifically, the field regions 47 are formed in a region between the peripheral edge of the first main surface 3 and the outer body region 21. More specifically, the field regions 47 are arranged at intervals from the terminal region 45 toward the peripheral edge side of the first main surface 3 in a region between the peripheral edge of the first main surface 3 and the terminal region 45.

The field regions 47 are formed in band shapes extending along the active region 8 (terminal region 45) in a plan view. Each of the field regions 47 includes a portion extending in a band shape in the first direction X and a portion extending in a band shape in the second direction Y.

In this embodiment, the field regions 47 are formed in a polygonal round shape (in this embodiment, a quadrangular round shape) surrounding the active region 8 (terminal region 45) in a plan view. The field regions 47 may include an edge portion that connects the portion extending in the first direction X and the portion extending in the second direction Y in an arc shape (preferably, a quarter arc shape) (refer to FIG. 4).

The field regions 47 are formed at an interval from the bottom portion of the first semiconductor region 6 toward the first main surface 3 side, and oppose the second semiconductor region 7 across a portion of the first semiconductor region 6. Preferably, the field regions 47 are formed at an interval from an intermediate portion of the first semiconductor region 6 toward the first main surface 3 side.

The widths, the depths, the intervals, the p-type impurity concentration, etc., of the field regions 47 are arbitrary, and can take various values according to the electric field to be relaxed. The widths of the field regions 47 may be substantially constant, or may be non-uniform. The widths of the field regions 47 may gradually increase toward the peripheral edge side of the first main surface 3. The widths of the field regions 47 may gradually decrease toward the peripheral edge side of the first main surface 3.

The depths of the field regions 47 may be substantially constant, or may be non-uniform. The depths of the field regions 47 may gradually increase toward the peripheral edge side of the first main surface 3. The depths of the field regions 47 may gradually decrease toward the peripheral edge side of the first main surface 3. As a matter of course, the field regions 47 may include a relatively shallow portion and a deep portion that is deeper than the shallow portion. The shallow portion may be formed on the inner side, and the deep portion may be formed on the peripheral edge side. The shallow portion may be formed on the peripheral edge side, and the deep portion may be formed on the inner side.

The intervals of the field regions 47 may be substantially constant, or may be non-uniform. The intervals of the field regions 47 may gradually increase toward the peripheral edge side of the first main surface 3. The intervals of the field regions 47 may gradually decrease toward the peripheral edge side of the first main surface 3.

The p-type impurity concentrations of the field regions 47 may be substantially constant, or may be non-uniform. The p-type impurity concentrations of the field regions 47 may gradually increase toward the peripheral edge side of the first main surface 3. The p-type impurity concentrations of the field regions 47 may gradually decrease toward the peripheral edge side of the first main surface 3.

The p-type impurity concentrations of the field regions 47 may be substantially equal to the p-type impurity concentration of the body region 20 (outer body region 21). The p-type impurity concentrations of the field regions 47 may be higher than the p-type impurity concentration of the body region 20 (outer body region 21), or may be lower than the p-type impurity concentration of the body region 20 (outer body region 21). The p-type impurity concentrations of the field regions 47 may be substantially equal to the p-type impurity concentration of the terminal region 45. The p-type impurity concentrations of the field regions 47 may be higher than the p-type impurity concentration of the terminal region 45, or may be lower than the p-type impurity concentration of the terminal region 45.

Referring to FIG. 8, the semiconductor device 1 includes an outer peripheral insulating film 51 that covers the first main surface 3 in the outer peripheral region 9. The outer peripheral insulating film 51 may include at least one among a silicon oxide film, a silicon nitride film, and a silicon oxynitride film.

In this embodiment, the outer peripheral insulating film 51 has a single layer structure including a silicon oxide film. It is particularly preferable that the outer peripheral insulating film 51 includes a silicon oxide film which is made of an oxide of the chip 2. Preferably, the outer peripheral insulating film 51 is made of the same kind of insulating material as the insulating material of the insulating film 31. Preferably, the outer peripheral insulating film 51 has a thickness substantially equal to the thickness of the insulating film 31.

The outer peripheral insulating film 51 covers the first main surface 3 in a film shape in the outer peripheral region 9. The outer peripheral insulating film 51 collectively covers the outer body region 21, the terminal region 45, and the field regions 47. The outer peripheral insulating film 51 is connected to the insulating films 31 on the active region 8 side. Specifically, the outer peripheral insulating film 51 is integrally formed with the insulating films 31, and forms one insulating film with the insulating films 31.

Referring to FIG. 4, FIG. 5, and FIG. 8, the semiconductor device 1 includes a gate wiring 52 arranged on the first main surface 3 in the outer peripheral region 9. The semiconductor device 1 does not have a side wall structure (spacer) made of an insulator (for example, silicon oxide and/or silicon nitride) on the gate wiring 52 side.

The gate wiring 52 is selectively drawn onto the first main surface 3, and includes a portion extending in a direction different from the extending direction of the gate electrodes 32. The gate wiring 52 is connected to the gate electrodes 32, and applies a gate signal to the gate electrodes 32. The gate wiring 52 may be referred to as a “polysilicon gate wiring,” a “poly gate wiring,” a “second gate electrode,” or the like.

The gate wiring 52 includes a semiconductor polycrystal having conductivity. The gate wiring 52 may include either one or both of p-type conductive polysilicon and n-type conductive polysilicon. Preferably, the gate wiring 52 has the same conductivity type as the conductivity type of the gate electrode 32. The conductivity type of the gate wiring 52 is adjusted according to the conductivity type of the gate electrode 32.

The gate wiring 52 is arranged on the outer peripheral insulating film 51 in the outer peripheral region 9. Specifically, the gate wiring 52 is arranged on a portion of the outer peripheral insulating film 51 that covers the outer body region 21, and opposes the outer body region 21 across the outer peripheral insulating film 51. The gate wiring 52 is formed at an interval from the peripheral edge of the first main surface 3 toward the active region 8 side, and extends in a band shape along the active region 8. The gate wiring 52 includes a portion extending in a band shape in the first direction X and a portion extending in a band shape in the second direction Y in a plan view, and defines the active region 8 from a plurality of directions.

In this embodiment, the gate wiring 52 surrounds the active region 8 in a plan view, and is defined in a polygonal round shape (in this embodiment, a quadrangular round shape) having four sides parallel to the peripheral edge of the first main surface 3. The gate wiring 52 may have an end shape or an endless shape.

In this embodiment, the gate wiring 52 extends in a band shape (in this embodiment, a round shape) along the outer body region 21 in a plan view, and opposes the outer body region 21 in the lamination direction over the entire periphery. The gate wiring 52 may include an edge portion that connects the portion extending in the first direction X and the portion extending in the second direction Y in an arc shape (preferably, a quarter arc shape) in a plan view (refer to FIG. 4).

The gate wiring 52 is formed to be narrower than the outer body region 21 in a plan view, and is arranged on the outer body region 21 at an interval from the inner edge portion and the outer edge portion of the outer body region 21. That is, in this embodiment, the gate electrodes 32 are led out onto the outer body region 21, and the gate wiring 52 is connected to the gate electrodes 32 on the outer body region 21.

Preferably, a thickness of the gate wiring 52 is substantially equal to the thickness of the gate electrode 32. Preferably, a width of the gate wiring 52 is wider than the width of the gate electrode 32. The width of the gate wiring 52 is a width in a direction orthogonal to the extending direction. For example, the ratio of the width of the gate wiring 52 to the width of the gate electrode 32 may be 1 or larger and 50 or smaller.

The ratio of the width may have a value in at least one range among a range of 1 or larger and 10 or smaller, a range of 10 or larger and 20 or smaller, a range of 20 or larger and 30 or smaller, a range of 30 or larger and 40 or smaller, and a range of 40 or larger and 50 or smaller. The ratio of the width may be 5 or larger. The ratio of the width may be 20 or larger and 40 or smaller. As a matter of course, the width of the gate wiring 52 may be equal to or narrower than the width of the gate electrode 32. The width of the gate wiring 52 may be wider than the width of the outer body region 21.

The gate wiring 52 includes a wiring surface 53, a first wiring side wall 54 on an inner edge side, and a second wiring side wall 55 on an outer edge side. The wiring surface 53 extends along the outer peripheral insulating film 51 (first main surface 3). The wiring surface 53 may extend substantially parallel to the outer peripheral insulating film 51 (first main surface 3). The first wiring side wall 54 extends in the vertical direction Z on the outer peripheral insulating film 51, and the second wiring side wall 55 extends in the vertical direction Z on the outer peripheral insulating film 51.

The first wiring side wall 54 is connected to the gate electrodes 32 (the first side wall 34 and the second side wall 35) in a portion extending in the first direction X. That is, the gate wiring 52 includes a plurality of portions connected to the gate electrodes 32 in a T shape. Thereby, the gate wiring 52 is electrically connected to the gate electrodes 32.

The first wiring side wall 54 and the second wiring side wall 55 may extend to be perpendicular to the outer peripheral insulating film 51. That is, the gate wiring 52 may be formed in a quadrangular shape (flat rectangular shape) in a cross-sectional view. The first wiring side wall 54 and the second wiring side wall 55 may be inclined obliquely toward the wiring surface 53. That is, the gate wiring 52 may be formed in a tapered shape (preferably, an isosceles trapezoidal shape) in a cross-sectional view.

Referring to FIG. 8 and FIG. 9, the semiconductor device 1 includes a second silicide portion 60 that is partially formed in a surface portion of the wiring surface 53 of the gate wiring 52. That is, the gate wiring 52 includes the second silicide portion 60 in the surface portion of the wiring surface 53. The second silicide portion 60 is a polycide portion obtained by performing silicide processing on the polysilicon of the gate wiring 52. The second silicide portion 60 may be referred to as a “second metal semiconductor compound layer,” a “second silicide layer (polycide layer),” a “second silicide region (polycide region),” or the like.

The second silicide portion 60 may include at least one among Ti silicide, Ni silicide, Co silicide, Mo silicide, and W silicide. Preferably, the second silicide portion 60 is made of Ti silicide, Ni silicide, or Co silicide. It is particularly preferable that the second silicide portion 60 is made of the same type of silicide as the first silicide portion 40.

The second silicide portion 60 is formed at an interval inwardly from at least one of the first wiring side wall 54 or the second wiring side wall 55 of the gate wiring 52, and exposes at least one of a peripheral edge portion of the wiring surface 53 on the first wiring side wall 54 side or a peripheral edge portion of the wiring surface 53 on the second wiring side wall 55 side. In this embodiment, the second silicide portion 60 is formed at intervals inwardly from both of the first wiring side wall 54 and the second wiring side wall 55, and exposes both of the peripheral edge portion of the wiring surface 53 on the first wiring side wall 54 side and the peripheral edge portion of the wiring surface 53 on the second wiring side wall 55 side.

That is, the second silicide portion 60 is not exposed from both of the first wiring side wall 54 and the second wiring side wall 55. The second silicide portion 60 is formed at intervals inwardly from both of the first wiring side wall 54 and the second wiring side wall 55 in the entire surface portion of the wiring surface 53 in a plan view.

The second silicide portion 60 is formed at an interval from the outer peripheral insulating film 51 toward the wiring surface 53 side in the thickness direction, and opposes the outer peripheral insulating film 51 across a portion of the gate wiring 52 (polysilicon). Preferably, the second silicide portion 60 is formed at an interval from an intermediate portion of the gate wiring 52 toward the wiring surface 53 side in the thickness direction. As a matter of course, in a case where the gate wiring 52 has a relatively thin thickness, the second silicide portion 60 may have a bottom portion located on the outer peripheral insulating film 51 side with respect to the intermediate portion of the gate wiring 52.

The second silicide portion 60 extends in a band shape along the gate wiring 52 in the wiring surface 53, and opposes the outer body region 21 in the lamination direction. The second silicide portion 60 includes a portion extending in a band shape in the first direction X and a portion extending in a band shape in the second direction Y in a plan view. In this embodiment, the second silicide portion 60 surrounds the active region 8 in a plan view, and is defined in a polygonal round shape (in this embodiment, a quadrangular round shape) having four sides parallel to the peripheral edge of the first main surface 3.

The second silicide portion 60 may have an end shape or an endless shape. The second silicide portion 60 may include an edge portion that connects the portion extending in the first direction X and the portion extending in the second direction Y in an arc shape (preferably, a quarter arc shape) in a plan view.

The second silicide portion 60 is connected to the first silicide portions 40 at connection portions between the gate electrodes 32 and the gate wiring 52. That is, the second silicide portion 60 is integrally formed with the first silicide portions 40, and includes a plurality of portions connected to the first silicide portions 40 in a T shape (refer to FIG. 5).

In this embodiment, the second silicide portion 60 has a flat surface with respect to the wiring surface 53. Preferably, the second silicide portion 60 forms one flat surface together with the first silicide portions 40 at the connection portions between the gate electrodes 32 and the gate wiring 52. That is, preferably, the second silicide portion 60 is formed flush with the first silicide portions 40.

The second silicide portion 60 may be formed at an interval of 0.1 μm or wider and 5 μm or narrower inwardly from the first wiring side wall 54 (second wiring side wall 55). The interval of the second silicide portion 60 may have a value in at least one range among a range of 0.1 μm or wider and 0.5 μm or narrower, a range of 0.5 μm or wider and 1 μm or narrower, a range of 1 μm or wider and 1.5 μm or narrower, a range of 1.5 μm or wider and 2 μm or narrower, a range of 2 μm or wider and 2.5 μm or narrower, a range of 2.5 μm or wider and 3 μm or narrower, a range of 3 μm or wider and 3.5 μm or narrower, a range of 3.5 μm or wider and 4 μm or narrower, a range of 4 μm or wider and 4.5 μm or narrower, and a range of 4.5 μm or wider and 5 μm or narrower.

Preferably, the interval of the second silicide portion 60 is in a range of 0.2 μm or wider and 1 μm or narrower. It is particularly preferable that the interval of the second silicide portion 60 is in a range of 0.5 μm or narrower. The interval of the second silicide portion 60 may be substantially equal to the interval of the first silicide portions 40. The interval of the second silicide portion 60 may be wider than the interval of the first silicide portions 40. The interval of the second silicide portion 60 may be narrower than the interval of the first silicide portions 40.

The semiconductor device 1 includes a second polysilicon portion 61 that is formed in a portion other than the second silicide portion 60 on the wiring surface 53 of each gate wiring 52. That is, each gate wiring 52 includes the second silicide portion 60 and the second polysilicon portion 61 that is formed in the surface portion of the wiring surface 53. The second polysilicon portion 61 may be referred to as a “second polysilicon layer,” a “second polysilicon region,” or the like.

The second polysilicon portion 61 adopts various layouts according to the layout of the second silicide portion 60. In a case where the second silicide portion 60 is formed at an interval inwardly from at least one of the first wiring side wall 54 and the second wiring side wall 55 of the gate wiring 52, the second polysilicon portion 61 is formed in a region on at least one side of the first wiring side wall 54 and the second wiring side wall 55 on the wiring surface 53.

In this embodiment, the second silicide portion 60 is formed at intervals inwardly from both of the first wiring side wall 54 and the second wiring side wall 55 of the gate wiring 52. Therefore, the second polysilicon portion 61 includes a second polysilicon portion 61A on one side that is defined in a region on the first wiring side wall 54 side with respect to the second silicide portion 60 and a second polysilicon portion 61B on the other side that is defined in a region on the second wiring side wall 55 side with respect to the second silicide portion 60 (refer to FIG. and FIG. 9).

The second polysilicon portion 61A on one side forms the first wiring side wall 54 of the gate wiring 52 in addition to the peripheral edge portion on one side of the wiring surface 53. The second polysilicon portion 61A on one side extends in a band shape along the second silicide portion 60. In this embodiment, the second polysilicon portion 61A on one side forms the first wiring side wall 54 in the entire region of the gate wiring 52. The second polysilicon portion 61A on one side opposes the outer body region 21 in the lamination direction.

The second polysilicon portion 61B on the other side forms the second wiring side wall 55 of the gate wiring 52 in addition to the peripheral edge portion on the other side of the wiring surface 53. The second polysilicon portion 61B on the other side opposes the second polysilicon portion 61A on one side across the second silicide portion 60, and extends in a band shape along the second silicide portion 60.

That is, the second polysilicon portion 61B on the other side extends substantially parallel to the second polysilicon portion 61A on one side. In this embodiment, the second polysilicon portion 61B on the other side forms the second wiring side wall 55 in the entire region of the gate wiring 52. The second polysilicon portion 61B on the other side opposes the outer body region 21 in the lamination direction.

The second polysilicon portion 61 (second polysilicon portion 61A on one side) is connected to the first polysilicon portions 41 at connection portions between the gate electrodes 32 and the gate wiring 52. That is, the second polysilicon portion 61 is integrally formed with the first polysilicon portions 41.

The second polysilicon portion 61 includes a plurality of portions that are connected in an L shape to the first polysilicon portions 41 at connection corner portions between the gate electrodes 32 and the gate wiring 52 (refer to FIG. 5). In this embodiment, the second polysilicon portion 61 has a flat surface with respect to the wiring surface 53. That is, the second polysilicon portion 61 forms the flat wiring surface 53 together with the second silicide portion 60.

Preferably, the second polysilicon portion 61 forms one flat surface together with the first polysilicon portions 41 at the connection portions between the gate electrodes 32 and the gate wiring 52. That is, preferably, the second polysilicon portion 61 is formed flush with the first polysilicon portions 41. A width of the second silicide portion 60 corresponds to the interval of the second silicide portion 60 described above.

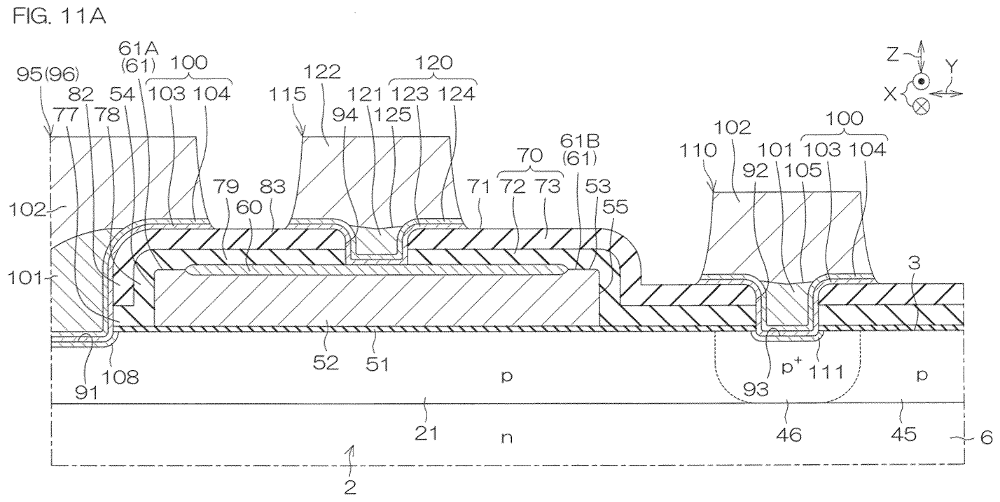

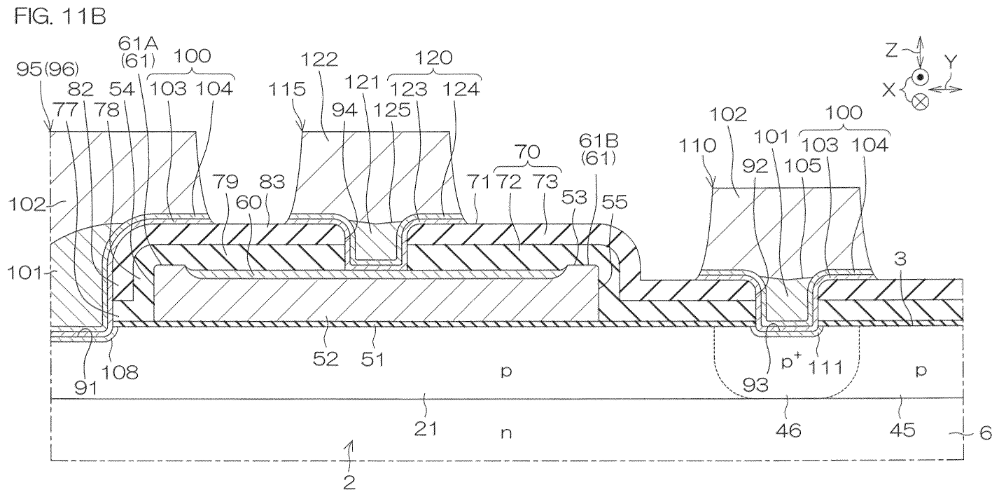

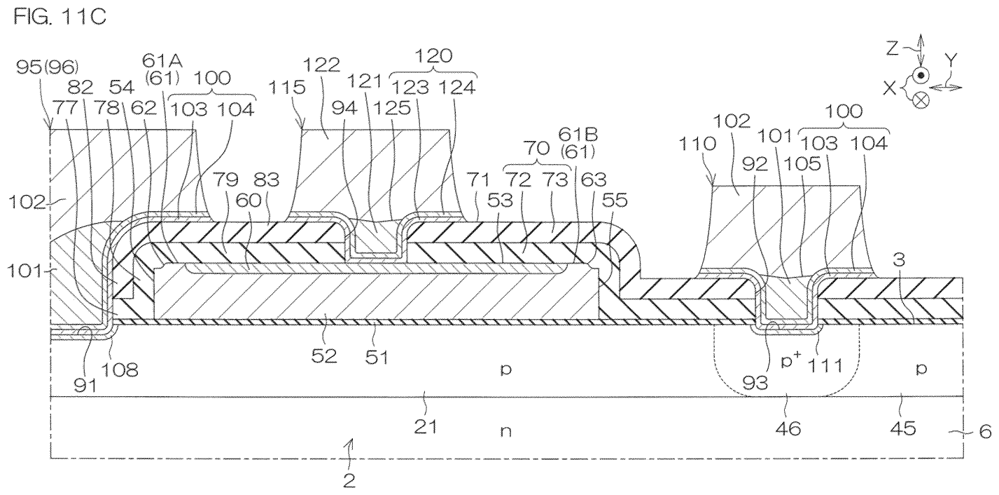

The gate wiring 52 (the second silicide portion 60 and the second polysilicon portion 61) may have a layout illustrated in FIG. 11A to FIG. 11C. FIG. 11A to FIG. 11C are enlarged cross-sectional views illustrating the gate wiring 52 according to a second example, a third example, and a fourth example.

The gate wiring 52 does not necessarily include any one of the configurations of the first to fourth examples (FIG. 9, and FIG. 11A to FIG. 11C). The gate wiring 52 may simultaneously include at least two features of the configurations of the first to fourth examples. The gate wirings 52 according to the first to fourth examples are obtained by adjusting process conditions in a manufacturing method.

Referring to FIG. 11A (second example), the second silicide portion 60 may include a portion that protrudes upwardly from the wiring surface 53 (opposite to the first main surface 3). The second silicide portion 60 may protrude upwardly in the entire region of the wiring surface 53.

The second polysilicon portion 61 may include a portion that is located on the first main surface 3 (the outer peripheral insulating film 51) side with respect to an upper end portion of the second silicide portion 60. The second polysilicon portion 61 may be located on the first main surface 3 (the outer peripheral insulating film 51) side with respect to the upper end portion of the second silicide portion 60 in the entire region of the wiring surface 53.

For example, in a case where the first silicide portion 40 includes a protrusion portion, a protrusion portion of the second silicide portion 60 may be connected to the protrusion portion of the first silicide portion 40. In this case, the second polysilicon portion 61 may be connected to the first polysilicon portion 41 in a region below the protrusion portion of the first silicide portion and the protrusion portion of the second silicide portion 60.

Referring to FIG. 11B (third example), the second silicide portion 60 may include a portion that is recessed toward the first main surface 3 (outer peripheral insulating film 51) side from the wiring surface 53. The second silicide portion 60 may be recessed toward the first main surface 3 (outer peripheral insulating film 51) side from the wiring surface 53 in the entire region of the wiring surface 53.

The second polysilicon portion 61 may include a portion that protrudes upwardly (opposite to the first main surface 3) from the second silicide portion 60. The second polysilicon portion 61 may protrude upwardly from the second silicide portion 60 in the entire region of the wiring surface 53.

For example, in a case where the first silicide portion 40 includes a recess portion, a recess portion of the second silicide portion 60 may be connected to the recess portion of the first silicide portion 40. In this case, the second polysilicon portion 61 may be connected to the first polysilicon portion 41 in a region above the recess portion of the first silicide portion 40 and the recess portion of the second silicide portion 60.

Referring to FIG. 11C (fourth example), the gate wiring 52 may include at least one (in this embodiment, both) of a first wiring recess 62 and a second wiring recess 63. FIG. 11C illustrates an example in which the first wiring recess 62 and the second wiring recess 63 are applied to the gate wiring 52 (refer to FIG. 9) according to the first example.

On the other hand, one or both of the first wiring recess 62 and the second wiring recess 63 may be applied to the gate wiring 52 (refer to FIG. 11A) according to the second example or the gate wiring 52 (refer to FIG. 11B) according to the third example.

The first wiring recess 62 is recessed toward the first main surface 3 (outer peripheral insulating film 51) side at a corner portion connecting the wiring surface 53 and the first wiring side wall 54. The first wiring recess 62 is formed in a band shape extending along the gate wiring 52 (first wiring side wall 54).

Preferably, a bottom portion of the first wiring recess 62 is formed at an interval from an intermediate portion of the gate wiring 52 toward the wiring surface 53 side in the thickness direction. In a case where the gate wiring 52 has a relatively thin thickness, the bottom portion of the first wiring recess 62 may have a bottom portion located on the outer peripheral insulating film 51 side with respect to the intermediate portion of the gate wiring 52.

The second wiring recess 63 is recessed toward the first main surface 3 (outer peripheral insulating film 51) side at a corner connecting the wiring surface 53 and the second wiring side wall 55. The second wiring recess 63 is formed in a band shape extending along the gate wiring 52 (second wiring side wall 55). Preferably, a bottom portion of the second wiring recess 63 is formed at an interval from an intermediate portion of the gate wiring 52 toward the wiring surface 53 side in the thickness direction.

In a case where the gate wiring 52 has a relatively thin thickness, the bottom portion of the second wiring recess 63 may have a bottom portion located on the outer peripheral insulating film 51 side with respect to the intermediate portion of the gate wiring 52. Preferably, a depth of the second wiring recess 63 is substantially equal to a depth of the first wiring recess 62.

The second silicide portion 60 is formed in the surface portion of the wiring surface 53 at an interval inwardly from the first wiring recess 62 and the second wiring recess 63, and exposes both of the first wiring recess 62 and the second wiring recess 63.

A bottom portion of the second silicide portion 60 may be located on the wiring surface 53 side with respect to a depth position of a bottom portion of the first wiring recess 62 (second wiring recess 63). The bottom portion of the second silicide portion 60 may be located on the first main surface 3 (outer peripheral insulating film 51) side with respect to a depth position of the bottom portion of the first wiring recess 62 (second wiring recess 63).

Preferably, a distance between the second silicide portion 60 and the first wiring recess 62 (second wiring recess 63) is longer than a width of the first wiring recess 62 (second wiring recess 63). As a matter of course, the distance between the second silicide portion 60 and the first wiring recess 62 (second wiring recess 63) may be shorter than the width of the first wiring recess 62 (second wiring recess 63).

The second polysilicon portion 61A on one side includes a portion that is exposed from the first wiring recess 62. In this embodiment, the second polysilicon portion 61A on one side is formed in the entire region of the first wiring recess 62. The second polysilicon portion 61A on one side includes a portion that is located in a region between the second silicide portion 60 and the first wiring recess 62.

In this embodiment, the second polysilicon portion 61B on the other side includes a portion that is exposed from the second wiring recess 63. In this embodiment, the second polysilicon portion 61B on the other side is formed in the entire region of the second wiring recess 63. The second polysilicon portion 61B on the other side includes a portion that is located in a region between the second silicide portion 60 and the second wiring recess 63.

For example, in a case where the gate electrode 32 includes the first electrode recess 42 and the second electrode recess 43, the first wiring recess 62 of the gate wiring 52 may be connected to both of the first electrode recess 42 and the second electrode recess 43.

That is, the first wiring recess 62 may include a plurality of portions that are connected in an L shape to the first electrode recesses 42 at connection corner portions between the gate electrodes 32 and the gate wiring 52. Also, the first wiring recess 62 may include a plurality of portions that are connected in an L shape to the second electrode recesses 43 at the connection corner portions.

The gate wiring 52 does not necessarily include both of the first wiring recess 62 and the second wiring recess 63 at the same time. For example, the gate wiring 52 may include only the first wiring recess 62 and may not include the second wiring recess 63. For example, the gate wiring 52 may include only the second wiring recess 63, and may not include the first wiring recess 62.

At least one of the gate wirings 52 (refer to FIG. 9, and FIG. 11A to FIG. 11C) according to the first to fourth examples can be combined with at least one of the gate electrodes 32 (refer to FIG. 7, and FIG. 10A to FIG. 10C) according to the first to fourth examples. From the viewpoint of uniformity of the layout of the gate electrode 32 and the layout of the gate wiring 52, preferably, the gate wiring 52 (refer to FIG. 9) according to the first example is combined with the gate electrode 32 (refer to FIG. 7) according to the first example.

Similarly, preferably, the gate wiring 52 (refer to FIG. 10A) according to the second example is combined with the gate electrode 32 (refer to FIG. 11A) according to the second example. Similarly, preferably, the gate wiring 52 (refer to FIG. 10B) according to the third example is combined with the gate electrode 32 (refer to FIG. 11B) according to the third example. Similarly, preferably, the gate wiring 52 (refer to FIG. 10C) according to the fourth example is combined with the gate electrode 32 (refer to FIG. 11C) according to the fourth example.

The semiconductor device 1 includes an interlayer film 70 of insulating property that covers the first main surface 3. The interlayer film 70 may be referred to as an “interlayer insulating film,” an “intermediate insulating film,” or the like. The interlayer film 70 has an insulating surface 71 extending along the first main surface 3. The interlayer film 70 collectively covers the active region 8 and the outer peripheral region 9 on the first main surface 3.

The interlayer film 70 covers the gate structures 30 in the active region 8. The interlayer film 70 directly covers both of the insulating film 31 and the gate electrode 32 of each gate structure 30. That is, the interlayer film 70 includes a portion that directly covers the electrode surface 33, the first side wall 34, and the second side wall 35 of the gate electrode 32.

The interlayer film 70 collectively covers the outer body region 21, the terminal region 45, and the field regions 47 across the outer peripheral insulating film 51 in the outer peripheral region 9. The interlayer film 70 directly covers both of the outer peripheral insulating film 51 and the gate wiring 52.

That is, the interlayer film 70 includes a portion that directly covers the wiring surface 53, the first wiring side wall 54, and the second wiring side wall 55 of the gate wiring 52. In this embodiment, the interlayer film 70 is continuous with the first to fourth side surfaces 5A to 5D. The interlayer film 70 may be formed at an interval inwardly from the first to fourth side surfaces 5A to 5D, and expose the peripheral edge portion (first semiconductor region 6) of the first main surface 3.

In this embodiment, the interlayer film 70 has a laminated structure including a first oxide film 72 (first insulating film) and a second oxide film 73 (second insulating film) laminated in this order from the first main surface 3 side. That is, the interlayer film 70 has an insulating surface 71 formed by the second oxide film 73. The first oxide film 72 has a single layer structure made of a silicon oxide film with no impurity added. The first oxide film 72 may be referred to as a non-doped silicate glass film (NSG).

The first oxide film 72 collectively covers the active region 8 and the outer peripheral region 9. The first oxide film 72 collectively covers the gate structures 30 in the active region 8. The first oxide film 72 covers both of the insulating film 31 and the gate electrode 32 of each gate structure 30 in a film shape.

The first oxide film 72 includes a first covering portion 74, a second covering portion 75, and a third covering portion 76. The first covering portion 74 extends in a film shape in the horizontal direction along the insulating film 31 (first main surface 3), and includes a portion in contact with the first side wall 34 (second side wall 35) of the gate electrode 32. In this embodiment, the first covering portion 74 (first oxide film 72) has a thickness thinner than the thickness of the gate electrode 32, and covers the insulating film 31 at an interval from a height position of the electrode surface 33 of the gate electrode 32 toward the insulating film 31 side.

The second covering portion 75 is led out from the first covering portion 74 toward the electrode surface 33 side in the lamination direction, and directly covers the first side wall 34 (second side wall 35) in a film shape. The second covering portion 75 (interlayer film 70) directly covers the first polysilicon portion 41 in the entire region of the first side wall 34 (second side wall 35).

The third covering portion 76 is led out from the second covering portion 75 onto the electrode surface 33, and extends in a film shape in the horizontal direction along the electrode surface 33. The third covering portion 76 directly covers the entire electrode surface 33 between the first side wall 34 and the second side wall 35.

The third covering portion 76 (interlayer film 70) has a portion that directly covers the first silicide portion 403 and a portion that directly covers the first polysilicon portion 41 in the electrode surface 3. Preferably, the third covering portion 76 forms an arc corner portion that is curved in an arc shape together with the second covering portion 75 in a portion that covers a corner portion of the gate electrode 32. The arc corner portion may have a center of curvature on the gate electrode 32 side.

The first oxide film 72 collectively covers the outer body region 21, the terminal region 45, and the field regions 47 across the outer peripheral insulating film 51 in the outer peripheral region 9. The first oxide film 72 covers the gate wiring 52 in the outer peripheral region 9.

The first oxide film 72 includes a first wiring covering portion 77, a second wiring covering portion 78, and a third wiring covering portion 79. The first wiring covering portion 77 extends in a film shape in the horizontal direction along the outer peripheral insulating film 51 (first main surface 3), and includes a portion in contact with the first wiring side wall 54 (second wiring side wall 55) of the gate wiring 52. In this embodiment, the first wiring covering portion 77 (first oxide film 72) has a thickness thinner than the thickness of the gate wiring 52, and covers the outer peripheral insulating film 51 at an interval from a height position of the wiring surface 53 of the gate wiring 52 toward the outer peripheral insulating film 51 side.

The second wiring covering portion 78 is led out from the first wiring covering portion 77 toward the wiring surface 53 side in the lamination direction, and directly covers the first side wall 34 (second side wall 35) in a film shape. The second wiring covering portion 78 (interlayer film 70) directly covers the second polysilicon portion 61 in the entire region of the first wiring side wall 54 (second wiring side wall 55).

The third wiring covering portion 79 is led out from the second wiring covering portion 78 onto the wiring surface 53, and extends in a film shape in the horizontal direction along the wiring surface 53. The third wiring covering portion 79 directly covers the entire wiring surface 53 between the first wiring side wall 54 and the second wiring side wall 55.

The third wiring covering portion 79 (interlayer film 70) includes a portion that directly covers the second silicide portion 60 and a portion that directly covers the second polysilicon portion 61 in the wiring surface 53. Preferably, the third wiring covering portion 79 forms an arc corner portion that is curved in an arc shape together with the second wiring covering portion 78 in a portion that covers the corner portion of the gate wiring 52. The arc corner portion may have a center of curvature on the gate wiring 52 side.

The second oxide film 73 may have a single layer structure made of a silicon oxide film containing phosphorus or a laminated structure including a silicon oxide film containing phosphorus. The silicon oxide film containing phosphorus may contain boron. The silicon oxide film containing phosphorus may be referred to as a phosphorus silicon glass film (PSG film). The silicon oxide film containing both of phosphorus and boron may be referred to as a boron phosphorus silicon glass film (BPSG film).

The second oxide film 73 may have a single layer structure including a PSG film or a BPSG film laminated on the first oxide film 72. The second oxide film 73 may have a laminated structure including a PSG film laminated on the first oxide film 72 and a BPSG film laminated on the PSG film. The second oxide film 73 may have a laminated structure including a BPSG film laminated on the first oxide film 72 and a PSG film laminated on the BPSG film. In this embodiment, the second oxide film 73 has a single layer structure made of a PSG film as an example.

The second oxide film 73 covers the first oxide film 72 in a film shape, and collectively covers the active region 8 and the outer peripheral region 9 across the first oxide film 72. The second oxide film 73 collectively covers the gate structures 30 across the first oxide film 72 in the active region 8. Specifically, the second oxide film 73 covers both of the insulating film 31 and the gate electrode 32 in a film shape across the first oxide film 72.

The second oxide film 73 includes a first upper covering portion 80 and a second upper covering portion 81. The first upper covering portion 80 covers the first covering portion 74 and the second covering portion 75 of the first oxide film 72. The first upper covering portion 80 covers the insulating film 31 across the first covering portion 74 in a portion that is located on the first covering portion 74.

The first upper covering portion 80 extends in a film shape in the lamination direction along the second covering portion 75 from above the first covering portion 74, and covers the first side wall 34 (second side wall 35) of the gate structure 30 across the second covering portion 75. That is, the first upper covering portion 80 includes a portion that covers the first polysilicon portion 41 across the second covering portion 75.

The second upper covering portion 81 covers the third covering portion 76 of the first oxide film 72. The second upper covering portion 81 extends in a film shape in the horizontal direction from the first upper covering portion 80 along the third covering portion 76, and covers the electrode surface 33 of the gate structure 30 across the third covering portion 76. The second upper covering portion 81 covers the entire electrode surface 33 across the third covering portion 76 between the first side wall 34 and the second side wall 35.

The second upper covering portion 81 includes a portion that covers the first silicide portion 40 across the first oxide film 72 (third covering portion 76) and a portion that covers the first polysilicon portion 41 across the first oxide film 72 (third covering portion 76). Preferably, the second upper covering portion 81 forms an arc corner portion that is curved in an arc shape together with the first upper covering portion 80 in a portion that covers the corner portion of the gate wiring 52. The arc corner portion may have a center of curvature on the gate wiring 52 side.

A variation in electrical characteristics of the gate electrode 32 (the first silicide portion 40 and the first polysilicon portion 41) due to impurity diffusion of the second oxide film 73 is suppressed by the first oxide film 72 with no impurity added. A variation in insulation characteristics of the second oxide film 73 due to impurity diffusion of the gate electrode 32 is suppressed by the first oxide film 72 with no impurity added.

The second oxide film 73 collectively covers the outer body region 21, the terminal region 45, and the field regions 47 across the outer peripheral insulating film 51 and the first oxide film 72 in the outer peripheral region 9. The second oxide film 73 covers the gate wiring 52 across the first oxide film 72 in the outer peripheral region 9.

The second oxide film 73 includes a first upper wiring covering portion 82 and a second upper wiring covering portion 83. The first upper wiring covering portion 82 covers the first wiring covering portion 77 and the second wiring covering portion 78 of the first oxide film 72. The first upper wiring covering portion 82 covers the outer peripheral insulating film 51 across the first wiring covering portion 77 in a portion that is located on the first wiring covering portion 77.

The first upper wiring covering portion 82 extends in a film shape in the lamination direction along the second wiring covering portion 78 from above the first wiring covering portion 77, and covers the first wiring side wall 54 (second wiring side wall 55) across the second wiring covering portion 78. That is, the first upper wiring covering portion 82 includes a portion that covers the second polysilicon portion 61 across the second wiring covering portion 78.

The second upper wiring covering portion 83 covers the third wiring covering portion 79 of the first oxide film 72. The second upper wiring covering portion 83 extends in a film shape in the horizontal direction from the first upper wiring covering portion 82 along the third wiring covering portion 79, and covers the wiring surface 53 across the third wiring covering portion 79. The second upper wiring covering portion 83 covers the entire region of the wiring surface 53 with the third wiring covering portion 79 interposed between the first wiring side wall 54 and the second wiring side wall 55.

The second upper wiring covering portion 83 includes a portion that covers the second silicide portion 60 across the first oxide film 72 (third wiring covering portion 79) and a portion that covers the second polysilicon portion 61 across the first oxide film 72 (third wiring covering portion 79). Preferably, the second upper wiring covering portion 83 forms an arc corner portion that is curved in an arc shape together with the first upper wiring covering portion 82 in a portion that covers the corner portion of the gate wiring 52. The arc corner portion may have a center of curvature on the gate wiring 52 side.

A variation in electrical characteristics of the gate wiring 52 (the second silicide portion 60 and the second polysilicon portion 61) due to impurity diffusion of the second oxide film 73 is suppressed by the first oxide film 72 with no impurity added. A variation in insulation characteristics of the second oxide film 73 due to impurity diffusion of the gate wiring 52 is suppressed by the first oxide film 72 with no impurity added.

The semiconductor device 1 includes a plurality of source openings 90 formed in the interlayer film 70 in the active region 8. The source openings 90 are formed at intervals from the gate electrodes 32 in regions on sides of the gate electrodes 32, and expose the first main surface 3 (chip 2). Specifically, the source openings 90 are respectively formed in regions between the gate electrodes 32, and penetrate the insulating film 31 and the interlayer film 70.

The source openings 90 have wall surfaces that penetrate both of the first oxide film 72 and the second oxide film 73 and are defined by both of the first oxide film 72 and the second oxide film 73. Each of the source openings 90 has an opening end defined by the arc corner portion of the interlayer film 70. Each of the source openings 90 exposes the corresponding source regions 23 and 24 and the corresponding contact region 25.

In this embodiment, the source openings 90 are formed at intervals in the first direction X, and are respectively formed in a band shape extending in the second direction Y. That is, the source openings 90 are formed in a stripe shape extending in the second direction Y. The source openings 90 are formed at intervals from the gate wiring 52 in the second direction Y. That is, the source openings 90 are formed in regions surrounded by the gate electrodes 32 and the gate wirings 52.

The source openings 90 may be formed in regions between two gate structures 30 adjacent to each other in the first direction X. In this case, the source openings 90 may be formed at intervals in a line in the second direction Y. Further, in this case, each source opening 90 may be formed in a quadrangular shape (square shape) in a plan view, a rectangular shape extending in the first direction X, a rectangular shape extending in the second direction Y, a hexagonal shape, a circular shape, or the like.

The source opening 90 may have a width W of 0.1 μm or wider and 3 μm or narrower. The width W of the source opening 90 may have a value in at least one range among a range of 0.1 μm or wider and 0.25 μm or narrower, a range of 0.25 μm or wider and 0.5 μm or narrower, a range of 0.5 μm or wider and 0.75 μm or narrower, a range of 0.75 μm or wider and 1 μm or narrower, a range of 1 μm or wider and 1.25 μm or narrower, a range of 1.25 μm or wider and 1.5 μm or narrower, a range of 1.5 μm or wider and 1.75 μm or narrower, a range of 1.75 μm or wider and 2 μm or narrower, a range of 2 μm or wider and 2.25 μm or narrower, a range of 2.25 μm or wider and 2.5 μm or narrower, a range of 2.5 μm or wider and 2.75 μm or narrower, and a range of 2.75 μm or wider and 3 μm or narrower. Preferably, the width W of the source opening 90 is in a range of 0.2 μm or wider and 1 μm or narrower.

The source opening 90 may have a depth D of 0.1 μm or deeper and 2 μm or shallower. The depth D of the source opening 90 may have a value in at least one range among a range of 0.1 μm or deeper and 0.25 μm or shallower, a range of 0.25 μm or deeper and 0.5 μm or shallower, a range of 0.5 μm or deeper and 0.75 μm or shallower, a range of 0.75 μm or deeper and 1 μm or shallower, a range of 1 μm or deeper and 1.25 μm or shallower, a range of 1.25 μm or deeper and 1.5 μm or shallower, a range of 1.5 μm or deeper and 1.75 μm or shallower, and a range of 1.75 μm or deeper and 2 μm or shallower. Preferably, the depth D of the source opening 90 is in a range of 0.5 μm or deeper and 1 μm or shallower.

Preferably, the source opening 90 has an aspect ratio D/W of 0.5 or larger and 3 or smaller. The aspect ratio D/W is defined by a ratio of the depth D of the source opening 90 to the width W of the source opening 90.

The aspect ratio D/W may have a value in at least one range among a range of 0.5 or larger and 0.75 or smaller, a range of 0.75 or larger and 1 or smaller, a range of 1 or larger and 1.25 or smaller, a range of 1.25 or larger and 1.5 or smaller, a range of 1.5 or larger and 1.75 or smaller, a range of 1.75 or larger and 2 or smaller, a range of 2 or larger and 2.25 or smaller, a range of 2.25 or larger and 2.5 or smaller, a range of 2.5 or larger and 2.75 or smaller, and a range of 2.75 or larger and 3 or smaller. Preferably, the aspect ratio D/W is larger than 1. That is, preferably, the source opening 90 has the depth D deeper than the width W. According to this configuration, the gate structures 30 are arranged at a narrow pitch.

The semiconductor device 1 includes a plurality of source recesses 91 that are respectively formed in portions of the first main surface 3 exposed from the source openings 90. The semiconductor device 1 does not necessarily include the source recess 91. Therefore, a configuration without the source recess 91 may be adopted.

Each of the source recesses 91 has a planar shape that matches the planar shape of the corresponding source opening 90, and is recessed from the first main surface 3 toward the second main surface 4 side. The source recesses 91 are formed at an interval from the bottom portion of the corresponding body region 20 toward the first main surface 3 side, and respectively expose the corresponding source regions 23 and 24 and the corresponding contact region 25. Specifically, the source recesses 91 are formed at an interval from the bottom portions of the corresponding source regions 23 and 24 (contact region 25) toward the first main surface 3 side.

The semiconductor device 1 includes at least one (in this embodiment, a plurality of) outer openings 92 formed in the interlayer film 70 in the outer peripheral region 9. The outer openings 92 are formed in a portion of the interlayer film 70 that covers the terminal region 45. The outer openings 92 penetrate the interlayer film 70, and expose the terminal region 45. In this embodiment, the outer openings 92 are formed in a portion of the interlayer film 70 that covers the overlap region 46 of the terminal region 45, and expose the overlap region 46.

The outer openings 92 may expose the outer body region 21 instead of or in addition to the terminal region 45 (overlap region 46). The outer openings 92 have wall surfaces that penetrate both of the first oxide film 72 and the second oxide film 73 and are defined by both of the first oxide film 72 and the second oxide film 73. Each of the outer openings 92 has an opening end defined by the arc corner portion of the interlayer film 70.

The outer openings 92 are formed at intervals along the terminal region 45 (overlap region 46) (refer to FIG. 4 and FIG. 5). The outer openings 92 may be formed in a quadrangular shape (square shape), a rectangular shape, a hexagonal shape, a circular shape, or the like in a plan view. The outer openings 92 may be formed in a band shape extending along the terminal region 45 (overlap region 46) in a plan view. Similarly to the source opening 90, the outer opening 92 may have the aspect ratio D/W (=0.5 or larger and 3 or smaller, preferably larger than 1).

The semiconductor device 1 may have a single outer opening 92. The single outer opening 92 may be formed in a band shape extending along the terminal region 45 (overlap region 46). The single outer opening 92 may have a portion extending in a band shape in the first direction X and a portion extending in a band shape in the second direction Y in a plan view.

The single outer opening 92 may be formed in a polygonal round shape having four sides parallel to the peripheral edge of the first main surface 3, either with ends or without ends (in this embodiment, a quadrangular round shape). The single outer opening 92 may have an edge portion that connects a portion extending in the first direction X and a portion extending in the second direction Y along the terminal region 45 (overlap region 46) in a plan view in an arc shape (preferably, a quadrangular arc shape) (refer to FIG. 4).

The semiconductor device 1 includes a plurality of outer recesses 93 that are respectively formed in portions of the first main surface 3 exposed from the outer openings 92. The semiconductor device 1 does not necessarily include the outer recess 93. Therefore, a configuration without the outer recess 93 may be adopted.

Each of the outer recesses 93 has a planar shape that matches the planar shape of the corresponding outer opening 92, and is recessed from the first main surface 3 toward the second main surface 4 side. The outer recesses 93 are formed at an interval from the bottom portion of the terminal region 45 (overlap region 46) toward the first main surface 3 side, and respectively expose the terminal region 45 (overlap region 46).

The outer recess 93 may have a depth substantially equal to the depth of the source recess 91. In a case where the single outer opening 92 is formed, a single outer recess 93 that matches the planar shape of the single outer opening 92 is formed.

The semiconductor device 1 includes at least one (in this embodiment, a plurality of) gate openings 94 formed in the interlayer film 70 in the outer peripheral region 9. The gate openings 94 are formed in a portion that covers the gate wiring 52 in the interlayer film 70. The gate openings 94 penetrate the interlayer film 70, and expose the wiring surface 53 of the gate wiring 52.

Specifically, the gate openings 94 expose the second silicide portion 60 of the gate wiring 52. More specifically, the gate openings 94 are formed at an interval inwardly from the second polysilicon portion 61, and expose the second silicide portion 60. The gate openings 94 expose only the second silicide portion 60, and do not expose the second polysilicon portion 61. As a matter of course, one or a plurality of gate openings 94 for exposing the second polysilicon portion 61 may be formed.

The gate openings 94 have wall surfaces that penetrate both of the first oxide film 72 and the second oxide film 73 and are defined by both of the first oxide film 72 and the second oxide film 73. Each of the gate openings 94 has an opening end defined by the arc corner portion of the interlayer film 70.

The gate openings 94 are formed at intervals along the gate wiring 52 (second silicide portion 60) (refer to FIG. 4 and FIG. 5). The gate openings 94 may be formed in a quadrangular shape (square shape), a rectangular shape, a hexagonal shape, a circular shape, or the like in a plan view. The gate openings 94 may be formed in a band shape extending along the gate wiring 52 in a plan view. Similarly to the source opening 90, the gate opening 94 may have the aspect ratio D/W (=0.5 or larger and 3 or smaller, preferably larger than 1).

The semiconductor device 1 may have a single gate opening 94. The single gate opening 94 may be formed in a band shape extending along the gate wiring 52. The single gate opening 94 may have a portion extending in a band shape in the first direction X and a portion extending in a band shape in the second direction Y in a plan view.

The single gate opening 94 may be formed in a polygonal round shape having four sides parallel to the peripheral edge of the first main surface 3, either with ends or without ends (in this embodiment, a quadrangular round shape). The single gate opening 94 may have an edge portion that connects a portion extending in the first direction X and a portion extending in the second direction Y along the gate wiring 52 (second silicide portion 60) in a plan view in an arc shape (preferably, a quadrangular arc shape) (refer to FIG. 4).

Referring to FIG. 1, etc., the semiconductor device 1 includes a source pad electrode 95 arranged on the interlayer film 70. The source pad electrode 95 is a terminal electrode to which the source potential is to be applied from outside. The source pad electrode 95 may be referred to as a “first pad electrode,” a “first main surface electrode,” a “first terminal electrode,” or the like.

The source pad electrode 95 is arranged on a portion of the interlayer film 70 that covers the active region 8. The source pad electrode 95 covers the gate electrodes 32 across the interlayer film 70, and is electrically separated from the gate electrodes 32 by the interlayer film 70. The source pad electrode 95 is electrically connected to the body regions 20, the outer body region 21, the source regions 23 and 24, the contact regions 25, etc., via the source openings 90.

In this embodiment, the source pad electrode 95 includes a first pad portion 96, a second pad portion 97, and a third pad portion 98. The first pad portion 96 has a relatively large planar area, and forms a main body of the source pad electrode 95. In this embodiment, the first pad portion 96 is formed in a polygonal shape (in this embodiment, quadrangular shape) having four sides parallel to the peripheral edge of the chip 2 in a plan view, and is unevenly distributed on the fourth side surface 5D side with respect to a central portion of the active region 8. The first pad portion 96 covers the gate electrodes 32 across the interlayer film 70, and is electrically connected to the body regions 20, etc., via the source openings 90.

The second pad portion 97 has a planar area smaller than the planar area of the first pad portion 96, and is led out in a band shape (quadrangular shape) from one end portion (end portion on the first side surface 5A side) of the first pad portion 96 in the second direction Y toward the third side surface 5C side. The second pad portion 97 covers the gate electrodes 32 across the interlayer film 70, and is electrically connected to the body regions 20, etc., via the source openings 90.

The third pad portion 98 has a planar area smaller than the planar area of the first pad portion 96, and is led out in a band shape (quadrangular shape) from the other end portion (end portion on the second side surface 5B side) of the first pad portion 96 in the second direction Y toward the third side surface 5C side, and opposes the second pad portion 97 in the second direction Y. The third pad portion 98 covers the gate electrodes 32 across the interlayer film 70, and is electrically connected to the body regions 20, etc., via the source openings 90.

The planar area of the third pad portion 98 may be substantially equal to the planar area of the second pad portion 97. As a matter of course, the planar area of the third pad portion 98 may be larger than the planar area of the second pad portion 97, or may be smaller than the planar area of the second pad portion 97. Either one or both of the second pad portion 97 and the third pad portion 98 may be used as a terminal portion for current monitoring.

The source pad electrode 95 does not necessarily include both of the second pad portion 97 and the third pad portion 98 at the same time. The source pad electrode 95 may include only one of the second pad portion 97 and the third pad portion 98. As a matter of course, the source pad electrode 95 may include only the first pad portion 96, and may not include the second pad portion 97 and the third pad portion 98.

Referring to FIG. 6 and FIG. 7, the source pad electrode 95 includes a first underlying electrode film 100, a plurality of first embedded electrodes 101, and a first main electrode film 102. The first underlying electrode film 100 may be referred to as a “source underlying electrode film,” the first embedded electrode 101 may be referred to as a “source-embedded electrode,” and the first main electrode film 102 may be referred to as a “source main electrode film.”

The first underlying electrode film 100 forms a lower layer portion of the source pad electrode 95 (the first pad portion 96, the second pad portion 97, and the third pad portion 98), and covers the interlayer film 70 in the active region 8. The first underlying electrode film 100 collectively covers a region of the interlayer film 70 in which the source openings 90 are formed in a film shape. That is, the first underlying electrode film 100 enters the source openings 90 from on the insulating surface 71.

The first underlying electrode film 100 includes a portion that covers the insulating surface 71 of the interlayer film 70 in a film shape and a portion that covers the wall surfaces of the source openings 90 in a film shape. The first underlying electrode film 100 defines recesses in the source openings 90. The first underlying electrode film 100 may include a portion that partially covers the gate wiring 52 across the interlayer film 70. The first underlying electrode film 100 may be formed at an interval inwardly from the gate wiring 52 in a plan view.

In this embodiment, the first underlying electrode film 100 has a laminated structure including a first electrode film 103 laminated on the interlayer film 70 and a second electrode film 104 laminated on the first electrode film 103. In this embodiment, the first electrode film 103 includes a Ti film, and the second electrode film 104 includes a TiN film. The first underlying electrode film 100 does not necessarily have a laminated structure, and may have a single layer structure including one of the first electrode film 103 (Ti film) and the second electrode film 104 (TiN film).

A thickness of the first electrode film 103 may be in a range of 10 nm or thicker and 100 nm or thinner. The thickness of the first electrode film 103 may have a value in at least one range among a range of 10 nm or thicker and 25 nm or thinner, a range of 25 nm or thicker and 50 nm or thinner, a range of 50 nm or thicker and 75 nm or thinner, and a range of 75 nm or thicker and 100 nm or thinner.

A thickness of the second electrode film 104 may be in a range of 50 nm or thicker and 200 nm or thinner. The thickness of the second electrode film 104 may have a value in at least one range among a range of 50 nm or thicker and 75 nm or thinner, a range of 75 nm or thicker and 100 nm or thinner, a range of 100 nm or thicker and 125 nm or thinner, a range of 125 nm or thicker and 150 nm or thinner, a range of 150 nm or thicker and 175 nm or thinner, and a range of 175 nm or thicker and 200 nm or thinner. Preferably, the thickness of the second electrode film 104 is thicker than the thickness of the first electrode film 103.

The first electrode film 103 collectively covers a region of the interlayer film 70 in which the source openings 90 are formed in a film shape, and enters the source openings 90 from on the insulating surface 71. The first electrode film 103 includes a portion that covers the insulating surface 71 of the interlayer film 70 in a film shape and a portion that covers the wall surfaces of the source openings 90 in a film shape. The first electrode film 103 directly covers the insulating surface 71.

That is, the first electrode film 103 directly covers the second oxide film 73 in the insulating surface 71. The first oxide film 72 opposes the gate electrodes 32 across the interlayer film 70 in a portion that covers the insulating surface 71. That is, the first electrode film 103 opposes the first silicide portion 40 and the first polysilicon portion 41 of each gate electrode 32 across the interlayer film 70.

The first electrode film 103 covers the arc corner portions in a film shape along the arc corner portions of the interlayer film 70 (second oxide film 73), and enters the source openings 90. That is, the first electrode film 103 includes a portion extending in an arc shape at the arc corner portion. Thereby, the film formability of the first electrode film 103 with respect to the interlayer film 70 (the wall surface of the source opening 90) is improved.

The first electrode film 103 extends along the wall surface of the source opening 90, and covers the insulating film 31, the first oxide film 72, and the second oxide film 73. The first electrode film 103 opposes the first side wall 34 (second side wall 35) of the gate electrode 32 across the interlayer film 70. That is, the first electrode film 103 opposes the first polysilicon portion 41 of the gate electrode 32 across the first oxide film 72 and the second oxide film 73.

The first electrode film 103 covers the first main surface 3 in a film shape at a bottom portion of each source opening 90, and is electrically connected to the first main surface 3. Specifically, the first electrode film 103 includes a portion that covers the source recess 91 in a film shape at the bottom portion of each source opening 90, and is electrically connected to the source regions 23 and 24 and the contact region 25.

The first electrode film 103 may be formed at an interval from a height position of the first main surface 3 toward the bottom portion side of the source recess 91, and cover the source recess 91 in a film shape. The first electrode film 103 may include a portion that is located on the bottom portion side of the source recess 91 with respect to the height position of the first main surface 3, and a portion that is located on the insulating film 31 side with respect to the height position of the first main surface 3.

The second electrode film 104, on the first electrode film 103, collectively covers a region of the interlayer film 70 in a film shape in which the source openings 90 are formed. The second electrode film 104 includes a portion that covers the insulating surface 71 of the interlayer film 70 in a film shape across the first electrode film 103 and a portion that covers the wall surfaces of the source openings 90 in a film shape across the first electrode film 103.

The second electrode film 104 opposes the gate electrodes 32 across the first electrode film 103 and the interlayer film 70 in a portion that covers the insulating surface 71. That is, the second electrode film 104 opposes the first silicide portion 40 and the first polysilicon portion 41 of each gate electrode 32 across the first electrode film 103 and the interlayer film 70.

The second electrode film 104 covers the arc corner portions of the interlayer film 70 (second oxide film 73) in a film shape along the first electrode film 103, and enters the source openings 90. That is, the second electrode film 104 includes a portion extending in an arc shape at the arc corner portion of the interlayer film 70. Thereby, the film formability of the second electrode film 104 with respect to the interlayer film 70 (the wall surface of the source opening 90) is improved.

The second electrode film 104 extends along the wall surface of the source opening 90, and covers the insulating film 31, the first oxide film 72, and the second oxide film 73 across the first electrode film 103. The second electrode film 104 opposes the first side wall 34 (second side wall 35) of the gate electrode 32 across the first electrode film 103 and the interlayer film 70. That is, the second electrode film 104 opposes the first polysilicon portion 41 of the gate electrode 32 across the first oxide film 72, the second oxide film 73, and the first electrode film 103.

The second electrode film 104 includes a portion that covers the source recess 91 in a film shape at the bottom portion of each source opening 90 across the first electrode film 103, and is electrically connected to the source regions 23 and 24 and the contact region 25 via the first electrode film 103. In a case where the first electrode film 103 is located on the bottom portion side of the source recess 91 with respect to the first main surface 3, the second electrode film 104 may include a portion that is located in the source recess 91. In a case where the first electrode film 103 includes a portion that is located above the first main surface 3, the entire second electrode film 104 is located above the source recess 91.

The first embedded electrodes 101 form an intermediate layer portion of the source pad electrode 95 (the first pad portion 96, the second pad portion 97, and the third pad portion 98), and are respectively embedded in the source openings 90. The first embedded electrode 101 includes a conductive material different from the conductive material of the first underlying electrode film 100. The first embedded electrode 101 includes at least one of tungsten, molybdenum, a tungsten alloy, and a molybdenum alloy. In this embodiment, the first embedded electrode 101 includes tungsten.

In this embodiment, the first embedded electrodes 101 are respectively embedded in a one-to-one correspondence relationship with the source openings 90 via the single first underlying electrode film 100. The first embedded electrodes 101 are electrically connected to the first main surface 3 (chip 2) in the source openings 90. Specifically, the first embedded electrode 101 is electrically connected to the source regions 23 and 24 and the contact region 25 via the first underlying electrode film 100. Hereinafter, the configuration of one first embedded electrode 101 will be described.

The first embedded electrode 101 has a first embedded electrode surface 105 exposed from the source opening 90, and exposes the insulating surface 71. The first embedded electrode surface 105 may be referred to as a “source-embedded electrode film.” The first embedded electrode 101 is embedded in the source opening 90 at an interval from the insulating surface 71 toward the first main surface 3 side, and exposes a portion of the first underlying electrode film 100 (the second electrode film 104) that covers the insulating surface 71. That is, the first embedded electrode surface 105 is located on the first main surface 3 side with respect to the insulating surface 71.

The first embedded electrode 101 does not include a portion that opposes the electrode surface 33 of the gate electrode 32 across the interlayer film 70 in the lamination direction (vertical direction Z). That is, the first embedded electrode 101 does not oppose the first silicide portion 40 and the first polysilicon portion 41 across the interlayer film 70 in the lamination direction (vertical direction Z).

The first embedded electrode 101 covers the first oxide film 72 and the second oxide film 73 across the first underlying electrode film 100. The first embedded electrode 101 opposes the first side wall 34 (second side wall 35) of the gate electrode 32 in the horizontal direction. That is, the first embedded electrode 101 opposes the first polysilicon portion 41 in the horizontal direction.

In a case where the first underlying electrode film 100 is located on the bottom portion side of the source recess 91 with respect to the first main surface 3, the first embedded electrode 101 may include a portion that is located in the source recess 91. In a case where the first underlying electrode film 100 includes a portion that is located above the first main surface 3, the entire first embedded electrode 101 is located above the source recess 91.

The first embedded electrode surface 105 of the first embedded electrode 101 is located on the insulating surface 71 side with respect to the height position of the first oxide film 72. In this embodiment, the first embedded electrode surface 105 is located above the electrode surface 33 of the gate electrode 32.

Specifically, the first embedded electrode surface 105 has a recess 106 that is recessed toward the first main surface 3 (chip 2) side at a central portion. A bottom portion of the recess 106 is located on the insulating surface 71 side with respect to the height position of the electrode surface 33. That is, in this embodiment, the entire first embedded electrode surface 105 is located above the electrode surface 33. In this embodiment, the first embedded electrode surface 105 includes a portion that covers the arc corner portion of the interlayer film 70 across the first underlying electrode film 100.

The first main electrode film 102 forms an upper layer portion of the source pad electrode 95 (the first pad portion 96, the second pad portion 97, and the third pad portion 98), and covers the first underlying electrode film 100 and the first embedded electrodes 101 in a film shape. The first main electrode film 102 includes a conductive material different from the conductive material of the first underlying electrode film 100 and the conductive material of the first embedded electrode 101.

The first main electrode film 102 may include at least one of an Al film, an Al alloy film, a Cu film, and a Cu alloy film. The Al alloy film may include at least one of an AlSi alloy film, an AlCu alloy film, and an AlSiCu alloy film. The first main electrode film 102 has a thickness thicker than the thickness (total thickness) of the first underlying electrode film 100. The first main electrode film 102 has a thickness thicker than the thickness of the first embedded electrode 101.

The thickness of the first main electrode film 102 may be in a range of 0.5 μm or thicker and 5 μm or thinner. The thickness of the first main electrode film 102 may have a value in at least one range among a range of 0.5 μm or thicker and 1 μm or thinner, a range of 1 μm or thicker and 1.5 μm or thinner, a range of 1.5 μm or thicker and 2 μm or thinner, a range of 2 μm or thicker and 2.5 μm or thinner, a range of 2.5 μm or thicker and 3 μm or thinner, a range of 3 μm or thicker and 3.5 μm or thinner, a range of 3.5 μm or thicker and 4 μm or thinner, a range of 4 μm or thicker and 4.5 μm or thinner, and a range of 4.5 μm or thicker and 5 μm or thinner.

The first main electrode film 102 is mechanically and electrically connected to the first underlying electrode film 100 in a portion that covers the insulating surface 71. Thereby, the first main electrode film 102 opposes the gate electrodes 32 across the first underlying electrode film 100 and the interlayer film 70. That is, the first main electrode film 102 opposes the first silicide portion 40 and the first polysilicon portion 41 of each gate electrode 32 across the first underlying electrode film 100 and the interlayer film 70.

The first main electrode film 102 is mechanically and electrically connected to the first embedded electrodes 101 in a portion that covers the source openings 90. That is, the first main electrode film 102 is electrically connected to the body regions 20, the outer body region 21, the source regions 23 and 24, the contact regions 25, etc., via both of the first underlying electrode film 100 and the first embedded electrodes 101.

The first main electrode film 102 is directly connected to the first embedded electrode surface 105 of the first embedded electrode 101. That is, the first main electrode film 102 includes a portion that is connected to the first embedded electrode surface 105 at a height on the first main surface 3 side with respect to a height position of the insulating surface 71. The first main electrode film 102 is connected to the first embedded electrode surface 105 above the height position of the first oxide film 72.

In this embodiment, the first main electrode film 102 is connected to the first embedded electrode surface 105 above the electrode surface 33 of the gate electrode 32. That is, the first main electrode film 102 does not include a portion that opposes the gate electrode 32 in the horizontal direction. The first main electrode film 102 includes a portion that covers the recess 106 of the first embedded electrode surface 105. The first main electrode film 102 may include a portion that covers the arc corner portion of the interlayer film 70 across the first underlying electrode film 100.

The film formability of the first main electrode film 102 with respect to the source openings 90 is improved by the first embedded electrodes 101. Thereby, a current path between the first main surface 3 and the first main electrode film 102 is appropriately secured. Such a configuration is effective in suppressing film formation defects caused by the source openings 90 and reducing wiring resistance.

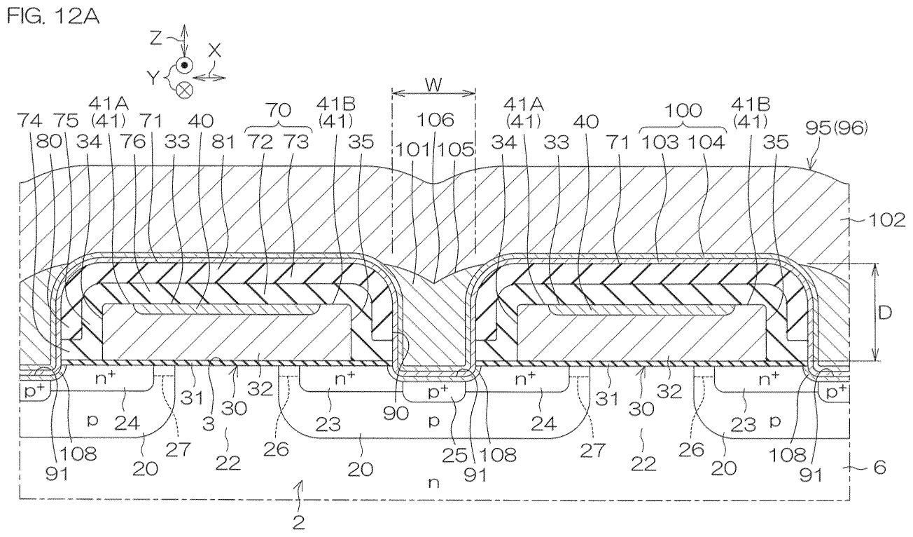

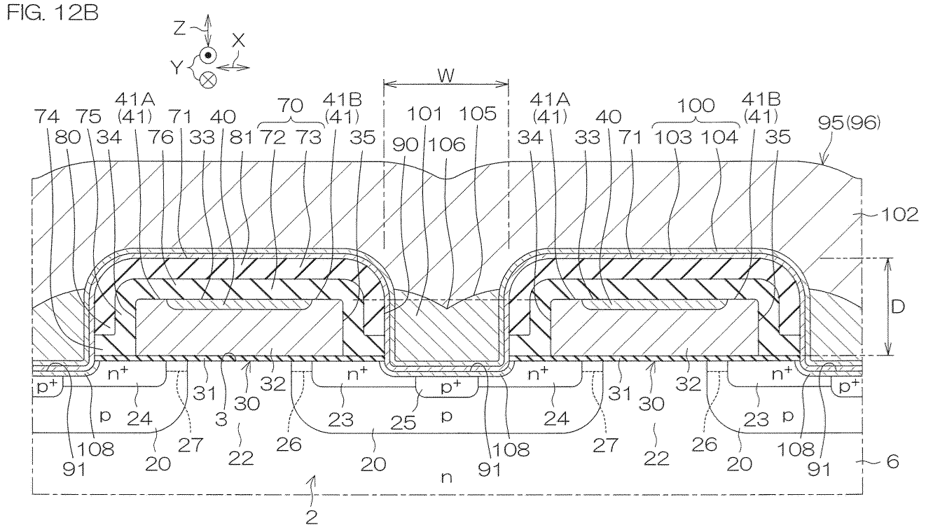

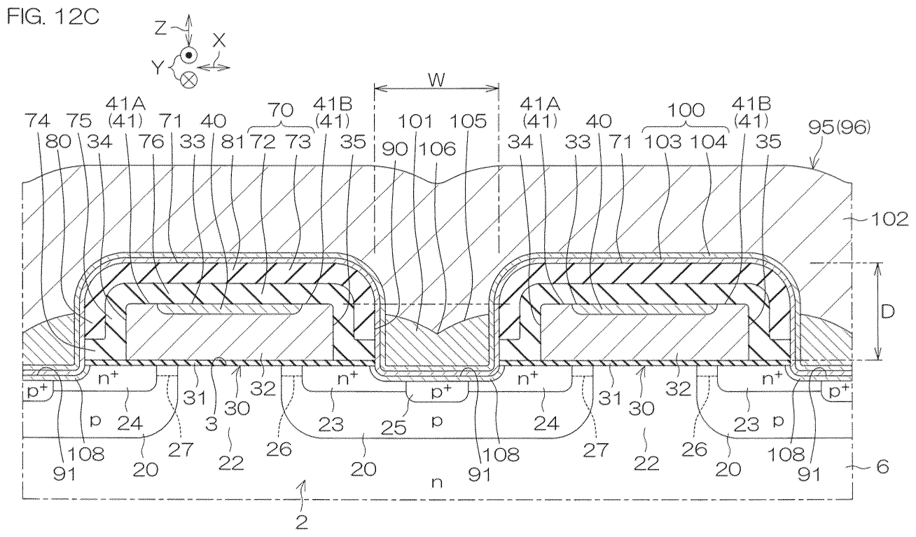

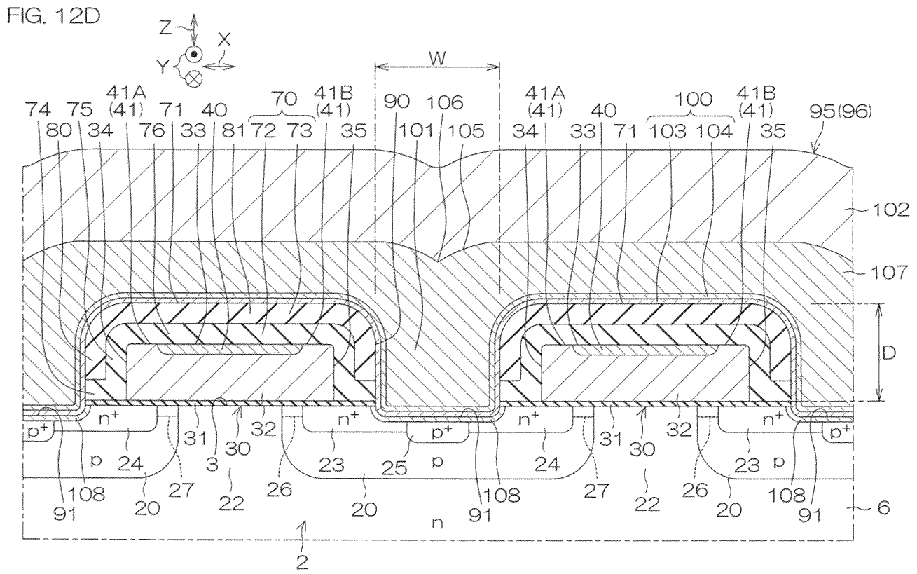

The source pad electrode 95 may have a layout illustrated in FIG. 12A to FIG. 12D. FIG. 12A to FIG. 12D are enlarged cross-sectional views illustrating the source pad electrode 95 according to a second example, a third example, a fourth example, and a fifth example.

The source pad electrode 95 does not necessarily include any one of the configurations of the first to fifth examples (FIG. 7, and FIG. 12A to FIG. 12D). The source pad electrode 95 may simultaneously include at least two features of the configurations of the first to fifth examples. The source pad electrode 95 according to the first to fifth examples is obtained by adjusting process conditions in a producing process.

FIG. 12A to FIG. 12D illustrate examples in which the source pad electrode 95 according to the first to fifth examples is formed together with the gate electrode 32 according to the first example. On the other hand, the source pad electrode 95 according to the first to fifth examples can be formed together with at least one of the gate electrodes 32 (FIG. 7, and FIG. 10A to FIG. 10C) according to the first to fourth examples.

Referring to FIG. 12A (second example), the source pad electrode 95 may include a plurality of first embedded electrodes 101 extending in a vertically long columnar shape in a cross-sectional view. That is, the first embedded electrodes 101 may be respectively embedded in the vertically long source openings 90 having the aspect ratio D/W larger than 1. In this case, each of the first embedded electrodes 101 has the aspect ratio D/W larger than 1 in the cross-sectional view, corresponding to the aspect ratio D/W of the corresponding source opening 90.

Preferably, the aspect ratio D/W of the vertically long first embedded electrode 101 (source opening 90) is larger than 1 and 3 or smaller. For example, the aspect ratio D/W may have a value in at least one range among a range larger than 1 and equal to or smaller than 1.25, a range of 1.25 or larger and 1.5 or smaller, a range of 1.5 or larger and 1.75 or smaller, a range of 1.75 or larger and 2 or smaller, a range of 2 or larger and 2.25 or smaller, a range of 2.25 or larger and 2.5 or smaller, a range of 2.5 or larger and 2.75 or smaller, and a range of 2.75 or larger and 3 or smaller. Preferably, the aspect ratio D/W is 2 or smaller.

In this embodiment, the first main electrode film 102 is mechanically and electrically connected to the first embedded electrodes 101 extending in the vertically long columnar shapes. In this configuration, the gate electrodes 32 are arranged at narrow pitches by the first embedded electrodes 101 (the source openings 90) extending in the vertically long columnar shapes. In particular, since the semiconductor device 1 does not have the side wall structure (spacer) on the side of the gate electrode 32, the narrowing pitch of the gate electrodes 32 each of which includes the first silicide portion 40 is not hindered by the side wall structure (spacer).

Referring to FIG. 12B (third example), the source pad electrode 95 may include a plurality of first embedded electrodes 101 including a portion that is located on the first main surface 3 side with respect to the electrode surface 33 of the gate electrode 32.

In this embodiment, the first embedded electrodes 101 include a portion that is located on the first main surface 3 side with respect to the electrode surface 33 and a portion that is located on the insulating surface 71 side with respect to the electrode surface 33 in the first embedded electrode surface 105, respectively. Specifically, in the first embedded electrode surface 105, the bottom portion of the recess 106 is located on the first main surface 3 side with respect to the electrode surface 33, and a portion other than the recess 106 is located on the insulating surface 71 side with respect to the electrode surface 33.

In this embodiment, the first main electrode film 102 includes a portion that is connected to the first embedded electrode surface 105 (first embedded electrode 101) in a region located on the first main surface 3 side with respect to the electrode surface 33, and a portion that is connected to the first embedded electrode surface 105 (first embedded electrode 101) in a region located on the insulating surface 71 side with respect to the electrode surface 33.

The first main electrode film 102 covers the interlayer film 70 across a portion of the first underlying electrode film 100 that covers the wall surface of the source opening 90, and includes a portion that opposes the first side wall 34 (second side wall 35) of the gate electrode 32 in the horizontal direction. That is, the first main electrode film 102 includes a portion that opposes the first polysilicon portion 41 in the horizontal direction.

Referring to FIG. 12C (fourth example), the source pad electrode 95 may include a plurality of first embedded electrodes 101 that are located on the first main surface 3 side with respect to the height position of the electrode surface 33 of the gate electrode 32. That is, the entire first embedded electrode surface 105 may be located on the first main surface 3 side with respect to the electrode surface 33.

At least a portion or the entirety of the first embedded electrode surface 105 may be located on the insulating surface 71 side with respect to the first oxide film 72. For example, the bottom portion of the recess 106 may be located on the insulating surface 71 side with respect to the first oxide film 72. In the first embedded electrode surface 105, the bottom portion of the recess 106 may be located on the first main surface 3 side with respect to the first oxide film 72, and a portion other than the recess 106 may be located on the insulating surface 71 side with respect to the first oxide film 72. As a matter of course, a configuration in which the entire first embedded electrode 101 is located on the first main surface 3 side with respect to the first oxide film 72 may be adopted.

In this embodiment, the first main electrode film 102 is connected to the first embedded electrode surface 105 (first embedded electrode 101) in a region located on the first main surface 3 side with respect to the electrode surface 33, and does not include a portion that is connected to the first embedded electrode surface 105 (first embedded electrode 101) in a region located on the insulating surface 71 side with respect to the electrode surface 33.

In this embodiment, the first main electrode film 102 is connected to the first embedded electrode surface 105 (first embedded electrode 101) in a region above the first oxide film 72. The first main electrode film 102 includes a portion that opposes the first side wall 34 (second side wall 35) of the gate electrode 32 in the horizontal direction. That is, the first main electrode film 102 opposes the first polysilicon portion 41 in the horizontal direction.

The first main electrode film 102 covers the interlayer film 70 across a portion of the first underlying electrode film 100 that covers the wall surface of the source opening 90. The first main electrode film 102 may be connected to the first embedded electrode surface 105 (first embedded electrode 101) in a region located on the first main surface 3 side with respect to the first oxide film 72.

Referring to FIG. 12D (fifth example), the source pad electrode 95 may include a plurality of first embedded electrodes 101 that are led out from the source openings 90 onto the insulating surface 71 and cover the insulating surface 71. The first embedded electrodes 101 cover the first underlying electrode film 100 on the insulating surface 71, and includes a portion that covers the insulating surface 71 across the first underlying electrode film 100.

That is, each of the first embedded electrodes 101 has the first embedded electrode surface 105 exposed from the source openings 90 above the insulating surface 71. The first embedded electrodes 101 include a portion that opposes the gate electrode 32 across the first underlying electrode film 100 and the interlayer film 70 in the lamination direction (vertical direction Z). That is, the first embedded electrode 101 include a portion that opposes the first silicide portion 40 and the first polysilicon portion 41 of the gate electrode 32 in the lamination direction (vertical direction Z).

The first embedded electrodes 101 are integrated on the insulating surface 71, and one source intermediate electrode 107 is formed. The source intermediate electrode 107 (the first embedded electrodes 101) covers the entire region of the first underlying electrode film 100. The electrode surface (first embedded electrode surface 105) of the source intermediate electrode 107 is located above the insulating surface 71.

In this embodiment, the first main electrode film 102 is mechanically and electrically connected to the first embedded electrode surfaces 105 of the first embedded electrodes 101 (source intermediate electrode 107) above the insulating surface 71. The first main electrode film 102 includes a portion that opposes the insulating surface 71 across the first embedded electrodes 101 (source intermediate electrode 107). In this embodiment, the first main electrode film 102 does not include a mechanical connection portion with the first underlying electrode film 100.

The semiconductor device 1 includes a plurality of first source silicide portions 108 that are respectively formed in surface portions of portions of the first main surface 3 that are exposed from the source openings 90. The first source silicide portions 108 are formed in a film shape along wall surfaces (side walls and bottom walls) of the source recesses 91, and are mechanically and electrically connected to the first underlying electrode film 100.

That is, the first source silicide portions 108 are formed in the surface layer portions of the body regions 20, and electrically connect the first embedded electrodes 101 to the body regions 20 via the first underlying electrode films 100.

The first source silicide portion 108 may include at least one among Ti silicide, Ni silicide, Co silicide, Mo silicide, and W silicide. Preferably, the first source silicide portion 108 is made of Ti silicide, Ni silicide, or Co silicide.

The semiconductor device 1 includes a source finger electrode 110 that is led out from the source pad electrode 95 onto the outer peripheral region 9. The source finger electrode 110 transmits the source potential applied to the source pad electrode 95 to the outer peripheral region 9. In this embodiment, the source finger electrode 110 is drawn from a portion of the source pad electrode 95 (first pad portion 96) on the fourth side surface 5D side onto a portion of the interlayer film 70 that covers the outer peripheral region 9.

The source finger electrode 110 is led out onto the terminal region 45, and is electrically connected to the terminal region 45 via the outer openings 92. Specifically, the source finger electrode 110 is electrically connected to the overlap region 46 of the terminal region 45 via the outer openings 92. The source finger electrode 110 extends in a band shape along the terminal region 45 (overlap region 46). The source finger electrode 110 includes a portion extending in a band shape in the first direction X and a portion extending in a band shape in the second direction Y in a plan view.

In this embodiment, the source finger electrode 110 is formed in a polygonal round shape (in this embodiment, a quadrangular round shape) having four sides parallel to the peripheral edge of the first main surface 3, and surrounds the source pad electrode 95. The source finger electrode 110 may include an edge portion that connects the portion extending in the first direction X and the portion extending in the second direction Y in an arc shape (preferably, a quarter arc shape) in a plan view (refer to FIG. 4).

Similarly to the source pad electrode 95, the source finger electrode 110 includes the first underlying electrode film 100, the first embedded electrodes 101, and the first main electrode film 102. The first underlying electrode film 100 forms a lower layer portion of the source finger electrode 110, and covers the interlayer film 70 in the outer peripheral region 9.

The first underlying electrode film 100 collectively covers a region of the interlayer film 70 in which the outer openings 92 are formed in a film shape. That is, the first underlying electrode film 100 enters the outer openings 92 from above the insulating surface 71. The first underlying electrode film 100 includes a portion that covers the insulating surface 71 of the interlayer film 70 in a film shape and a portion that covers the wall surfaces of the outer openings 92 in a film shape. The first underlying electrode film 100 defines recesses in the outer openings 92.

Similarly to the source pad electrode 95, the first underlying electrode film 100 has the laminated structure including the first electrode film 103 and the second electrode film 104. The first electrode film 103 collectively covers a region of the interlayer film 70 in which the outer openings 92 are formed in a film shape, and enters the outer openings 92 from above the insulating surface 71. That is, the first electrode film 103 includes a portion that covers the insulating surface 71 of the interlayer film 70 in a film shape and a portion that covers the wall surfaces of the outer openings 92 in a film shape.

The first electrode film 103 covers the arc corner portion in a film shape along the arc corner portion of the interlayer film 70 (second oxide film 73), and enters the outer opening 92. That is, the first electrode film 103 includes a portion extending in an arc shape at an arc corner portion. Thereby, the film formability of the first electrode film 103 with respect to the interlayer film 70 (the wall surface of the outer opening 92) is improved. The first electrode film 103 extends along the wall surface of the outer opening 92, and covers the outer peripheral insulating film 51, the first oxide film 72, and the second oxide film 73.

The first electrode film 103 covers the first main surface 3 in a film shape at a bottom portion of each outer opening 92, and is electrically connected to the first main surface 3 (chip 2). Specifically, the first electrode film 103 includes a portion that covers the outer recess 93 in a film shape at the bottom portion of each outer opening 92, and is electrically connected to the terminal region 45 (overlap region 46) in the outer recess 93.

The first electrode film 103 may be formed at an interval from a height position of the first main surface 3 toward the bottom portion side of the outer recess 93, and cover the outer recess 93 in a film shape. The first electrode film 103 may include a portion that is located on the bottom portion side of the outer recess 93 with respect to the height position of the first main surface 3, and a portion that is located on the outer peripheral insulating film 51 side with respect to the height position of the first main surface 3.

The second electrode film 104 collectively covers a region of the interlayer film 70 which is arranged on the first electrode film 103 and in which the outer openings 92 are formed in a film shape. That is, the second electrode film 104 includes a portion that covers the insulating surface 71 of the interlayer film 70 in a film shape across the first electrode film 10 and a portion that covers the wall surfaces of the outer openings 92 in a film shape across the first electrode film 103.

The second electrode film 104 covers the arc corner portion of the interlayer film 70 (second oxide film 73) in a film shape along the first electrode film 103, and enters the outer opening 92. That is, the second electrode film 104 includes a portion extending in an arc shape at the arc corner portion of the interlayer film 70 (second oxide film 73).

Thereby, the film formability of the second electrode film 104 with respect to the interlayer film 70 (the wall surface of the outer opening 92) is improved. The second electrode film 104 extends along the wall surface of the outer opening 92, and covers the outer peripheral insulating film 51, the first oxide film 72, and the second oxide film 73 across the first electrode film 103.

The second electrode film 104 includes a portion that covers the outer recess 93 in a film shape across the first electrode film 103 at the bottom portion of each outer opening 92, and is electrically connected to the terminal region 45 (overlap region 46) via the first electrode film 103.

In a case where the first electrode film 103 is located on the bottom portion side of the outer recess 93 with respect to the first main surface 3, the second electrode film 104 may include a portion that is located in the outer recess 93. In a case where the first electrode film 103 includes a portion that is located above the first main surface 3, the entire second electrode film 104 is located above the outer recess 93.

The first embedded electrodes 101 form a middle layer portion of the source finger electrode 110, and are respectively embedded in the outer openings 92. In this embodiment, the first embedded electrodes 101 are respectively embedded in a one-to-one correspondence relationship with the outer openings 92 via the single first underlying electrode film 100. The first embedded electrodes 101 are electrically connected to the terminal region 45 (overlap region 46) via the first underlying electrode film 100.

The first embedded electrode 101 has the first embedded electrode surface 105 exposed from the outer opening 92, and exposes the insulating surface 71. Specifically, the first embedded electrode 101 is embedded in the outer opening 92 at an interval from the insulating surface 71 toward the first main surface 3 side, and exposes a portion of the first underlying electrode film 100 (the second electrode film 104) that covers the insulating surface 71. That is, the first embedded electrode surface 105 is located on the first main surface 3 side with respect to the insulating surface 71.

The first embedded electrode 101 covers the first oxide film 72 and the second oxide film 73 across the first underlying electrode film 100. The first embedded electrode surface 105 is located on the insulating surface 71 side with respect to the height position of the first oxide film 72 in the outer opening 92. The first embedded electrode 101 includes a portion that covers the arc corner portion of the interlayer film 70 across the first underlying electrode film 100.

The first embedded electrode 101 may be embedded at an interval from the arc corner portion of the interlayer film 70 toward the outer peripheral insulating film 51 side, and expose the entire region of the arc corner portion. In this case, the first embedded electrode surface 105 may be located on the insulating surface 71 side with respect to the height position of the first oxide film 72. As a matter of course, the first embedded electrode surface 105 may be located on the outer peripheral insulating film 51 side with respect to the height position of the first oxide film 72.

In a case where the first underlying electrode film 100 is located on the bottom portion side of the outer recess 93 with respect to the first main surface 3, the first embedded electrode 101 may include a portion that is located in the outer recess 93. In a case where the first underlying electrode film 100 includes a portion that is located above the first main surface 3, the entire first embedded electrode 101 is located above the outer recess 93.

The first main electrode film 102 forms an upper layer portion of the source finger electrode 110, and covers the first underlying electrode film 100 and the first embedded electrodes 101 in a film shape. The first main electrode film 102 is mechanically and electrically connected to the first underlying electrode film 100 in a portion that covers the insulating surface 71, and is mechanically and electrically connected to the first embedded electrodes 101 in a portion that covers the outer openings 92. That is, the first main electrode film 102 is electrically connected to the terminal region 45 (overlap region 46) via the first underlying electrode film 100 and the first embedded electrodes 101.

The first main electrode film 102 is also directly connected to the first embedded electrode surface 105 of the first embedded electrode 101 on the source finger electrode 110 side. That is, the first main electrode film 102 includes a portion that is connected to the first embedded electrode surface 105 at the height position of the first main surface 3 side with respect to the height position of the insulating surface 71.

The first main electrode film 102 is connected to the first embedded electrode surface 105 above the height position of the first oxide film 72. The first main electrode film 102 includes a portion that covers the recess 106 of the first embedded electrode surface 105. The first main electrode film 102 may include a portion that covers the arc corner portion of the interlayer film 70 across the first underlying electrode film 100.

The film formability of the first main electrode film 102 with respect to the outer openings 92 is improved by the first embedded electrodes 101. Thereby, a current path between the terminal region 45 (overlap region 46) and the first main electrode film 102 is appropriately secured. Such a configuration is effective in suppressing film formation defects caused by the outer openings 92 and reducing wiring resistance.

In addition, a connection form of the first main electrode film 102 of the source finger electrode 110 with respect to the first embedded electrode 101 of the source finger electrode 110 is similar to the connection form of the first main electrode film 102 of the source pad electrode 95 with respect to the first embedded electrode 101 of the source pad electrode 95.

The semiconductor device 1 includes a plurality of second source silicide portions 111 that are respectively formed in surface portions of portions of the first main surface 3 that are exposed from the outer openings 92. The second source silicide portions 111 are formed in a film shape along wall surfaces (side walls and bottom walls) of the outer recesses 93, and are mechanically and electrically connected to the first underlying electrode film 100.

That is, the second source silicide portions 111 are formed in the surface layer portion of the terminal region 45 (overlap region 46), and electrically connect the first embedded electrodes 101 to the terminal region 45 (overlap region 46) via the first underlying electrode film 100.

The second source silicide portion 111 may include at least one among Ti silicide, Ni silicide, Co silicide, Mo silicide, and W silicide. Preferably, the second source silicide portion 111 is made of Ti silicide, Ni silicide, or Co silicide. It is particularly preferable that the second source silicide portion 111 is made of the same type of silicide as the first source silicide portion 108.

The semiconductor device 1 includes a gate finger electrode 115 that is selectively drawn onto the interlayer film 70. The gate finger electrode 115 transmits the gate potential to the gate wiring 52. The gate finger electrode 115 is drawn onto a portion of the interlayer film 70 that covers the gate wiring 52 (that is, on the outer peripheral region 9), and is electrically connected to the gate wiring 52 via the gate openings 94.

The gate finger electrode 115 is arranged in a region between the source pad electrode 95 and the source finger electrode 110 at an interval from the source pad electrode 95 and the source finger electrode 110. The gate finger electrode 115 is arranged on the gate wiring 52, and extends in a band shape along the gate wiring 52. The gate finger electrode 115 includes a portion extending in a band shape in the first direction X and a portion extending in a band shape in the second direction Y in a plan view.

In this embodiment, the gate finger electrode 115 is formed in a band shape with ends that has four sides parallel to the peripheral edge of the first main surface 3, and surrounds the source pad electrode 95. The gate finger electrode 115 may include an edge portion that connects the portion extending in the first direction X and the portion extending in the second direction Y in an arc shape (preferably, a quarter arc shape) in a plan view (refer to FIG. 4). The gate finger electrode 115 has a pair of open ends through which the source finger electrode 110 pass on the fourth side surface 5D side.

Referring to FIG. 9, the gate finger electrode 115 includes a second underlying electrode film 120, at least one (in this embodiment, a plurality of) second embedded electrodes 121, and a second main electrode film 122. The second underlying electrode film 120 may be referred to as a “gate underlying electrode film,” the second embedded electrode 121 may be referred to as a “gate embedded electrode,” and the second main electrode film 122 may be referred to as a “gate main electrode film.”

The second underlying electrode film 120 forms a lower layer portion of the gate finger electrode 115, and covers the interlayer film 70 in the outer peripheral region 9. The second underlying electrode film 120 collectively covers a region of the interlayer film 70 in which the gate openings 94 are formed in a film shape.

That is, the second underlying electrode film 120 enters the gate openings 94 from above the insulating surface 71. The second underlying electrode film 120 includes a portion that covers the insulating surface 71 of the interlayer film 70 in a film shape and a portion that covers the wall surfaces of the gate openings 94 in a film shape. The second underlying electrode film 120 defines a plurality of recesses in the gate openings 94.

The second underlying electrode film 120 has a laminated structure including a first electrode film 123 laminated on the interlayer film 70 and a second electrode film 124 laminated on the first electrode film 123. Preferably, the first electrode film 123 includes the same type of conductive material as the first electrode film 103 on the source side, and the second electrode film 124 includes the same type of conductive material as the second electrode film 104 on the source side. In this embodiment, the first electrode film 123 includes a Ti film, and the second electrode film 124 includes a TiN film.

The second underlying electrode film 120 does not necessarily have a laminated structure, and may have a single layer structure including one of the first electrode film 123 (Ti film) and the second electrode film 124 (TiN film). The first electrode film 123 may have a thickness substantially equal to the thickness of the first electrode film 103 on the source side. The second electrode film 124 may have a thickness substantially equal to the thickness of the second electrode film 104 on the source side.

The first electrode film 123 collectively covers a region of the interlayer film 70 in which the gate openings 94 are formed in a film shape, and enters the gate openings 94 from above the insulating surface 71. That is, the first electrode film 123 includes a portion that covers the insulating surface 71 of the interlayer film 70 in a film shape and a portion that covers the wall surfaces of the gate openings 94 in a film shape.

The first electrode film 123 covers the arc corner portion in a film shape along the arc corner portion of the interlayer film 70 (second oxide film 73), and enters the gate opening 94. That is, the first electrode film 123 includes a portion extending in an arc shape at an arc corner portion. Thereby, the film formability of the first electrode film 123 with respect to the interlayer film 70 (the wall surface of the gate opening 94) is improved. The first electrode film 123 extends along the wall surface of the gate opening 94, and covers the first oxide film 72 and the second oxide film 73.

The first electrode film 123 covers the gate wiring 52 in a film shape at the bottom portion of each gate opening 94, and is electrically connected to the gate wiring 52. Specifically, the first electrode film 123 includes a portion that covers the second silicide portion 60 of the gate wiring 52 in a film shape at the bottom portion of each gate opening 94, and is mechanically and electrically connected to the second silicide portion 60.

The first electrode film 123 is mechanically connected to the second silicide portion 60 at an interval inwardly from the second polysilicon portion 61. That is, the first electrode film 123 is mechanically connected only to the second silicide portion 60, and is not mechanically connected to the second polysilicon portion 61. The first electrode film 123 is electrically connected to the second polysilicon portion 61 via the second silicide portion 60. As a matter of course, the first electrode film 123 (second underlying electrode film 120) may include a portion that is connected to the second polysilicon portion 61.

The second electrode film 124 collectively covers a region of the interlayer film 70 in which the gate openings 94 are formed in a film shape, on the first electrode film 123. That is, the second electrode film 124 includes a portion that covers the insulating surface 71 of the interlayer film 70 in a film shape across the first electrode film 123 and a portion that covers the wall surfaces of the gate openings 94 in a film shape across the first electrode film 123.

The second electrode film 124 covers the arc corner portion of the interlayer film 70 (second oxide film 73) in a film shape along the first electrode film 123, and enters the gate opening 94. That is, the second electrode film 124 includes a portion extending in an arc shape at the arc corner portion of the interlayer film 70 (second oxide film 73). Thereby, the film formability of the second electrode film 124 with respect to the interlayer film 70 (the wall surface of the gate opening 94) is improved. The second electrode film 124 extends along the wall surface of the gate opening 94, and covers the first oxide film 72 and the second oxide film 73 across the first electrode film 123.

The second electrode film 124 includes a portion that covers the gate wiring 52 in a film shape across the first electrode film 123 at the bottom portion of each gate opening 94, and is electrically connected to the gate wiring 52 via the first electrode film 123. Specifically, the second electrode film 124 includes a portion that covers the second silicide portion 60 of the gate wiring 52 in a film shape across the first electrode film 123, and is electrically connected to the second silicide portion 60 via the first electrode film 123.

The second electrode film 124 is located on the second silicide portion 60 at an interval inwardly from the second polysilicon portion 61. That is, the second electrode film 124 opposes only the second silicide portion 60 across the first electrode film 123, and does not oppose the second polysilicon portion 61. The second electrode film 124 is electrically connected to the second polysilicon portion 61 via the first electrode film 123 and the second silicide portion 60. As a matter of course, the second electrode film 124 may include a portion that opposes the second polysilicon portion 61 across the first electrode film 123.

The second embedded electrodes 121 form a middle layer portion of the gate finger electrode 115, and are respectively embedded in the gate openings 94. The second embedded electrode 121 includes a conductive material different from the conductive material of the second underlying electrode film 120. The second embedded electrode 121 includes at least one of tungsten, molybdenum, a tungsten alloy, and a molybdenum alloy. Preferably, the second embedded electrode 121 includes the same type of conductive material as the conductive material of the first embedded electrode 101. In this embodiment, the second embedded electrode 121 includes tungsten.

In this embodiment, the second embedded electrodes 121 are respectively embedded in a one-to-one correspondence relationship with the gate openings 94 via the single second underlying electrode film 120. The second embedded electrodes 121 are electrically connected to the second silicide portion 60 of the gate wiring 52 via the second underlying electrode film 120 in the gate openings 94.

The second embedded electrodes 121 are located on the second silicide portion 60 at an interval inwardly from the second polysilicon portion 61. That is, the second embedded electrodes 121 oppose only the second silicide portion 60 across the first electrode film 123, and do not oppose the second polysilicon portion 61. The second embedded electrodes 121 are electrically connected to the second polysilicon portion 61 via the second underlying electrode film 120. As a matter of course, the second embedded electrodes 121 may include a portion that opposes the second polysilicon portion 61 across the second underlying electrode film 120.

The second embedded electrode 121 has a second embedded electrode surface 125 exposed from the gate opening 94, and exposes the insulating surface 71. The second embedded electrode surface 125 may be referred to as a “gate embedded electrode surface.” The second embedded electrode 121 is embedded in the gate opening 94 at an interval from the insulating surface 71 toward the first main surface 3 side, and exposes a portion of the second underlying electrode film 120 (the second electrode film 124) that covers the insulating surface 71. That is, the second embedded electrode surface 125 is located on the first main surface 3 side with respect to the insulating surface 71.

The second embedded electrode 121 covers the first oxide film 72 and the second oxide film 73 across the second underlying electrode film 120. The second embedded electrode surface 125 is located on the insulating surface 71 side with respect to the height position of the first oxide film 72. The second embedded electrode 121 includes a portion that covers the arc corner portion of the interlayer film 70 across the second underlying electrode film 120.

The second embedded electrode 121 may be embedded at an interval from the arc corner portion of the interlayer film 70 toward the gate wiring 52 side, and expose the entire region of the arc corner portion. In this case, the second embedded electrode surface 125 may be located on the insulating surface 71 side with respect to the height position of the first oxide film 72. As a matter of course, the second embedded electrode surface 125 may be located on the gate wiring 52 side with respect to the height position of the first oxide film 72.

The second main electrode film 122 forms an upper layer portion of the gate finger electrode 115, and covers the second underlying electrode film 120 and the second embedded electrodes 121 in a film shape. The second main electrode film 122 includes a conductive material different from the conductive material of the second underlying electrode film 120 and the conductive material of the second embedded electrode 121.

The second main electrode film 122 may include at least one of an Al film, an Al alloy film, a Cu film, and a Cu alloy film. The Al alloy film may include at least one of an AlSi alloy film, an AlCu alloy film, and an AlSiCu alloy film. Preferably, the second main electrode film 122 includes the same type of conductive material as the conductive material of the first main electrode film 102. The second main electrode film 122 may have a thickness substantially equal to the thickness of the first main electrode film 102.

The second main electrode film 122 is mechanically and electrically connected to the second underlying electrode film 120 in a portion that covers the insulating surface 71, and is mechanically and electrically connected to the second embedded electrodes 121 in a portion that covers the gate openings 94. Thereby, the second main electrode film 122 is electrically connected to the second silicide portion 60 via the second underlying electrode film 120 and the second embedded electrodes 121.

The second main electrode film 122 includes a portion that is connected to the second embedded electrode 121 at the height position of the first main surface 3 side with respect to the height position of the insulating surface 71. The second main electrode film 122 is connected to the second embedded electrode surface 125 above the height position of the first oxide film 72. The second main electrode film 122 includes a portion that covers the arc corner portion of the interlayer film 70 across the second underlying electrode film 120. In a case where the second embedded electrode 121 is located below the first oxide film 72, the second main electrode film 122 may be connected to the second embedded electrode 121 in a region below the first oxide film 72.

The film formability of the second main electrode film 122 with respect to the gate openings 94 is improved by the second embedded electrodes 121. Thereby, a current path between the gate wiring 52 (second silicide portion 60) and the second main electrode film 122 is appropriately secured. Such a configuration is effective in suppressing film formation defects caused by the gate openings 94 and reducing wiring resistance.

The semiconductor device 1 includes a gate pad electrode 130 that is arranged on the interlayer film 70. The gate pad electrode 130 is a terminal electrode to which the gate potential is to be applied from the outside. The gate pad electrode 130 may be referred to as a “second pad electrode,” a “second main surface electrode,” a “second terminal electrode,” or the like. The gate pad electrode 130 is arranged in a region between the source pad electrode 95 and the source finger electrode 110 at an interval from the source pad electrode 95 and the source finger electrode 110.

In this embodiment, the gate pad electrode 130 is arranged in a region on the third side surface 5C side with respect to the first pad portion 96, and is interposed between the second pad portion 97 and the third pad portion 98. That is, the gate pad electrode 130 opposes the first pad portion 96 in the first direction X, and opposes the second pad portion 97 and the third pad portion 98 in the second direction Y.

The gate pad electrode 130 is formed in a polygonal shape (in this embodiment, quadrangular shape) having four sides parallel to the peripheral edge of the chip 2 in a plan view. The gate pad electrode 130 has a planar area smaller than a planar area of the source pad electrode 95 (first pad portion 96). The gate pad electrode 130 may have a planar area smaller than the planar area of the second pad portion 97 (third pad portion 98).

The gate pad electrode 130 is arranged on a portion that covers the active region 8 and the outer peripheral region 9, and is connected to the gate finger electrode 115. The gate pad electrode 130 may cover the gate electrodes 32 across the interlayer film 70, or may cover the gate wiring 52 across the interlayer film 70.

Similarly to the gate finger electrode 115, the gate pad electrode 130 includes the second underlying electrode film 120 and the second main electrode film 122. The second underlying electrode film 120 forms a lower layer portion of the gate pad electrode 130, and covers the interlayer film 70 in a film shape.

Similarly to the gate finger electrode 115, the second underlying electrode film 120 has the laminated structure including the first electrode film 123 and the second electrode film 124. The first electrode film 123 covers the interlayer film 70 in a film shape, and the second electrode film 124 covers the first electrode film 123 in a film shape. The second main electrode film 122 forms an upper layer portion of the gate pad electrode 130, and covers the second underlying electrode film 120 in a film shape.

Although not specifically illustrated, the gate pad electrode 130 may include a plurality of second embedded electrodes 121 similarly to the gate finger electrode 115. In this case, similarly to the gate finger electrode 115, the gate pad electrode 130 may be electrically connected to the gate wiring 52 (second silicide portion 60) via the second embedded electrodes 121.

In a case where the gate electrodes 32 are arranged below the gate pad electrode 130, the gate pad electrode 130 may be electrically connected to the gate electrodes 32 (first silicide portion 40) via the second embedded electrodes 121. As a matter of course, the gate pad electrode 130 may not include the second embedded electrodes 121. That is, the gate pad electrode 130 may not include an electrical connection portion with respect to the gate electrodes 32 and an electrical connection portion with respect to the gate wiring 52 in the region immediately below.

The gate potential applied to the gate pad electrode 130 is to be applied to the second silicide portion 60 of the gate wiring 52 via the gate finger electrode 115. The gate potential is to be transmitted from the second silicide portion 60 to the first silicide portions 40 of the gate electrodes 32 via a wiring path (current path) along the gate wiring 52.

Thereby, the gate electrodes 32 are turned on, and on/off of the channel regions 26 and 27 is controlled. The wiring resistance (gate resistance) caused by the polysilicon of the gate electrode 32 is reduced by the first silicide portion 40. Similarly, the wiring resistance (gate resistance) caused by the polysilicon of the gate wiring 52 is reduced by the second silicide portion 60.

The semiconductor device 1 includes a drain pad electrode 140 that covers the second main surface 4. The drain pad electrode 140 is a terminal electrode to which a drain potential is to be applied from the outside. The drain pad electrode 140 may be referred to as a “third pad electrode,” a “third main surface electrode,” a “third terminal electrode,” or the like.

The drain pad electrode 140 is electrically connected to the second semiconductor region 7. The drain pad electrode 140 may cover the entire region of the second main surface 4 such as to be continuous with the peripheral edge (the first to fourth side surfaces 5A to 5D) of the second main surface 4. The drain pad electrode 140 may partially cover the second main surface 4 such as to expose a peripheral edge portion of the second main surface 4.

A breakdown voltage that can be applied between the source pad electrode 95 and the drain pad electrode 140 (between the first main surface 3 and the second main surface 4) may be in a range of 500 V or higher and 3000 V or lower. The breakdown voltage may have a value in at least one range among a range of 500 V or higher and 1000 V or lower, a range of 1000 V or higher and 1500 V or lower, a range of 1500 V or higher and 2000 V or lower, a range of 2000 V or higher and 2500 V or lower, and a range of 2500 V or higher and 3000 V or lower.

As described above, the semiconductor device 1 includes the chip 2, the gate electrode 32, the first silicide portion 40, and the first polysilicon portion 41. The chip 2 has the first main surface 3. The gate electrode 32 is arranged on the first main surface 3. The gate electrode 32 includes polysilicon, and has the electrode surface 33.

The first silicide portion 40 is partially formed in the surface portion of the electrode surface 33. The first polysilicon portion 41 is formed in a portion other than the first silicide portion 40 in the surface portion of the electrode surface 33. According to this configuration, the wiring resistance (gate resistance) of the gate electrode 32 is reduced by the first silicide portion 40.

The gate electrode 32 has the first side wall 34 and the second side wall 35. Preferably, the first silicide portion 40 is formed at an interval inwardly from at least one of the first side wall 34 and the second side wall 35. That is, preferably, the first polysilicon portion 41 is exposed from at least one of the first side wall 34 and the second side wall 35.

According to this configuration, in the producing process of the gate electrode 32 (polysilicon etching process), the first silicide portion 40 is not removed on at least one side of the first side wall 34 and the second side wall 35. Thereby, metal contamination (metal particle contamination) of other structures on the first main surface 3 and metal contamination (metal particle contamination) of a producing device due to etching of the first silicide portion 40 are suppressed.

For example, in a case where the gate electrodes 32 are arranged at a narrow pitch, it is difficult to eliminate metal contamination in a region on a side of the gate electrode 32 (a region having a relatively narrow width between the gate electrodes 32). Therefore, the configuration according to the semiconductor device 1 is effective in suppressing metal contamination in a region on a side of the gate electrode 32 (a region having a relatively narrow width between the gate electrodes 32) in a case where the gate electrodes 32 are arranged at a narrow pitch.

In particular, in the case of the semiconductor device 1 including SiC, an extremely high voltage is applied due to characteristics (physical properties) of SiC, unlike a lateral type Si semiconductor device such as an LSI. The metal contamination on the first main surface 3 may have an unexpected impact on the electrical characteristics of the semiconductor device 1 due to the high voltage. Therefore, by eliminating an occurrence of metal contamination on the first main surface 3, the semiconductor device 1 having appropriate electrical characteristics is provided.

In this case, preferably, the first silicide portion 40 is formed at intervals inwardly from both of the first side wall 34 and the second side wall 35. That is, preferably, the first polysilicon portion 41 is exposed from both of the first side wall 34 and the second side wall 35. According to this configuration, metal contamination on the first main surface 3 caused by the first silicide portion 40 is appropriately suppressed.

Preferably, the first silicide portion 40 is formed at intervals inwardly from both of the first side wall 34 and the second side wall 35 in the entire surface portion of the electrode surface 33. That is, preferably, the first polysilicon portion 41 is exposed from both of the first side wall 34 and the second side wall 35 in the entire surface portion of the electrode surface 33.

The first polysilicon portion 41 may form the flat electrode surface 33 together with the first silicide portion 40 (refer to FIG. 7). The first polysilicon portion 41 may be recessed toward the first main surface 3 side with respect to the first silicide portion 40 (refer to FIG. 10A). The first polysilicon portion 41 may protrude upwardly from the first silicide portion 40 (refer to FIG. 10B). The first silicide portion 40 may be formed in the surface portion of the electrode surface 33 at an interval from the intermediate portion of the gate electrode 32 toward the electrode surface 33 side in the thickness direction.

The semiconductor device 1 may include the gate wiring 52 that is selectively drawn onto the first main surface 3 so as to be connected to the gate electrode 32. The gate wiring 52 includes polysilicon, and has the wiring surface 53.

In such a configuration, the semiconductor device 1 may include the second silicide portion 60 and the second polysilicon portion 61. The second silicide portion 60 is formed in the surface portion of the wiring surface 53. The second polysilicon portion 61 is formed in a portion other than the second silicide portion 60 in the surface portion of the wiring surface 53. According to this configuration, the wiring resistance of the gate wiring 52 is reduced by the first silicide portion 40.

Preferably, the second silicide portion 60 is connected to the first silicide portion 40 at the connection portion between the gate electrode 32 and the gate wiring 52. Preferably, the second polysilicon portion 61 is connected to the first polysilicon portion 41 at the connection portion between the gate electrode 32 and the gate wiring 52. According to this configuration, a wiring path that reaches the first silicide portion 40 via the second silicide portion 60 is formed. Thereby, the wiring resistance is appropriately reduced in both of the gate electrode 32 and the gate wiring 52.

The gate wiring 52 includes the first wiring side wall 54 and the second wiring side wall 55. Preferably, the second silicide portion 60 is formed at an interval inwardly from at least one of the first wiring side wall 54 and the second wiring side wall 55. That is, preferably, the second polysilicon portion 61 is exposed from at least one of the first wiring side wall 54 and the second wiring side wall 55.

According to this configuration, in a manufacturing step of the gate wiring 52 (polysilicon etching process), the second silicide portion 60 is not removed on at least one side of the first wiring side wall 54 and the second wiring side wall 55. Thereby, metal contamination (metal particle contamination) of other structures on the first main surface 3 and metal contamination (metal particle contamination) of a manufacturing equipment due to an etching process of the second silicide portion 60 are suppressed. Therefore, the semiconductor device 1 having appropriate electrical characteristics is provided.

In this case, preferably, the second silicide portion 60 is formed at intervals inwardly from both of the first wiring side wall 54 and the second wiring side wall 55. That is, preferably, the second polysilicon portion 61 is exposed from both of the first wiring side wall 54 and the second wiring side wall 55. According to this configuration, metal contamination on the first main surface 3 caused by the first silicide portion 40 is appropriately suppressed.

Preferably, the second silicide portion 60 is formed at intervals inwardly from both of the first wiring side wall 54 and the second wiring side wall 55 in the entire surface portion of the wiring surface 53. That is, preferably, the second polysilicon portion 61 is exposed from both of the first wiring side wall 54 and the second wiring side wall 55 in the entire region of the surface portion of the wiring surface 53.

The gate electrode 32 may extend in the second direction Y (one direction). In this case, the gate wiring 52 may include a portion extending in the first direction X (intersection direction) intersecting the second direction Y (one direction). That is, the gate wiring 52 may be connected to the gate electrode 32 in a T shape (refer to FIG. 5). The second silicide portion 60 may be connected to the first silicide portion 40 in a T shape (refer to FIG. 5). The second polysilicon portion 61 may be connected to the first polysilicon portion 41 in an L shape at a connection corner portion between the gate electrode 32 and the gate wiring 52 (refer to FIG. 5).

The semiconductor device 1 may include the interlayer film 70. The interlayer film 70 covers the gate electrode 32, and may include the portion in contact with the first silicide portion and the portion in contact with the first polysilicon portion 41. In this case, preferably, the semiconductor device 1 does not have an insulating side wall structure (spacer) that covers the first side wall 34 and the second side wall 35 of the gate electrode 32. That is, preferably, the interlayer film 70 directly covers the first side wall 34 and the second side wall 35 of the gate electrode 32.

The interlayer film 70 covers the gate wiring 52, and may include the portion in contact with the second silicide portion 60 and the portion in contact with the second polysilicon portion 61. In this case, preferably, the semiconductor device 1 does not have an insulating side wall structure (spacer) that covers the first wiring side wall 54 and the second wiring side wall 55 of the gate wiring 52. That is, preferably, the interlayer film 70 directly covers the first wiring side wall 54 and the second wiring side wall 55 of the gate wiring 52.

The interlayer film 70 may have the laminated structure including the first oxide film 72 and the second oxide film 73. The first oxide film 72 may be an oxide film with no impurity added. The first oxide film 72 may include the portion in contact with the first silicide portion 40 and the portion in contact with the first polysilicon portion 41. The second oxide film 73 may be an oxide film containing phosphorus. The second oxide film 73 may include the portion that covers the first silicide portion 40 and the first polysilicon portion 41 across the first oxide film 72.

The first oxide film 72 may include the portion in contact with the second silicide portion 60 and the portion in contact with the second polysilicon portion 61. The second oxide film 73 may be an oxide film containing phosphorus. The second oxide film 73 may include the portion that covers the second silicide portion 60 and the second polysilicon portion 61 across the first oxide film 72.

The semiconductor device 1 may include the first semiconductor region 6 of the n-type, the body region 20 of the p-type, the source region 23, 24 (impurity region) of the n-type, the channel region 26, 27 (channel), and the insulating film 31. The first semiconductor region 6 may be formed in the surface layer portion of the first main surface 3. The body region 20 may be formed in the surface layer portion of the first semiconductor region 6. The source region 23, 24 may be formed in the surface layer portion of the body region 20.

The channel region 26, 27 may be formed in the region between the first semiconductor region 6 and the source region 23, 24 in the surface layer portion of the body region 20. The insulating film 31 may cover the channel region 26, 27 on the first main surface 3. In this case, the gate electrode 32 may oppose the channel region 26, 27 across the insulating film 31.

From another point of view, the semiconductor device 1 includes the chip 2, the gate electrode 32, the interlayer film 70, the source opening 90, the first embedded electrode 101, and the first main electrode film 102. The chip 2 has the first main surface 3. The gate electrode 32 is arranged on the first main surface 3. The interlayer film 70 covers the gate electrode 32, and has the insulating surface 71. The source opening 90 is formed in the interlayer film 70 to be separated from the gate electrode 32, and exposes the first main surface 3.

The first embedded electrode 101 is embedded in the source opening 90, and is electrically connected to the first main surface 3. The first embedded electrode 101 has the first embedded electrode surface 105 exposed from the source opening 90. The first main electrode film 102 is mechanically and electrically connected to the first embedded electrode surface 105 of the first embedded electrode 101. According to this configuration, the film formability of the first main electrode film 102 with respect to the source opening 90 is improved by the first embedded electrode 101.

Preferably, the first embedded electrode 101 is embedded in the source opening 90 such as to expose the insulating surface 71. In this configuration, preferably, the first main electrode film 102 is arranged on the insulating surface 71 of the interlayer film 70 and the first embedded electrode surface 105 of the first embedded electrode 101. According to this configuration, a level difference between the insulating surface 71 and the source opening 90 is reduced by the first embedded electrode 101. Thereby, the film formability of the first main electrode film 102 with respect to the insulating surface 71 of the interlayer film 70 and the first embedded electrode surface 105 of the first embedded electrode 101 is improved.

The first embedded electrode surface 105 of the first embedded electrode 101 may be located on the first main surface 3 side with respect to the insulating surface 71. According to this configuration, it is possible to appropriately suppress the first embedded electrode 101 from protruding above the insulating surface 71. In this case, the first main electrode film 102 may be connected to the first embedded electrode surface 105 of the first embedded electrode 101 that is located on the first main surface 3 side with respect to the insulating surface 71.

Preferably, the first embedded electrode surface 105 of the first embedded electrode 101 is located above the electrode surface 33 of the gate electrode 32. According to this configuration, a level difference between the insulating surface 71 and the source opening 90 is reduced to the height position above the electrode surface 33 by the first embedded electrode 101. Thereby, the connection portion of the source main electrode to the first embedded electrode 101 can be located above the electrode surface 33.

The first embedded electrode surface 105 of the first embedded electrode 101 may have the recess 106 toward the chip 2. In this case, preferably, the bottom portion of the recess 106 is located above the height position of the gate electrode 32 (electrode surface 33). Preferably, the source opening 90 has the vertically long aspect ratio D/W along the lamination direction.

According to this configuration, the first embedded electrode 101 is embedded in the source opening 90 having a narrow width. Thereby, the film formability of the first main electrode film 102 with respect to the source opening 90 having a narrow width is improved by the first embedded electrode 101. Further, according to this configuration, an increase in size of the device due to the aspect ratio D/W of the source opening 90 is suppressed.

Preferably, the first embedded electrode 101 includes tungsten. According to this configuration, the first embedded electrode 101 is appropriately embedded in the source opening 90 by using the physical properties of tungsten. The first main electrode film 102 may include aluminum. For example, while the first embedded electrode 101 includes tungsten, the first main electrode film 102 may include aluminum. Such a configuration is effective in improving the film formability of the first main electrode film 102 with respect to the source opening 90 having a narrow width in a case where the source opening 90 having a relatively narrow width is formed.

The interlayer film 70 may have the laminated structure including the first oxide film 72 and the second oxide film 73. The first oxide film 72 may be an oxide film with no impurity added. The second oxide film 73 may be an oxide film containing phosphorus. In this case, the source opening 90 may penetrate the first oxide film 72 and the second oxide film 73.

Preferably, the interlayer film 70 has the arc corner portion that is curved in the arc shape in the portion that covers the corner portion of the gate electrode 32. In this configuration, preferably, the source opening 90 has the opening end defined by the arc corner portion. According to this configuration, the embedding property of the first embedded electrode 101 into the source opening 90 is improved by the arc corner portion. Further, the film formability of the first main electrode film 102 with respect to the first embedded electrode 101 (source opening 90) is improved.

The gate electrodes 32 may be arranged at an interval on the first main surface 3. In this case, the source opening 90 may be defined in the region between the gate electrodes 32. According to this configuration, the film formability of the first main electrode film 102 with respect to the source opening 90 defined in the region between the gate electrodes 32 is improved by the first embedded electrode 101.

The semiconductor device 1 may include the first underlying electrode film 100. The first underlying electrode film 100 may cover the wall surface of the source opening 90, and include the portion that is electrically connected to the chip 2 in the source opening 90. In this case, the first embedded electrode 101 may be embedded in the source opening 90 via the first underlying electrode film 100. For example, according to this configuration, the first embedded electrode 101 can be embedded in the source opening 90 with the first underlying electrode film 100 as a barrier film for the chip 2. For example, the first underlying electrode film 100 may include at least one of a Ti film and a TiN film.

The first underlying electrode film 100 may be mechanically and electrically connected to the chip 2. The first embedded electrode 101 may be electrically connected to the chip 2 via the first underlying electrode film 100. The first underlying electrode film 100 may include the portion that covers the insulating surface 71 outside the source opening 90. The first main electrode film 102 may cover the insulating surface 71 across the first underlying electrode film 100. For example, according to this configuration, the first main electrode film 102 can be formed on the interlayer film 70 by using the first underlying electrode film 100 as a barrier film for the interlayer film 70.

The semiconductor device 1 may include the first source silicide portion 108 formed in the surface layer portion of the portion of the first main surface 3 that is exposed from the source opening 90. In this case, the first source silicide portion 108 may be mechanically and electrically connected to the first underlying electrode film 100. According to this configuration, the ohmic property between the chip 2 and the first underlying electrode film 100 (first embedded electrode 101) is improved.

The semiconductor device 1 may include the source recess 91 formed in the portion of the first main surface 3 that is exposed from the source opening 90. In this case, the first underlying electrode film 100 may include the portion that is located in the source recess 91.

The semiconductor device 1 may include the gate wiring 52 that is selectively drawn onto the first main surface 3 and is connected to the gate electrode 32. According to this configuration, a wiring path for the gate electrode 32 is formed by the gate wiring 52.

The semiconductor device 1 may include the gate opening 94, the second embedded electrode 121, and the second main electrode film 122. The gate opening 94 may be formed in the interlayer film 70 such as to expose the gate wiring 52. The second embedded electrode 121 may be embedded in the gate opening 94, and may be electrically connected to the gate wiring 52.

The second embedded electrode 121 may have the second embedded electrode surface 125 exposed from the interlayer film 70. The second main electrode film 122 may be mechanically and electrically connected to the second embedded electrode surface 125. According to this configuration, the film formability of the second main electrode film 122 with respect to the gate opening 94 is improved by the second embedded electrode 121.

The semiconductor device 1 may include the first semiconductor region 6 of the n-type, the body region 20 of the p-type, the source region 23, 24 (first impurity region) of the n-type, the contact region 25 (second impurity region) of the p-type, the channel region 26, 27 (channel), and the insulating film 31.

The first semiconductor region 6 may be formed in the surface layer portion of the first main surface 3. The body region 20 may be formed in the surface layer portion of the first semiconductor region 6. The source region 23, 24 may be formed in the surface layer portion of the body region 20. The contact region 25 may be formed in the region different from the source region 23, 24 in the surface layer portion of the body region 20.

The channel region 26, 27 may be formed in the region between the first semiconductor region 6 and the source region 23, 24 in the surface layer portion of the body region 20. The insulating film 31 may cover the channel region 26, 27 on the first main surface 3. In this case, the gate electrode 32 may oppose the channel region 26, 27 across the insulating film 31. The source opening 90 may expose the source region 23, 24 and the contact region 25. The first embedded electrode 101 may be electrically connected to the source region 23, 24 and the contact region 25 in the source opening 90.

The semiconductor device 1 may include the first silicide portion 40 and the first polysilicon portion 41. The first silicide portion 40 may be partially formed in the surface portion of the gate electrode 32. The first polysilicon portion 41 may be formed in the portion other than the silicide portion in the surface portion of the gate electrode 32. According to this configuration, the wiring resistance (gate resistance) of the gate electrode 32 is reduced by the first silicide portion 40.

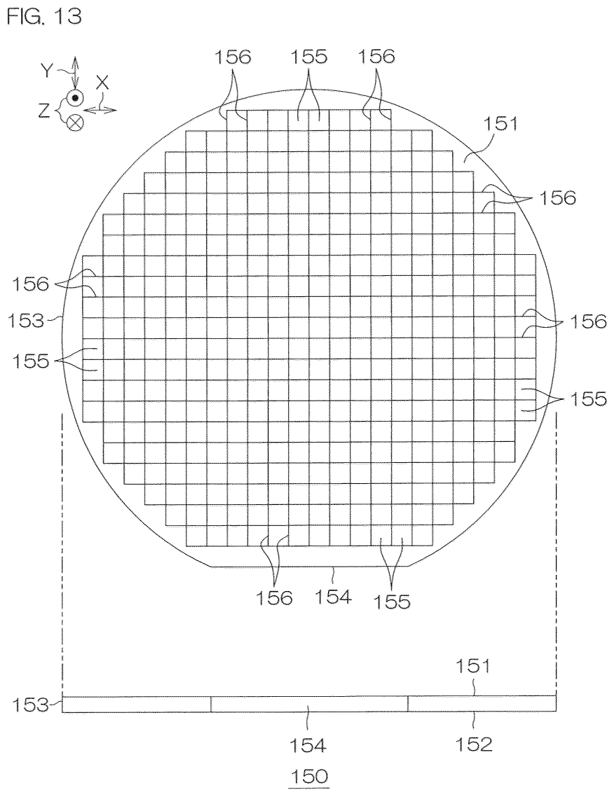

FIG. 13 is a schematic view illustrating a wafer 150 to be used in a manufacturing of the semiconductor device 1. Referring to FIG. 13, the wafer 150 is a base material of the chip 2, and includes the SiC single crystal. The wafer 150 is formed in a flat disc shape. As a matter of course, the wafer 150 may be formed in a flat rectangular parallelepiped shape. The wafer 150 has a first wafer main surface 151 on one side, a second wafer main surface 152 on the other side, and a wafer side surface 153 that connects the first wafer main surface 151 and the second wafer main surface 152.

The first wafer main surface 151 corresponds to the first main surface 3 of the chip 2, and the second wafer main surface 152 corresponds to the second main surface 4 of the chip 2. The first wafer main surface 151 and the second wafer main surface 152 are formed by c-planes of the SiC single crystal. The first wafer main surface 151 is formed by the silicon plane of the SiC single crystal, and the second wafer main surface 152 is formed by the carbon plane of the SiC single crystal. The wafer 150 (the first wafer main surface 151 and the second wafer main surface 152) has the off direction and the off angle described above.

The wafer 150 has, on the wafer side surface 153, a mark 154 that indicates a crystal orientation of the SiC single crystal. The mark 154 may include either or both of an orientation flat and an orientation notch. The orientation flat is made of a notched portion that is notched linearly in a plan view. The orientation notch is made of a notched portion that is notched in a recessed shape (for example, a tapered shape) toward a central portion of the first wafer main surface 151 in a plan view.

The mark 154 may include either or both of a first orientation flat that extends in the m-axis direction and a second orientation flat that extends in the a-axis direction. The mark 154 may include either or both of an orientation notch that is recessed in the m-axis direction and an orientation notch flat that is recessed in the a-axis direction.

The wafer 150 includes the first semiconductor region 6 in a region (surface layer portion) on the first wafer main surface 151 side. The first semiconductor region 6 is formed in a layer shape extending along the first wafer main surface 151. In this embodiment, the first semiconductor region 6 is made of an epitaxial layer (specifically, an SiC epitaxial layer).

The wafer 150 includes the second semiconductor region 7 in a region (surface layer portion) on the second wafer main surface 152 side. The second semiconductor region 7 is formed in a layer shape extending along the second wafer main surface 152, and is electrically connected to the first semiconductor region 6. In this embodiment, the second semiconductor region 7 is made of a wafer body (specifically, an SiC wafer). That is, in this embodiment, the wafer 150 is made of an epitaxial wafer (so-called epi-wafer) having a laminated structure including a wafer body and an epitaxial layer.

For example, in the wafer 150, a plurality of device regions 155 and a plurality of intended cutting lines 156 are set by alignment marks, etc. Each device region 155 is a region corresponding to the semiconductor device 1. The device regions 155 are respectively set in a quadrangle shape in a plan view.

In this embodiment, the device regions 155 are set in a matrix pattern along the first direction X and the second direction Y in a plan view. The device regions 155 are respectively set at an interval inwardly from a peripheral edge of the first wafer main surface 151 in a plan view. The intended cutting lines 156 are set in a lattice pattern that extends along the first direction X and the second direction Y such that the device regions 155 are defined.

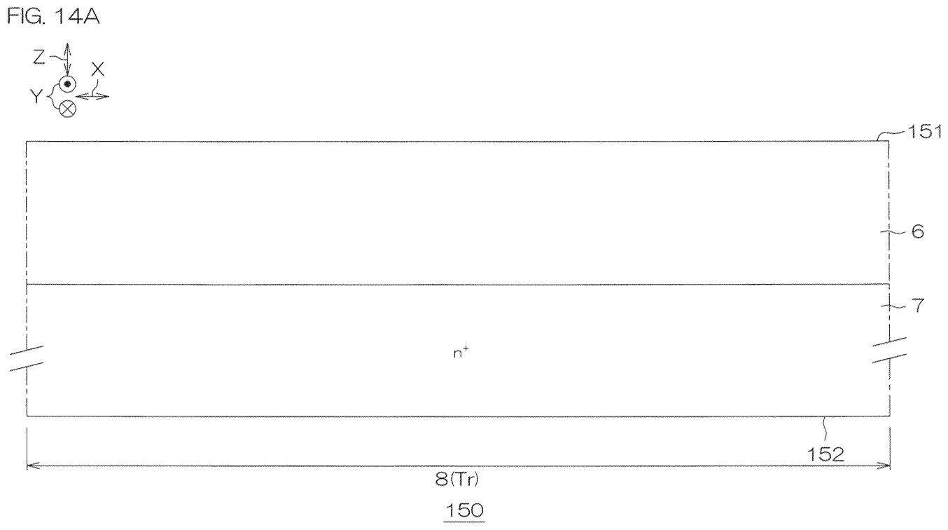

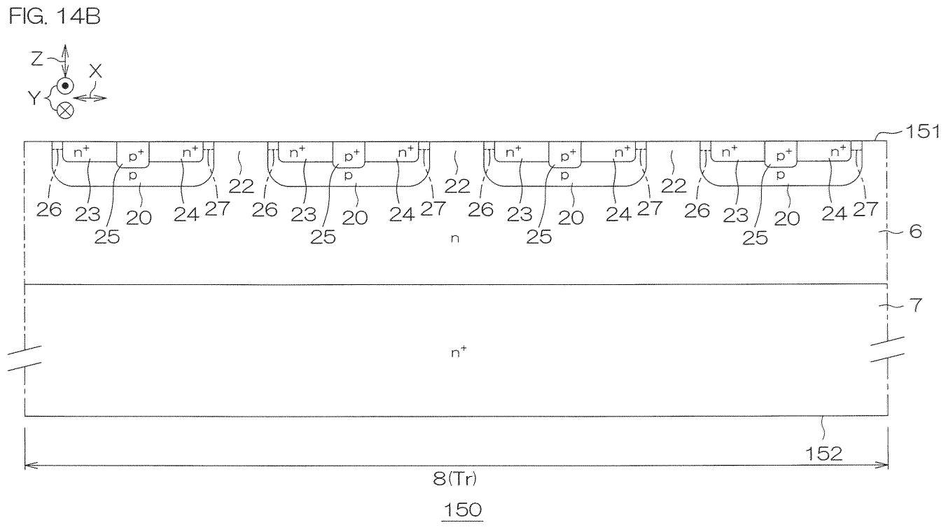

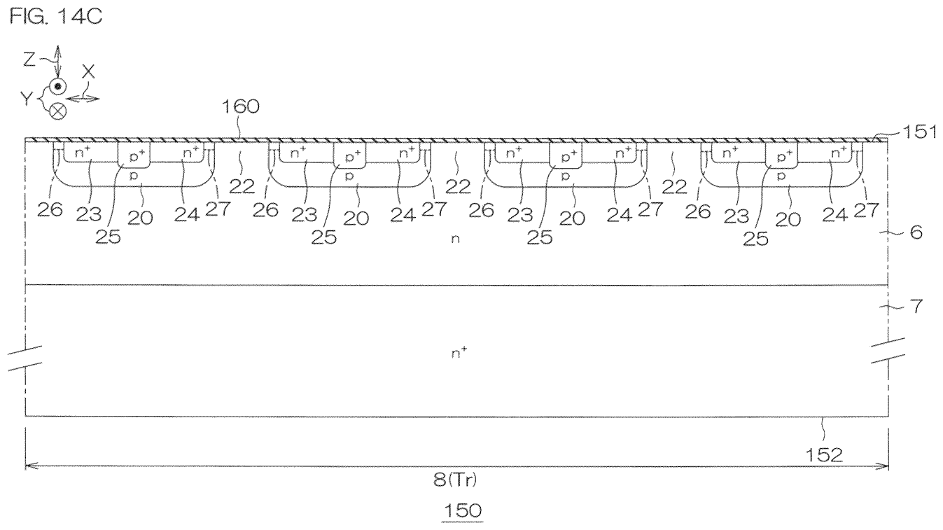

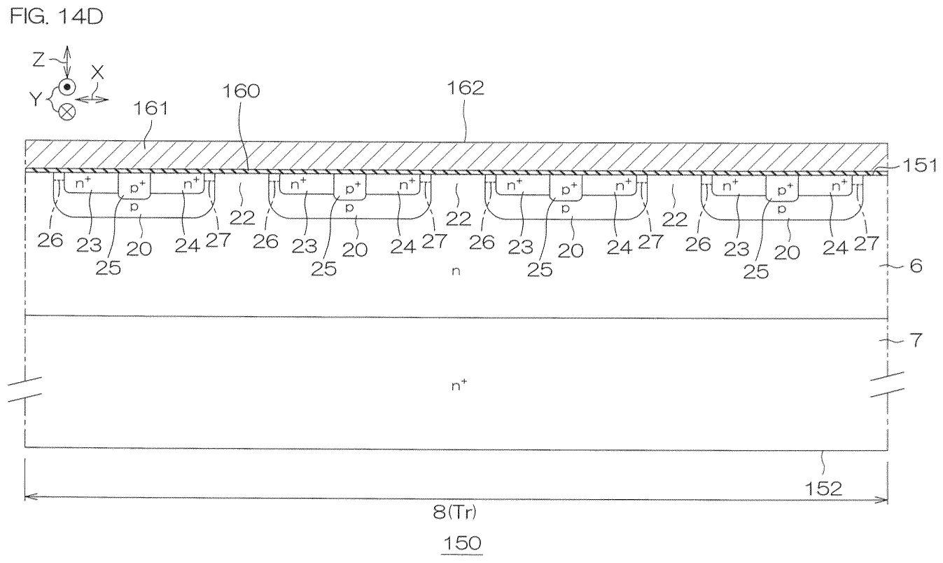

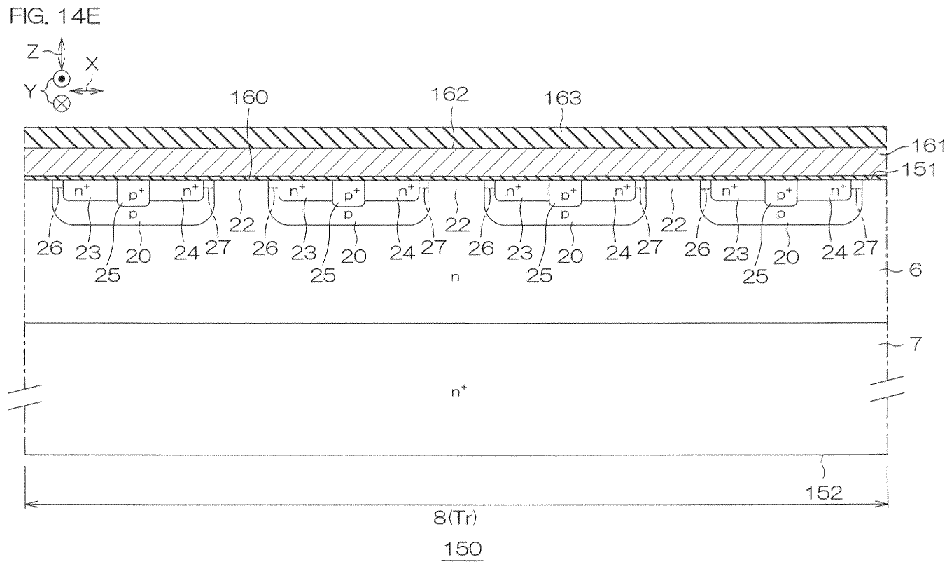

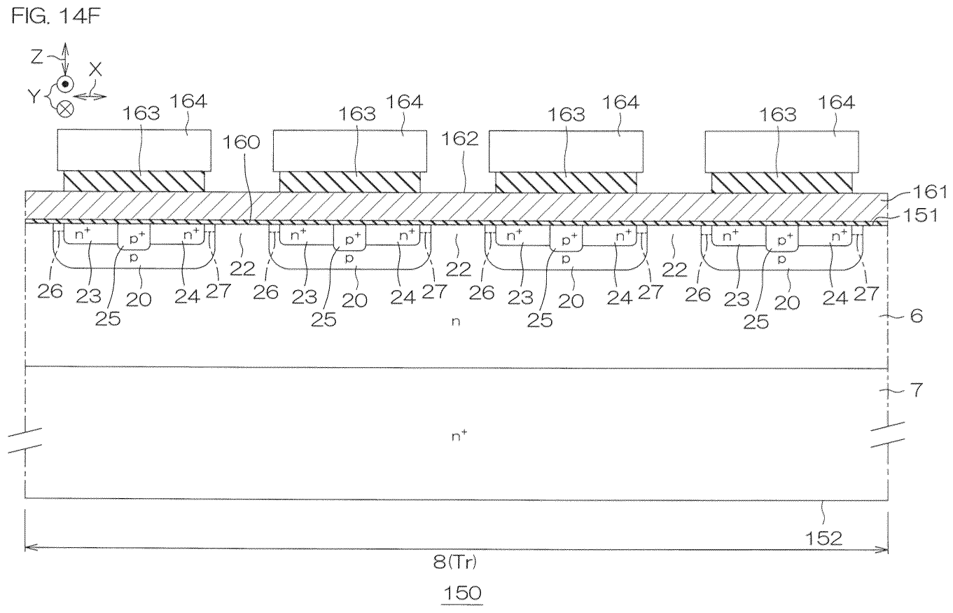

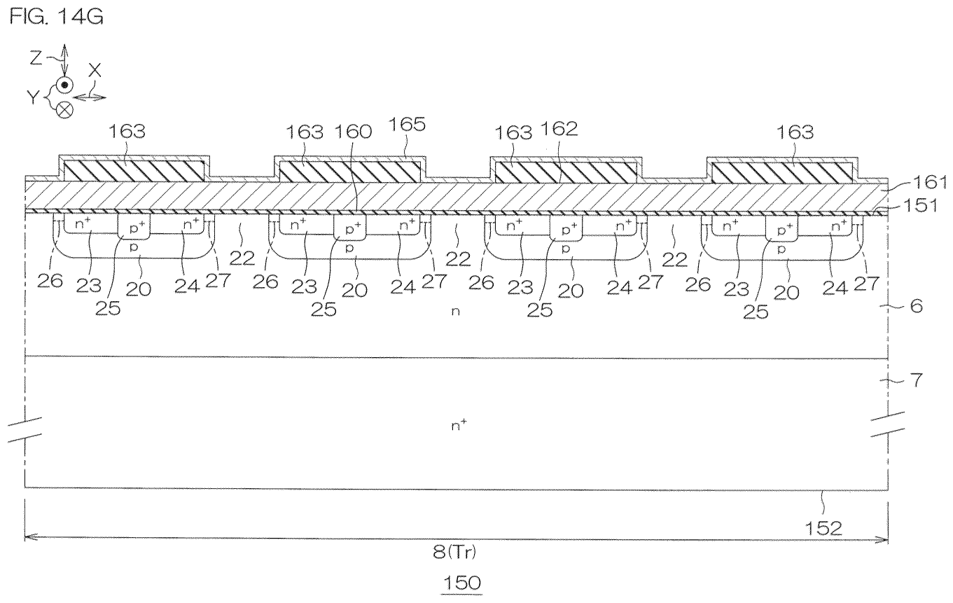

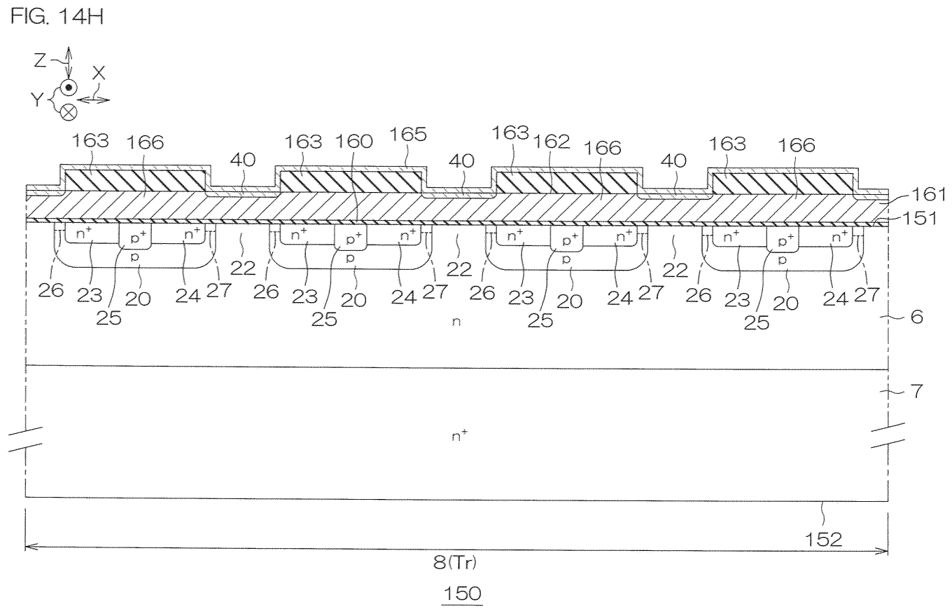

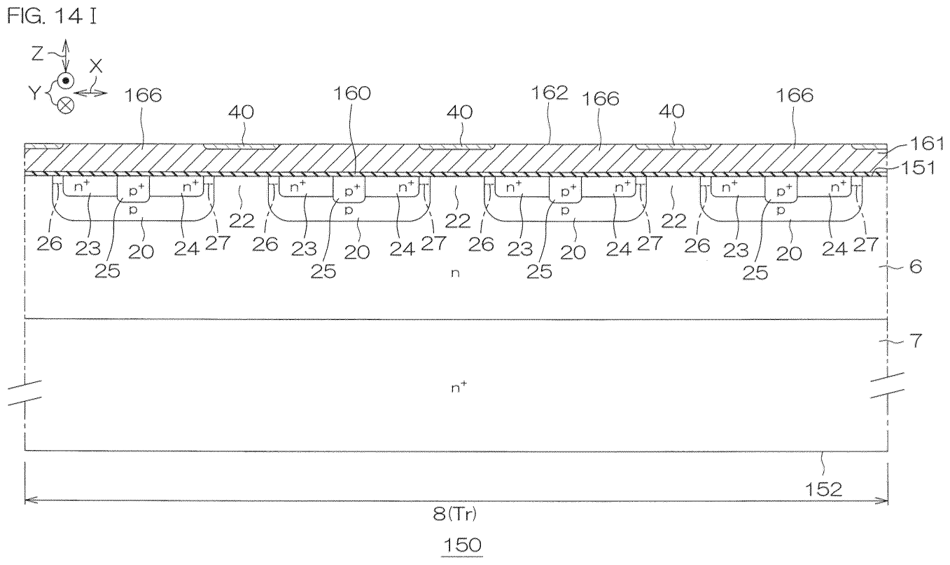

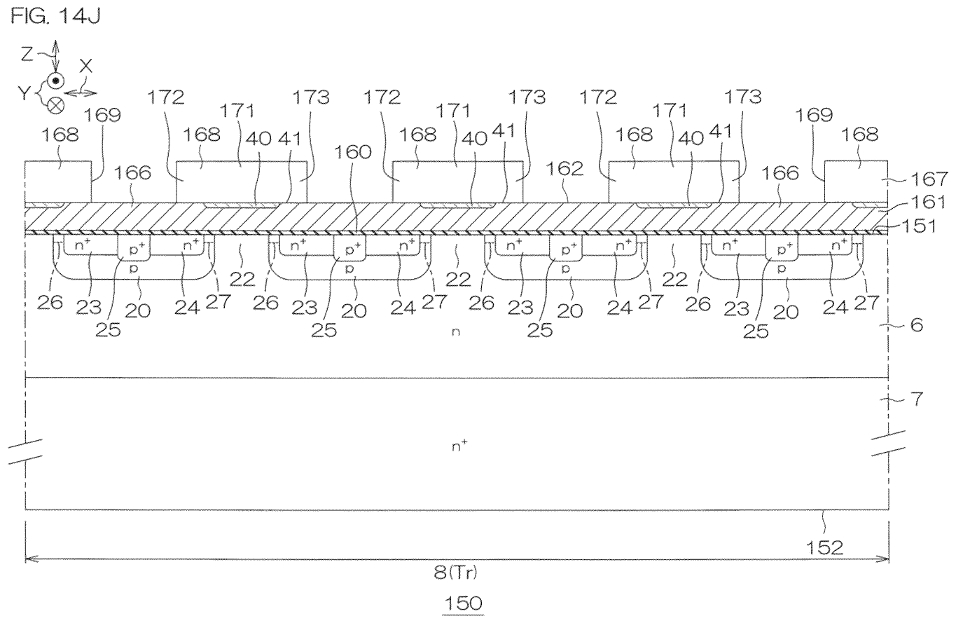

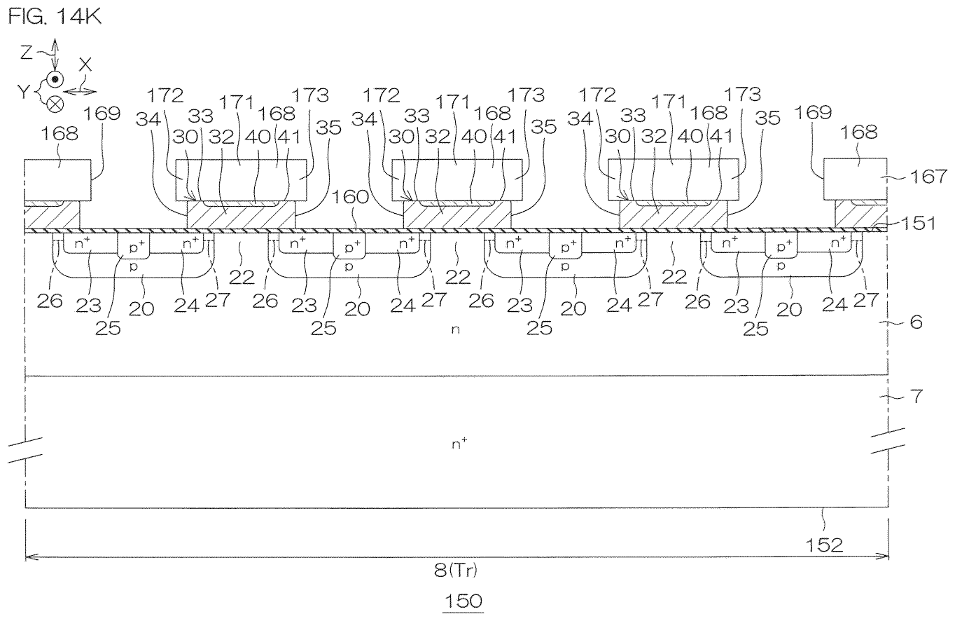

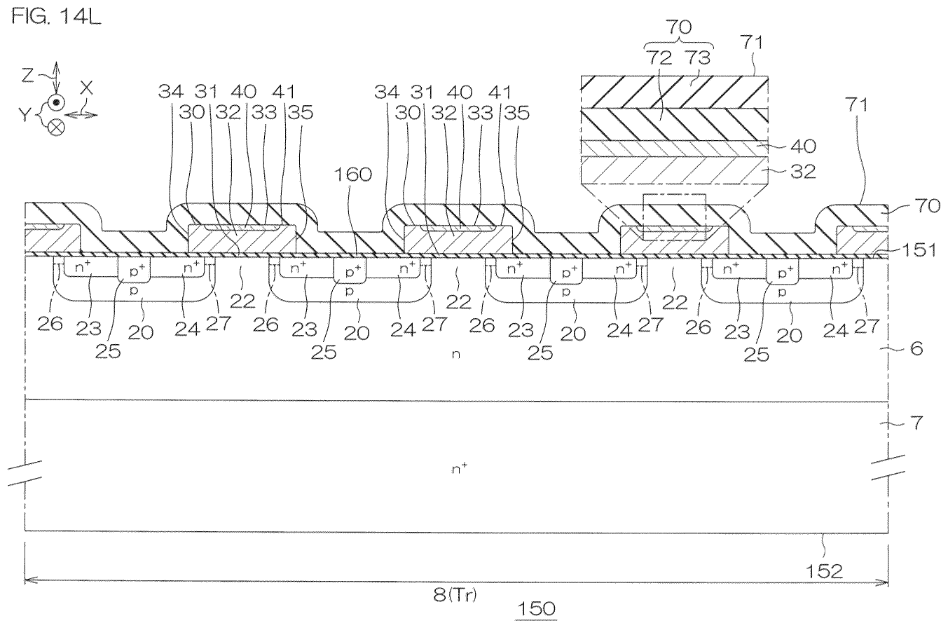

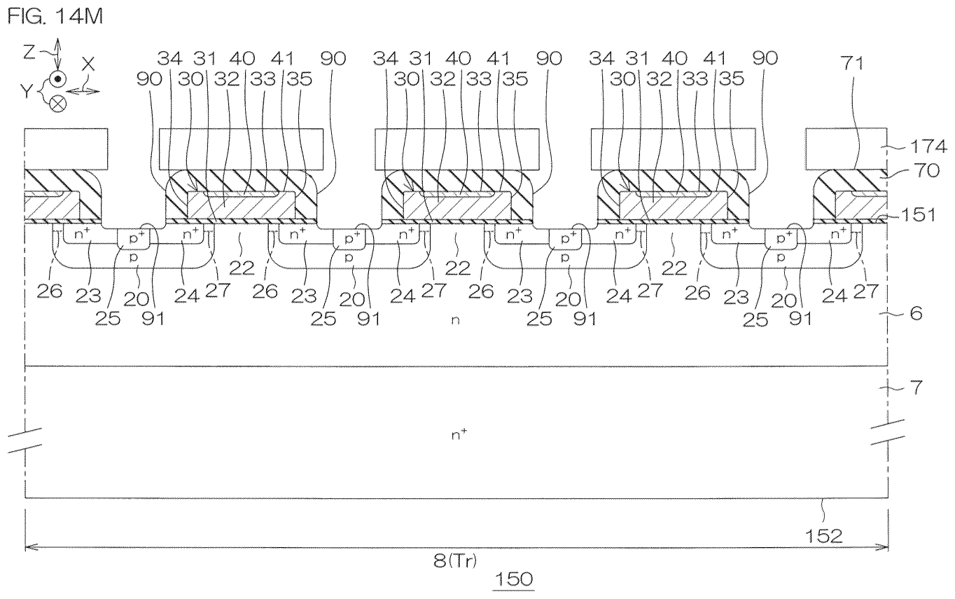

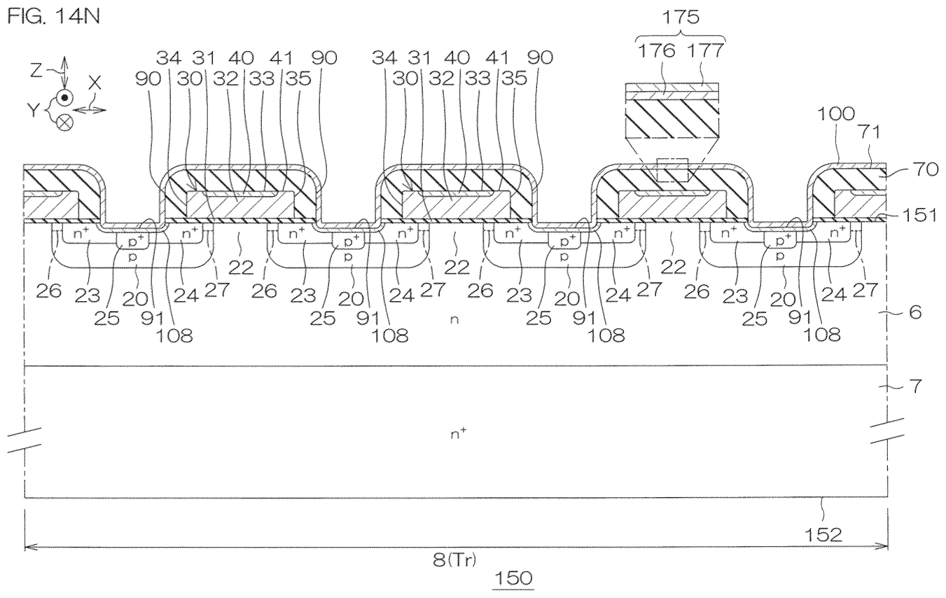

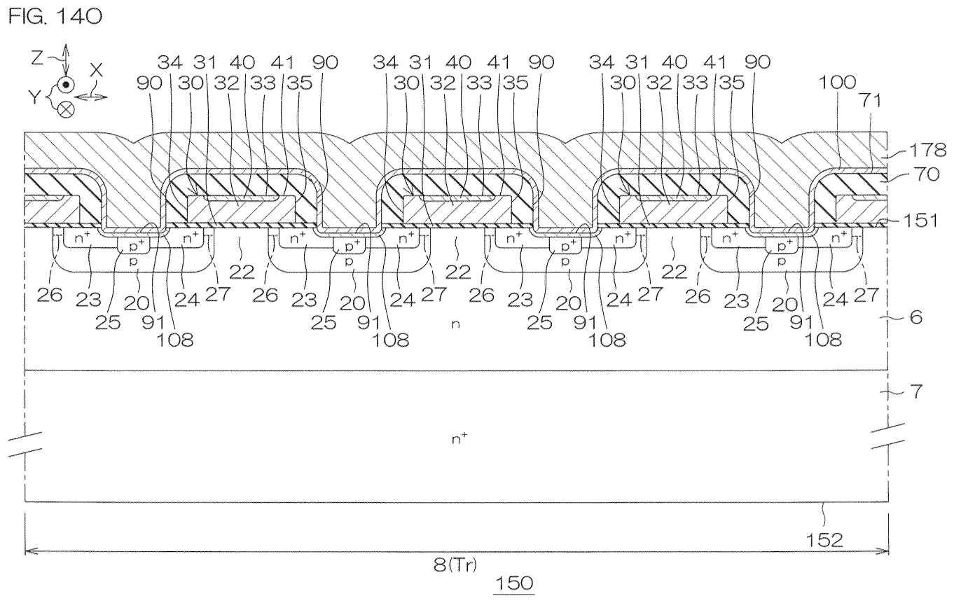

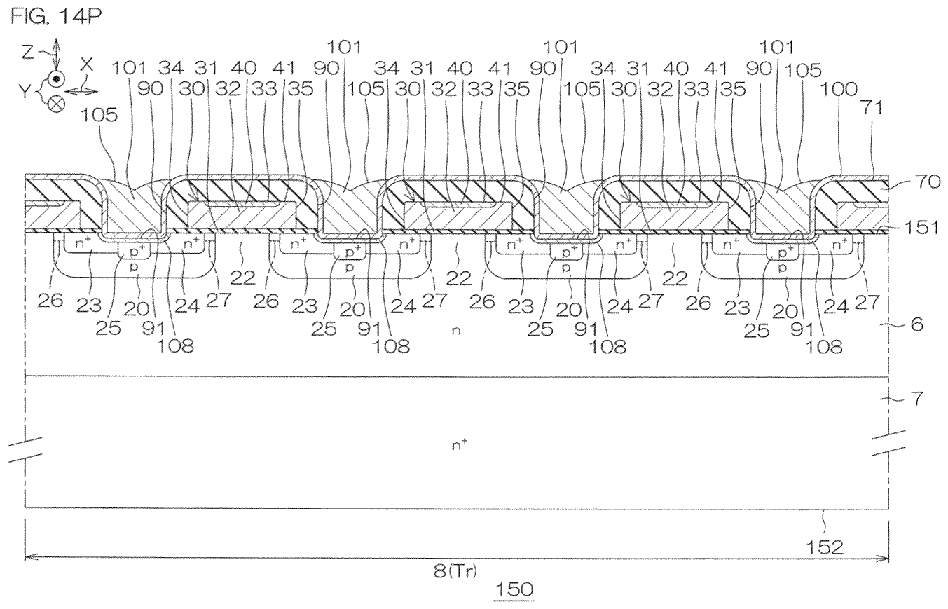

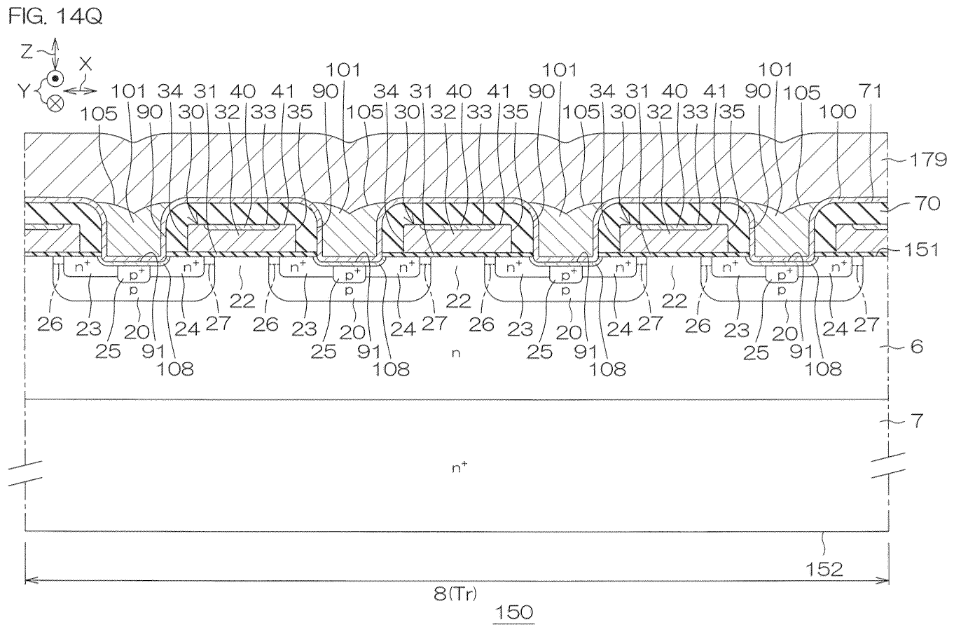

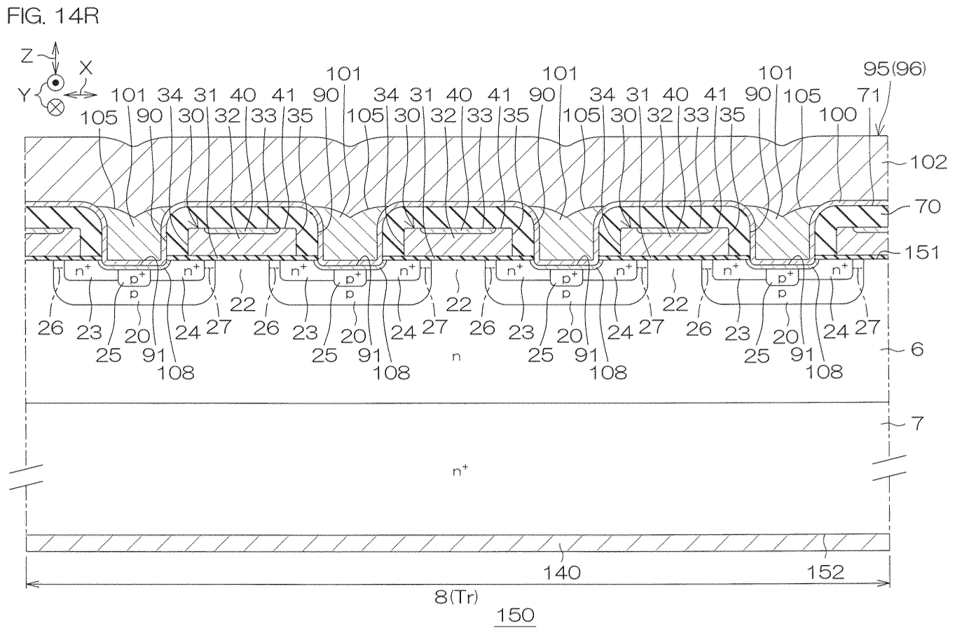

FIG. 14A to FIG. 14R are cross-sectional views illustrating a manufacturing method for the semiconductor device 1. In FIG. 14A to FIG. 14R, cross-sections of a portion of the active region 8 of one device region 155 are illustrated.

Referring to FIG. 14A, first, the above-described wafer 150 is prepared. Next, referring to FIG. 14B, p-type impurities are selectively introduced into the surface layer portion of the first wafer main surface 151 by an ion implantation method through a mask (not illustrated), and the body regions 20 are formed.

Also, p-type impurities are selectively introduced into the surface layer portion of the first wafer main surface 151 by an ion implantation method through a mask (not illustrated), and the outer body region 21 is formed. Also, n-type impurities are selectively introduced into the surface layer portion of the first wafer main surface 151 by an ion implantation method through a mask (not illustrated), and the source regions 23 and 24 are formed.

Also, p-type impurities are selectively introduced into the surface layer portion of the first wafer main surface 151 by an ion implantation method through a mask (not illustrated), and the contact regions 25 are formed. Also, p-type impurities are selectively introduced into the surface layer portion of the first wafer main surface 151 by an ion implantation method through a mask (not illustrated), and the terminal region 45 is formed. Also, p-type impurities are selectively introduced into the surface layer portion of the first wafer main surface 151 by an ion implantation method through a mask (not illustrated), and the field regions 47 are formed.

The order of the forming step of the body regions 20, the forming step of the outer body region 21, the forming step of the source regions 23 and 24, the forming step of the contact regions 25, the forming step of the terminal region 45, and the forming step of the field regions 47 is arbitrary.

The forming step of the outer body region 21 may be performed simultaneously with the forming step of the body regions 20. The forming step of the terminal region 45 may be performed simultaneously with the forming step of the body regions 20 or the forming step of the outer body region 21. The forming step of the field regions 47 may be performed simultaneously with the forming step of the body regions 20, the forming step of the outer body region 21, or the forming step of the terminal region 45.

Next, with reference to FIG. 14C, a base insulating film 160 that covers the first wafer main surface 151 is formed. The base insulating film 160 is a base of the insulating film 31 and the outer peripheral insulating film 51. The base insulating film 160 may be formed by a chemical vapor deposition (CVD) method or an oxidation treatment method (for example, a thermal oxidation treatment method).

Next, referring to FIG. 14D, a base electrode 161 is formed on the base insulating film 160. The base electrode 161 is a base of the gate electrodes 32 and the gate wiring 52. The base electrode 161 includes conductive polysilicon. The base electrode 161 may be formed by a CVD method. The base electrode 161 has a base electrode surface 162 extending along the base insulating film 160.

Next, referring to FIG. 14E, a first mask 163 is formed on the base electrode 161 (base electrode surface 162). Preferably, the first mask 163 is an inorganic mask (that is, a hard mask). The first mask 163 may include at least one among a silicon oxide film, a silicon nitride film, and a silicon oxynitride film. In this embodiment, the first mask 163 is made of a silicon oxide film (insulating film). The first mask 163 may be formed by a CVD method. The first mask 163 may be formed by an oxidation treatment method (for example, a thermal oxidation treatment method) for the base electrode 161.

Next, referring to FIG. 14F, a second mask 164 having a predetermined layout is formed on the first mask 163. The second mask 164 exposes regions in the base electrode surface 162 in which the first silicide portions 40 are to be formed, and covers regions in which the first polysilicon portions 41 are to be formed. Also, the second mask 164 exposes regions in the base electrode surface 162 in which the second silicide portions 60 are to be formed, and covers regions in which the second polysilicon portions 61 are to be formed.

Next, an unnecessary portion of the first mask 163 is removed by an etching method through the second mask 164. The etching method may be a wet etching method and/or a dry etching method. Thereby, the first mask 163 having a predetermined layout for selectively exposing the base electrode 161 is formed on the base electrode 161.

Specifically, the first mask 163 exposes regions of the base electrode 161 (base electrode surface 162) in which the first silicide portions 40 and the second silicide portion 60 are to be formed, and covers regions of the base electrode 161 in which the first polysilicon portions 41 and the second polysilicon portion 61 are to be formed.

In the removing step of the first mask 163, a portion (surface portion) of the base electrode 161 (base electrode surface 162) may be partially removed. In this case, recesses corresponding to the first electrode recess 42 and the second electrode recess 43 (refer to FIG. 10C) of the gate electrode 32 are formed on the base electrode surface 162. Also, recesses corresponding to the first wiring recess 62 and the second wiring recess 63 (refer to FIG. 11C) of the gate wiring 52 are formed on the base electrode surface 162.

As a matter of course, the material of the first mask 163, the type of the etching processing, the process conditions, etc., may be adjusted such that a portion of the base electrode surface 162 is not removed. The second mask 164 is removed after the removing step of the first mask 163. The first mask 163 may be made of an organic mask (that is, a soft mask) instead of the inorganic mask. For example, the first mask 163 may be a resist mask. In these cases, the first mask 163 may be formed with a predetermined layout through an exposure step and a development step.

Next, referring to FIG. 14G, a metal film 165 that partially covers the base electrode surface 162 of the base electrode 161 is formed. The metal film 165 may include at least one of a Ti film, an Ni film, a Co film, an Mo film, and a W film. The metal film 165 may be formed by a sputtering method, a vapor deposition method, or the like. The metal film 165 covers both of the base electrode 161 and the first mask 163. The metal film 165 covers the portions of the base electrode surface 162 of the base electrode 161 that are exposed from the first mask 163.

Next, referring to FIG. 14H, the metal film 165 reacts (silicide reaction) with polysilicon of the base electrode 161, and the portions of the base electrode surface 162 that are in contact with the metal film 165 are made into silicide.

Thereby, the first silicide portions 40 and the second silicide portion 60 are partially formed on the base electrode surface 162. A portion of the base electrode surface 162 other than the first silicide portions 40 and the second silicide portion 60 are formed as a polysilicon portion 166. The silicide reaction may be performed by an annealing method such as a rapid thermal anneal (RTA) method.

In this step, the first silicide portions 40 may be formed to be flat with respect to the base electrode surface 162 (polysilicon portion 166) (refer to FIG. 7). In this step, the first silicide portions 40 may be formed such as to protrude upwardly from the base electrode surface 162 (polysilicon portion 166) (refer to FIG. 10A).

In this step, the second silicide portion 60 may be formed to be flat with respect to the base electrode surface 162 (polysilicon portion 166) (refer to FIG. 9). In this step, the q 60 may be formed such as to protrude upwardly from the base electrode surface 162 (polysilicon portion 166) (refer to FIG. 11A).

Next, referring to FIG. 14I, an unreacted portion of the metal film 165 and the first mask 163 are sequentially removed from the base electrode surface 162. The metal film 165 may be removed by an etching method. The etching method may be a wet etching method and/or a dry etching method.

The first mask 163 may be removed by an etching method. The etching method may be a wet etching method and/or a dry etching method. In a case where the first mask 163 is made of an organic mask, the first mask 163 may be removed by an ashing method.

In the removing step of the metal film 165, the first silicide portions 40 may be partially removed. In this case, the first silicide portions 40 may be removed until the first silicide portions are located on the base insulating film 160 side with respect to the height position of the base electrode surface 162 (polysilicon portion 166) (refer to FIG. 10B).

In the removing step of the metal film 165, the second silicide portion 60 may be partially removed. In this case, the second silicide portion 60 may be removed until the second silicide portion 60 are located on the base insulating film 160 side with respect to the height position of the base electrode surface 162 (polysilicon portion 166) (refer to FIG. 11B).

Next, referring to FIG. 14J, a third mask 167 having a predetermined layout is formed on the base electrode 161 (base electrode surface 162). The third mask 167 may be an organic mask (for example, a resist mask).

The third mask 167 includes a plurality of mask portions 168 that cover regions in which the gate electrodes 32 are to be formed, and has a plurality of openings 169 exposing regions other than the mask portions 168. Each mask portion 168 is formed to be wider than the corresponding first silicide portion 40, and partially covers the polysilicon portion 166 on both sides of the first silicide portion 40.

Specifically, each mask portion 168 includes a first covering portion 171, a second covering portion 172, and a third covering portion 173. The first covering portion 171 covers the entire region of the corresponding first silicide portion 40. The second covering portion 172 protrudes from the first covering portion 171 to one side, and covers a portion of the polysilicon portion 166 as a region where the first polysilicon portion 41 (41A) is to be formed. The third covering portion 173 protrudes from the first covering portion 171 to the other side, and covers a portion of the polysilicon portion 166 as a region where the first polysilicon portion 41 (41B) is to be formed.

Although not specifically illustrated, the third mask 167 includes a mask portion 168 that covers a region where the gate wiring 52 is to be formed. The mask portion 168 for the gate wiring 52 is formed to be wider than the corresponding second silicide portion 60, and partially covers the polysilicon portion 166 on both sides of the second silicide portion 60. That is, the mask portion 168 for the gate wiring 52 includes the first covering portion 171, the second covering portion 172, and the third covering portion 173 similarly to the mask portion 168 for the gate electrode 32.

The first covering portion 171 covers the entire region of the second silicide portion 60. The second covering portion 172 protrudes from the first covering portion 171 to one side, and covers a portion of the polysilicon portion 166 as a region where the second polysilicon portion 61 (61A) is to be formed. The third covering portion 173 protrudes from the first covering portion 171 to the other side, and covers a portion of the polysilicon portion 166 as a region where the second polysilicon portion 61 (61B) is to be formed.

The openings 169 are defined in regions between the mask portions 168. The openings 169 are formed at intervals from the first silicide portions 40 and the second silicide portion 60, and respectively expose portions of the polysilicon portion 166. That is, the openings 169 expose only the polysilicon portion 166, and do not expose the first silicide portions 40 and the second silicide portion 60.

Next, referring to FIG. 14K, an unnecessary portion of the base electrode 161 is removed in the thickness direction. In this step, the base electrode 161 is removed by an etching method through the third mask 167. The etching method may be a wet etching method and/or a dry etching method. In the base electrode 161, the base electrode 161 is removed in the thickness direction from portions of the base electrode surface 162 where the q are exposed.

Thereby, the gate electrodes 32, each of which includes the first silicide portion 40 and the first polysilicon portion 41 as portions of the polysilicon portion 166, are formed. Also, the gate wiring 52 including the second silicide portion 60 and the second polysilicon portion 61 as portions of the polysilicon portion 166 is formed. After the forming step of the gate electrodes 32 and the gate wiring 52, the third mask 167 is removed.

In this step, the first silicide portion 40 and the second silicide portion 60 are protected from etchant by the third mask 167, and are prevented from being etched. That is, in this step, only the polysilicon portion 166 are removed, and the first silicide portion 40 and the second silicide portion 60 are not removed.

Thereby, metal contamination (metal particle contamination) of other structures on the first wafer main surface 151 due to etching of the first silicide portion 40 and the second silicide portion 60 and metal contamination (metal particle contamination) of a producing device (etching device for removing polysilicon) are suppressed.

The removing step of the base electrode 161 may include an over-etching step for the base electrode 161. In the over-etching step, the base electrode 161 is removed until a lower surface of the third mask 167 (mask portion 168) is exposed. The over-etching step is completed before the first silicide portion 40 and the second silicide portion 60 are exposed. That is, in the over-etching step, a state in which an etched surface (etching side wall) of the base electrode 161 opposes the first silicide portion 40 and the second silicide portion 60 across a portion of the polysilicon is maintained.

Next, referring to FIG. 14L, the interlayer film 70 is formed on the first wafer main surface 151. In this step, the interlayer film 70 including the portions that directly cover the electrode surface 33, the first side wall 34, and the second side wall 35 of the gate electrode 32 is formed. Also, the interlayer film 70 including the portions that directly cover the wiring surface 53, the first wiring side wall 54, and the second wiring side wall 55 of the gate wiring 52 is formed.

In this embodiment, the interlayer film 70 has the laminated structure including the first oxide film 72 and the second oxide film 73. The first oxide film 72 includes a silicon oxide film with no impurity added. The second oxide film 73 includes a silicon oxide film containing phosphorus. The first oxide film 72 may be formed by a CVD method. The second oxide film 73 may be formed by a CVD method. After the forming step of the second oxide film 73, a reflow step (heat treatment step) is performed to the interlayer film 70. Thereby, the corner portion and surface roughness of the interlayer film 70 are smoothed.

Next, referring to FIG. 14M, a fourth mask 174 having a predetermined layout is arranged on the interlayer film 70. The fourth mask 174 exposes regions where the source openings 90, the outer openings 92, and the gate openings 94 are to be formed, and covers the other regions.

Next, an unnecessary portion of the interlayer film 70 and an unnecessary portion of the base insulating film 160 are removed by an etching method through the fourth mask 174. In this step, an unnecessary portion of the second oxide film 73, an unnecessary portion of the first oxide film 72, and an unnecessary portion of the base insulating film 160 are removed in this order. The etching method may be a wet etching method and/or a dry etching method. Preferably, the etching method is an anisotropic dry etching method (for example, a reactive ion etching (RIE) method).

Thereby, the source openings 90, the outer openings 92, and the gate openings 94 are formed in the interlayer film 70. Also, the insulating film 31 and the outer peripheral insulating film 51 are formed. This step may include a forming step of the source recesses 91 and a forming step of the outer recesses 93.

In this case, a step of further digging portions of the first wafer main surface 151 that are exposed from the source openings 90 and the outer openings 92 toward the second wafer main surface 152 side is performed. Thereafter, the fourth mask 174 is removed. The reflow step (heat treatment step) for the interlayer film 70 described above may be performed after the forming step of the source openings 90, etc.

Next, referring to FIG. 14N, a base underlying electrode film 175 is formed on the interlayer film 70. The base underlying electrode film 175 is a base of the first underlying electrode film 100 and the second underlying electrode film 120. The base underlying electrode film 175 has a laminated structure including a first base electrode film 176 and a second base electrode film 177. The first base electrode film 176 is a base of the first electrode film 103 and the first electrode film 123. The second base electrode film 177 is a base of the second electrode film 104 and the second electrode film 124.

In this embodiment, the first base electrode film 176 includes a Ti film. The first base electrode film 176 may be formed by a sputtering method or a vapor deposition method. The first base electrode film 176 is formed in a film shape along the insulating surface 71 of the interlayer film 70, the wall surfaces of the source openings 90, the wall surfaces of the outer openings 92, and the wall surfaces of the gate openings 94.

In this embodiment, the second base electrode film 177 includes a TiN film. The second base electrode film 177 may be formed by a sputtering method or a vapor deposition method. The second base electrode film 177 is formed in a film shape along the insulating surface 71 of the interlayer film 70, the wall surfaces of the source openings 90, the wall surfaces of the outer openings 92, and the wall surfaces of the gate openings 94.

After the forming step of the first base electrode film 176, the first base electrode film 176 reacts (silicide reaction) with SiC on the first wafer main surface 151, and the first source silicide portions 108 and the second source silicide portions 111 are formed. The silicide reaction may be performed by an annealing method such as an RTA method.

The forming step of the first source silicide portions 108 (second source silicide portions 111) may be performed prior to the forming step of the second electrode film 104 (second electrode film 124). The forming step of the first source silicide portions 108 (second source silicide portions 111) may be performed after the forming step of the second electrode film 104 (second electrode film 124).

As a matter of course, the first source silicide portions 108 (second source silicide portions 111) including silicide other than Ti silicide may be formed. In this case, prior to the forming step of the first base electrode film 176, a step of making portions of the wafer 150 into silicide by using a metal film (not illustrated) is performed. The metal film may include at least one of an Ni film, a Co film, an Mo film, and a W film. The metal film may be formed by a sputtering method or a vapor deposition method.

Next, with reference to FIG. 14O, a base intermediate electrode film 178 is formed on the base underlying electrode film 175. The base intermediate electrode film 178 includes at least one of tungsten, molybdenum, a tungsten alloy, and a molybdenum alloy. In this embodiment, the base intermediate electrode film 178 includes tungsten.

The base intermediate electrode film 178 may be formed by a CVD method (for example, a reduced pressure CVD method). The base intermediate electrode film 178 backfills the source openings 90, the outer openings 92, and the gate openings 94, and covers the insulating surface 71 of the interlayer film 70 in a film shape.

Next, referring to FIG. 14P, an unnecessary portion of the base intermediate electrode film 178 is removed by an etching method (etch-back method). The etching method may be a wet etching method and/or a dry etching method.

The unnecessary portion of the base intermediate electrode film 178 is removed until the base underlying electrode film 175 is exposed. Thereby, the first embedded electrodes 101 are embedded in the source openings 90. Also, the first embedded electrodes 101 are embedded in the outer openings 92. Also, the second embedded electrodes 121 are embedded in the gate openings 94.

The first embedded electrodes 101 (refer to FIG. 9, FIG. 12A to FIG. 12D) according to the first to fifth examples are formed by adjusting an etching amount of the base intermediate electrode film 178 in this step. The source intermediate electrode 107 according to the fifth example is formed by omitting etching processing on the base intermediate electrode film 178. The source intermediate electrode 107 according to the fifth example is also formed by finishing the etching processing on the base intermediate electrode film 178 before the exposure of the base underlying electrode film 175.

Next, referring to FIG. 14Q, a base main electrode film 179 is formed on the base underlying electrode film 175, the first embedded electrodes 101, and the second embedded electrodes 121. The base main electrode film 179 is a base of the first main electrode film 102 and the second main electrode film 122.

The base main electrode film 179 may include at least one of an Al film, an Al alloy film, a Cu film, and a Cu alloy film. The Al alloy film may include at least one of an AlSi alloy film, an AlCu alloy film, and an AlSiCu alloy film. The base main electrode film 179 may be formed by a sputtering method or a vapor deposition method.

Next, the base main electrode film 179 is divided into the source pad electrode 95, the source finger electrode 110, the gate finger electrode 115, and the gate pad electrode 130. In this step, a mask (not illustrated) having a predetermined layout is formed on the base main electrode film 179. The mask (not illustrated) covers regions where the source pad electrode 95, the source finger electrode 110, the gate finger electrode 115, and the gate pad electrode 130 are to be formed, and exposes regions other than these regions.

Next, an unnecessary portion of the base main electrode film 179 is removed by an etching method through the mask (not illustrated). The unnecessary portion of the base main electrode film 179 is removed until the base underlying electrode film 175 is exposed. The etching method may be a wet etching method and/or a dry etching method. The mask (not illustrated) is removed after the etching step of the base main electrode film 179.

Next, an unnecessary portion of the base underlying electrode film 175 is removed by an etching method through the base main electrode film 179. The unnecessary portion of the base underlying electrode film 175 is removed until the interlayer film 70 (insulating surface 71) is exposed. The removing step of the base underlying electrode film 175 includes a removing step of the second base electrode film 177 by an etching method and a removing step of the first base electrode film 176 by an etching method. The etching method may be a wet etching method and/or a dry etching method.

As a matter of course, the unnecessary portion of the base underlying electrode film 175 may be removed by an etching method through a mask (not illustrated) for the etching step of the base main electrode film 179. Thereby, the source pad electrode 95, the source finger electrode 110, the gate finger electrode 115, and the gate pad electrode 130 are formed on the interlayer film 70.

Next, referring to FIG. 12R, the drain pad electrode 140 is formed on the second wafer main surface 152. The drain pad electrode 140 may be formed by a sputtering method or a vapor deposition method. Thereafter, the wafer 150 is cut according to the intended cutting lines 156, and the semiconductor devices 1 are cut out. The semiconductor device 1 is produced through the steps including the above.

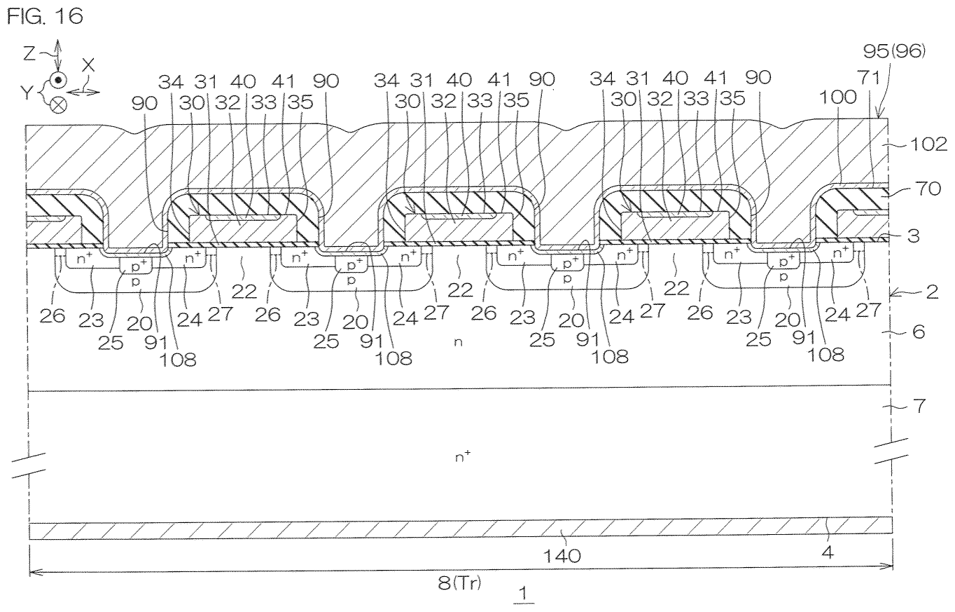

Hereinafter, a modification example of the semiconductor device 1 will be described. FIG. is a cross-sectional view illustrating a first modification example of the semiconductor device 1. FIG. 16 is a cross-sectional view illustrating a second modification example of the semiconductor device 1.

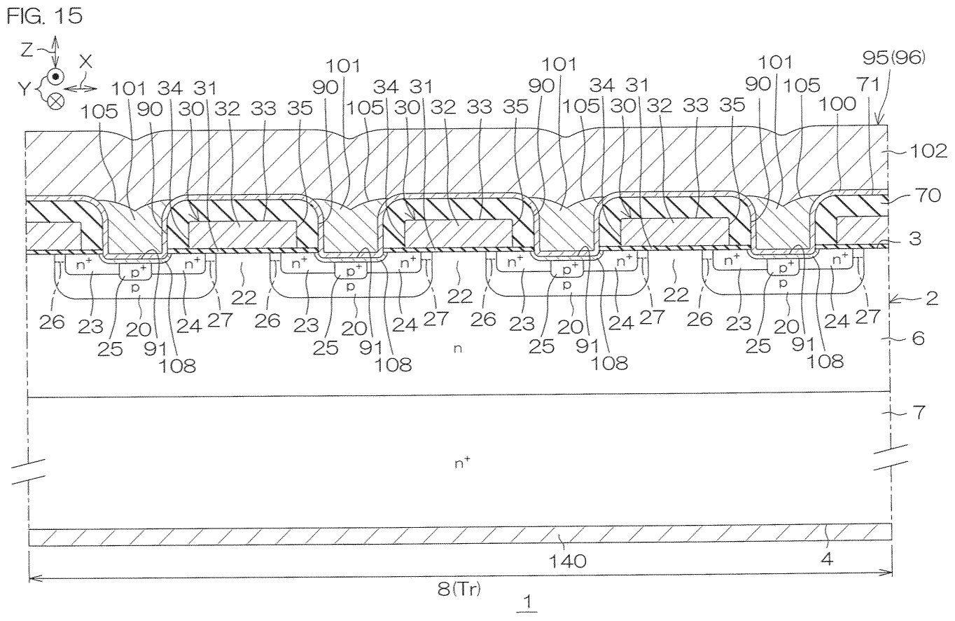

Referring to FIG. 15, the semiconductor device 1 does not necessarily include the first silicide portions 40 (first polysilicon portion 41) in the gate electrodes 32. Similarly, the semiconductor device 1 does not necessarily include the second silicide portion 60 (second polysilicon portion 61) in the gate wirings 52.

The semiconductor device 1 includes the first silicide portions 40 (first polysilicon portion 41), but may not include the second silicide portion 60 (second polysilicon portion 61). The semiconductor device 1 includes the second silicide portion 60 (second polysilicon portion 61), but may not include the first silicide portions 40 (first polysilicon portion 41).

Referring to FIG. 16, the semiconductor device 1 does not necessarily include the first embedded electrodes 101. In this case, the first main electrode film 102 for the source pad electrodes 95 enters the source openings 90 from above the interlayer film 70, and is electrically connected to the body regions 20, etc., in the source openings 90. The first main electrode film 102 for the source finger electrodes 110 enters the outer openings 92 from above the interlayer film 70, and is electrically connected to the terminal region 45 (overlap region 46) in the outer openings 92.

Similarly, the semiconductor device 1 does not necessarily include the second embedded electrodes 121. In this case, the gate finger electrodes 115 enter the gate openings 94 from above the interlayer film 70, and are electrically connected to the gate wirings 52 in the gate openings 94.

The semiconductor device 1 may include the first embedded electrodes 101 for the source pad electrodes 95, but may not include the first embedded electrodes 101 for the source finger electrodes 110. The semiconductor device 1 may include the first embedded electrodes 101 for the source finger electrodes 110, but may not include the first embedded electrodes 101 for the source pad electrodes 95.

The semiconductor device 1 includes the first embedded electrodes 101 for the source pad electrodes 95, but may not include the second embedded electrodes 121. The semiconductor device 1 may include the second embedded electrodes 121, but may not include the first embedded electrodes 101 for the source pad electrodes 95. The semiconductor device 1 may include the first embedded electrodes 101 for the source finger electrodes 110, but may not include the second embedded electrodes 121. The semiconductor device 1 may include the second embedded electrodes 121, but may not include the first embedded electrodes 101 for the source finger electrodes 110.

The above-described embodiments (including the modification examples) can be implemented in still other forms. For example, in the above-described embodiment, a configuration in which the relationship between the a-axis direction and the m-axis direction is interchanged may be adopted. A specific configuration in this case can be obtained by interchanging the “a-axis direction (off direction)” and the “m-axis direction (direction orthogonal to off direction)” in the above description and the accompanying drawings.

In the above-described embodiments, a structure in which the conductivity type of the “n-type” semiconductor region is inverted to the “p-type” and the conductivity type of the “p-type” semiconductor region is inverted to the “n-type” may be adopted. A specific configuration in this case can be obtained by replacing the “n-type” with the “p-type” at the same time as replacing the “p-type” with the “n-type” in the above descriptions and accompanying drawings.

In the embodiments described above, the chip 2 including an SiC single crystal is adopted. On the other hand, the chip 2 may include a single crystal of a wide bandgap semiconductor other than the SiC single crystal. The wide bandgap semiconductor is a semiconductor having a bandgap greater than a bandgap of silicon. Examples of the single crystal of the wide bandgap semiconductor include gallium nitride, gallium oxide, and diamond. As a matter of course, the chip 2 may include a silicon single crystal.

Similarly, the first semiconductor region 6 (semiconductor layer) may include a single crystal of a wide bandgap semiconductor other than the SiC single crystal. The first semiconductor region 6 may include gallium nitride, gallium oxide, diamond, or the like. As a matter of course, the first semiconductor region 6 may include a silicon single crystal.

Similarly, the second semiconductor region 7 (semiconductor substrate) may include a single crystal of a wide bandgap semiconductor other than the SiC single crystal. The second semiconductor region 7 may include gallium nitride, gallium oxide, diamond, or the like. As a matter of course, the second semiconductor region 7 may include a silicon single crystal.

In the embodiments described above, the second semiconductor region 7 of the n-type is illustrated. On the other hand, the second semiconductor region 7 of the p-type may be adopted instead of the second semiconductor region 7 of the n-type. In this case, an insulated gate bipolar transistor (IGBT) structure is formed in place of the MISFET structure. In this case, in the above descriptions, the “source” of the MISFET structure is replaced with an “emitter” of the IGBT structure and the “drain” of the MISFET structure is replaced with a “collector” of the IGBT structure. The p-type second semiconductor region 7 may be an impurity region containing p-type impurities introduced into the surface layer portion of the second main surface 4 of the chip 2 (n-type chip 2) by an ion implantation method.

Hereinafter, examples of features extracted from this description and the attached drawings are indicated. Hereinafter, the alphanumeric characters, etc., in parentheses represent the corresponding components, etc., in the embodiments described above, but are not intended to limit the scope of each clause to the embodiments described above. The “semiconductor device” in the following clauses may be replaced with an “SiC semiconductor device,” a “wide bandgap semiconductor device,” a “semiconductor switching device,” an “MISFET device,” an “IGBT device,” or the like, as needed.
[A1] A semiconductor device (1) comprising: a chip (2) that has a main surface (3); a gate electrode (32) that is arranged on the main surface (3), includes polysilicon, and has an electrode surface (33); a silicide portion (40) that is partially formed in a surface portion of the electrode surface (33); and a polysilicon portion (41) that is formed in a portion of the surface portion of the electrode surface (33) other than the silicide portion (40).
[A2] The semiconductor device (1) according to A1, wherein the gate electrode (32) has a side wall (34, 35), the silicide portion (40) is formed at an interval inwardly from the side wall (34, 35), and the polysilicon portion (41) is exposed from the side wall (34, 35).
[A3] The semiconductor device (1) according to A2, wherein the side wall (34, 35) includes a first side wall (34) on one side and a second side wall (35) on the other side, the silicide portion (40) is formed at intervals inwardly from both of the first side wall (34) and the second side wall (35), and the polysilicon portion (41) is exposed from both of the first side wall (34) and the second side wall (35).
[A4] The semiconductor device (1) according to A3, wherein the silicide portion (40) is formed at intervals inwardly from both of the first side wall (34) and the second side wall (35) in an entire region of the surface portion of the electrode surface (33), and the polysilicon portion (41) is exposed from both of the first side wall (34) and the second side wall (35) in the entire region of the surface portion of the electrode surface (33).
[A5] The semiconductor device (1) according to any one of A1 to A4, wherein the polysilicon portion (41) forms the flat electrode surface (33) together with the silicide portion (40).
[A6] The semiconductor device (1) according to any one of A1 to A5, wherein the polysilicon portion (41) is recessed toward the main surface (3) side with respect to the silicide portion (40).
[A7] The semiconductor device (1) according to any one of A1 to A6, wherein the polysilicon portion (41) protrudes upwardly from the silicide portion (40).
[A8] The semiconductor device (1) according to any one of A1 to A7, wherein the silicide portion (40) is formed at an interval from an intermediate portion of the gate electrode (32) toward the electrode surface (33) side in a thickness direction.
[A9] The semiconductor device (1) according to any one of A1 to A8, further comprising: a gate wiring (52) that is selectively drawn onto the main surface (3) such as to be connected to the gate electrode (32), includes polysilicon, and has a wiring surface (53); a second silicide portion (60) that is formed in a surface portion of the wiring surface (53); and a second polysilicon portion (61) that is formed in a portion of the surface portion of the wiring surface (53) other than the second silicide portion (60).
[A10] The semiconductor device (1) according to A9, wherein the second silicide portion (60) is connected to the silicide portion (40) at a connection portion between the gate electrode (32) and the gate wiring (52), and the second polysilicon portion (61) is connected to the polysilicon portion (41) at the connection portion.
[A11] The semiconductor device (1) according to A9 or A10, wherein the gate wiring (52) has a wiring side wall (54, 55), the second silicide portion (60) is formed at an interval inwardly from the wiring side wall (54, 55), and the second polysilicon portion (61) is exposed from the wiring side wall (54, 55).
[A12] The semiconductor device (1) according to A11, wherein the wiring side wall (54, 55) includes a first wiring side wall (54) on one side and a second wiring side wall (55) on the other side, the second silicide portion (60) is formed at intervals inwardly from both of the first wiring side wall (54) and the second wiring side wall (55), and the second polysilicon portion (61) is exposed from both of the first wiring side wall (54) and the second wiring side wall (55).
[A13] The semiconductor device (1) according to any one of A9 to A12, wherein the gate electrode (32) extends in one direction (Y), and the gate wiring (52) has a portion extending in an intersection direction (X) intersecting the one direction (Y).
[A14] The semiconductor device (1) according to any one of A1 to A13, further comprising: an interlayer film (70) that covers the gate electrode (32) and includes a portion in contact with the silicide portion (40) and a portion in contact with the polysilicon portion (41).
[A15] The semiconductor device (1) according to A 14, wherein the interlayer film (70) includes a first oxide film (72) that includes a portion in contact with the silicide portion (40) and a portion in contact with the polysilicon portion (41) and in which impurities are not added, and a second oxide film (73) that covers the first oxide film (72) and contains phosphorus.
[A16] The semiconductor device (1) according to any one of A1 to A15, further comprising: a semiconductor region (6) that has a first conductivity type (n-type) and is formed in a surface layer portion of the main surface (3); a body region (20) that has a second conductivity type (p-type) and is formed in a surface layer portion of the semiconductor region (6); an impurity region (23, 24) that has the first conductivity type (n-type) and is formed in a surface layer portion of the body region (20); a channel (26, 27) that is formed in a region between the semiconductor region (6) and the impurity region (23, 24) in the surface layer portion of the body region (20); and an insulating film (31) that covers the channel (26, 27) on the main surface (3), wherein the gate electrode (32) opposes the channel (26, 27) across the insulating film (31).
[A17] The semiconductor device (1) according to any one of A1 to A16, wherein the chip (2) includes a wide bandgap semiconductor.
[A18] A manufacturing method for a semiconductor device (1) comprising: a step of forming a base electrode (161) including polysilicon on a wafer (150); a step of forming a metal film (165) that partially covers an electrode surface (162) of the base electrode (161); a step of partially forming a silicide portion (40) in a surface portion of the electrode surface (162) by causing the polysilicon to react with the metal film (165); a step of removing an unreacted portion of the metal film (165) from the electrode surface (162); and a step of removing the base electrode (161) in a thickness direction from a polysilicon portion (166) other than the silicide portion (40) and forming a gate electrode (32) that includes both of the silicide portion (40) and the polysilicon portion (41, 166) in the surface portion of the electrode surface (33, 162).
[A19] The manufacturing method for the semiconductor device (1) according to A18, further comprising: a step of forming a base mask (163) selectively exposing the base electrode (161) on the base electrode (161) prior to the forming step of the metal film (165), wherein the forming step of the metal film (165) includes a step of forming the metal film (165) that covers both of the base electrode (161) and the base mask (163), and the forming step of the silicide portion (40) includes a step of causing the polysilicon portion exposed from the base mask (163) to react with the metal film (165).
[A20] The manufacturing method for the semiconductor device (1) according to A18 or A19, wherein the removing step of the base electrode (161) includes a step of removing only the polysilicon portion (166).
[A21] The manufacturing method for the semiconductor device (1) according to any one of A18 to A20, wherein the removing step of the base electrode (61) includes: a step of forming a mask (167) that covers the silicide portion (40) and exposes the polysilicon portion (166) on the base electrode (161); and a step of removing the polysilicon portion (166) by an etching method through the mask (167).
[A22] The manufacturing method for the semiconductor device (1) according to any one of A18 to A21, wherein the wafer (150) includes a wide bandgap semiconductor.
[B1] A semiconductor device (1) comprising: a chip (2) that has a main surface (3); a gate electrode (32) that is arranged on the main surface (3); an interlayer film (70) that covers the gate electrode (32) and has an insulating surface (71); an opening (90) that is formed in the interlayer film (70) at a distance from the gate electrode (32) and exposes the main surface (3); an embedded electrode (101) that is embedded in the opening (90), has an electrode surface (105) exposed from the opening (90), and is electrically connected to the main surface (3); and a main electrode (102) that is mechanically and electrically connected to the electrode surface (105) of the embedded electrode (101).
[B2] The semiconductor device (1) according to B1, wherein the embedded electrode (101) is embedded in the opening (90) such as to expose the insulating surface (71), and the main electrode (102) covers both of the insulating surface (71) and the electrode surface (105).
[B3] The semiconductor device (1) according to B2, wherein the electrode surface (105) is located on the main surface (3) side with respect to the insulating surface (71), and the main electrode (102) is connected to the electrode surface (105) located on the main surface (3) side with respect to the insulating surface (71).
[B4] The semiconductor device (1) according to B3, wherein the gate electrode (32) has a gate electrode surface (33), and the electrode surface (105) is located above the gate electrode surface (33).
[B5] The semiconductor device (1) according to any one of B2 to B4, wherein the electrode surface (105) has a recess (106) toward the chip (2).
[B6] The semiconductor device (1) according to B5, wherein a bottom portion of the recess (106) is located above a height position of the gate electrode (32).
[B7] The semiconductor device (1) according to any one of B1 to B6, wherein the opening (90) has a vertically long aspect ratio (D/W) along a lamination direction.
[B8] The semiconductor device (1) according to any one of B1 to B7, wherein the embedded electrode (101) includes tungsten, and the main electrode (102) includes aluminum.
[B9] The semiconductor device (1) according to any one of B1 to B8, wherein the interlayer film (70) includes a first oxide film (72) which covers the gate electrode (32) and in which impurities are not added and a second oxide film (73) that contains phosphorus and covers the first oxide film (72), and the opening (90) penetrates both of the first oxide film (72) and the second oxide film (73).
[B10] The semiconductor device (1) according to any one of B1 to B9, further comprising: a plurality of the gate electrodes (32) that are arranged at an interval on the main surface (3), wherein the opening (90) is defined in a region between the gate electrodes (32).
[B11] The semiconductor device (1) according to any one of B1 to B10, further comprising: an underlying electrode film (100) that covers a wall surface of the opening (90) and includes a portion electrically connected to the main surface (3), wherein the embedded electrode (101) is embedded in the opening (90) across the underlying electrode film (100), and are electrically connected to the main surface (3) via the underlying electrode film (100).
[B12] The semiconductor device (1) according to B11, wherein the underlying electrode film (100) includes a portion that covers the insulating surface (71) other than the opening (90), and the main electrode (102) includes a portion that covers the insulating surface (71) across the underlying electrode film (100).
[B13] The semiconductor device (1) according to B11 or B12, further comprising: a surface layer silicide portion (108) that is formed in a surface layer portion of a portion of the main surface (3), which is exposed from the opening (90), and is mechanically and electrically connected to the underlying electrode film (100).
[B14] The semiconductor device (1) according to any one of B11 to B13, further comprising: a recess (91) that is formed in a portion of the main surface (3) exposed from the opening (90), wherein the underlying electrode film (100) includes a portion located in the recess (91).
[B15] The semiconductor device (1) according to any one of B11 to B14, wherein the underlying electrode film (100) includes at least one of a Ti film and a TiN film.
[B16] The semiconductor device (1) according to any one of B1 to B15, further comprising: a gate wiring (52) that is selectively drawn onto the main surface (3) and is connected to the gate electrode (32).
[B17] The semiconductor device (1) according to B16, further comprising: a gate opening (94) that is formed in the interlayer film (70) such as to expose the gate wiring (52); a gate embedded electrode (121) that is embedded in the gate opening (94), has a gate embedded electrode surface (125) exposed from the gate opening (94), and is electrically connected to the gate wiring (52); and a gate main electrode (122) that is mechanically and electrically connected to the gate embedded electrode surface (125) of the gate embedded electrode (121).
[B18] The semiconductor device (1) according to any one of B1 to B17, further comprising: a semiconductor region (6) that has a first conductivity type (n-type) and is formed in a surface layer portion of the main surface (3); a body region (20) that has a second conductivity type (p-type) and is formed in a surface layer portion of the semiconductor region (6); an impurity region (23, 24) that has the first conductivity type (n-type) and is formed in a surface layer portion of the body region (20); a channel (26, 27) that is formed in a region between the semiconductor region (6) and the impurity region (23, 24) in the surface layer portion of the body region (20); and an insulating film (31) that covers the channel (26, 27) on the main surface (3), wherein the gate electrode (32) opposes the channel (26, 27) across the insulating film (31), the opening (90) exposes the impurity region (23, 24), and the embedded electrode (101) is electrically connected to the impurity region (23, 24) in the opening (90).
[B19] The semiconductor device (1) according to B18, further comprising: a second impurity region (25) that has the second conductivity type (p-type) and is formed in a region different from the impurity region (23, 24) in the surface layer portion of the body region (20), wherein the opening (90) exposes the second impurity region (25), and the embedded electrode (101) is electrically connected to the second impurity region (25) in the opening (90).
[B20] The semiconductor device (1) according to any one of B1 to B19, further comprising: a silicide portion (40) that is partially formed in a surface portion of the gate electrode (32); and a polysilicon portion (41) that is formed in a portion other than the silicide portion (40) in the surface portion of the gate electrode (32).
[B21] The semiconductor device (1) according to any one of B1 to B20, wherein the chip (2) includes a wide bandgap semiconductor.
[B22] A manufacturing method for a semiconductor device (1) comprising: a step of forming a gate electrode (32) on a wafer (150); a step of forming an interlayer film (70) that covers the gate electrode (32) on the wafer (150); a step of forming an opening (90) that exposes the wafer (150) at a position separated from the gate electrode (32) in the interlayer film (70); a step of embedding an electrode (178) in the opening (90) such as to be electrically connected to the wafer (150) and forming an embedded electrode (101) that is exposed from the opening (90) and has an electrode surface (105); and a step of forming a main electrode (102) that directly covers the electrode surface (105) of the embedded electrode (101).
[B23] The manufacturing method for the semiconductor device (1) according to B22, wherein the wafer (150) includes a wide bandgap semiconductor.

The configurations according to [A1] to [A22] and the configurations according to [B1] to [B23] can be appropriately combined therebetween. While specific embodiments have been described in detail above, these are merely specific examples used to clarify the technical contents. The various technical ideas extracted from this description can be combined as appropriate with each other without being limited by the order of description, the order of configuration examples, the order of modification examples, etc., in this description.

What is claimed is:

1. A semiconductor device comprising:
a chip that includes SiC and has a main surface;
a gate electrode that is arranged on the main surface, includes polysilicon, and has an electrode surface;
a silicide portion that is partially formed in a surface portion of the electrode surface; and
a polysilicon portion that is formed in a portion of the surface portion of the electrode surface other than the silicide portion.

2. The semiconductor device according to claim 1,
wherein the gate electrode has a side wall,
the silicide portion is formed at an interval inwardly from the side wall, and
the polysilicon portion is exposed from the side wall.

3. The semiconductor device according to claim 2,
wherein the side wall includes a first side wall on one side and a second side wall on the other side,
the silicide portion is formed at intervals inwardly from both of the first side wall and the second side wall, and
the polysilicon portion is exposed from both of the first side wall and the second side wall.

4. The semiconductor device according to claim 3,
wherein the silicide portion is formed at intervals inwardly from both of the first side wall and the second side wall in an entire region of the surface portion of the electrode surface, and
the polysilicon portion is exposed from both of the first side wall and the second side wall in the entire region of the surface portion of the electrode surface.

5. The semiconductor device according to claim 1,
wherein the polysilicon portion forms the flat electrode surface together with the silicide portion.

6. The semiconductor device according to claim 1,
wherein the polysilicon portion is recessed toward the main surface side with respect to the silicide portion.

7. The semiconductor device according to claim 1,
wherein the polysilicon portion protrudes upwardly from the silicide portion.

8. The semiconductor device according to claim 1,
wherein the silicide portion is formed at an interval from an intermediate portion of the gate electrode toward the electrode surface side in a thickness direction.

9. The semiconductor device according to claim 1, further comprising:
a gate wiring that is selectively drawn onto the main surface such as to be connected to the gate electrode, includes polysilicon, and has a wiring surface;
a second silicide portion that is formed in a surface portion of the wiring surface; and
a second polysilicon portion that is formed in a portion of the surface portion of the wiring surface other than the second silicide portion.

10. The semiconductor device according to claim 9,
wherein the second silicide portion is connected to the silicide portion at a connection portion between the gate electrode and the gate wiring, and
the second polysilicon portion is connected to the polysilicon portion at the connection portion.

11. The semiconductor device according to claim 9,
wherein the gate wiring has a wiring side wall,
the second silicide portion is formed at an interval inwardly from the wiring side wall, and
the second polysilicon portion is exposed from the wiring side wall.

12. The semiconductor device according to claim 11,
wherein the wiring side wall includes a first wiring side wall on one side and a second wiring side wall on the other side,
the second silicide portion is formed at intervals inwardly from both of the first wiring side wall and the second wiring side wall, and
the second polysilicon portion is exposed from both of the first wiring side wall and the second wiring side wall.

13. The semiconductor device according to claim 9,
wherein the gate electrode extends in one direction, and
the gate wiring includes a portion extending in an intersection direction intersecting the one direction.

14. The semiconductor device according to claim 1, further comprising:
an interlayer film that covers the gate electrode and includes a portion in contact with the silicide portion and a portion in contact with the polysilicon portion.

15. The semiconductor device according to claim 14,
wherein the interlayer film includes a first oxide film that includes a portion in contact with the silicide portion and a portion in contact with the polysilicon portion and in which impurities are not added, and a second oxide film that covers the first oxide film and contains phosphorus.

16. The semiconductor device according to claim 1, further comprising:
a semiconductor region that has a first conductivity type and is formed in a surface layer portion of the main surface;
a body region that has a second conductivity type and is formed in a surface layer portion of the semiconductor region;
an impurity region that has the first conductivity type and is formed in a surface layer portion of the body region;
a channel that is formed in a region between the semiconductor region and the impurity region in the surface layer portion of the body region; and
an insulating film that covers the channel on the main surface,
wherein the gate electrode opposes the channel across the insulating film.

17. A manufacturing method for a semiconductor device comprising:
a step of forming a base electrode including polysilicon on a wafer including SiC;
a step of forming a metal film that partially covers an electrode surface of the base electrode;
a step of partially forming a silicide portion in a surface portion of the electrode surface by causing the polysilicon to react with the metal film;
a step of removing an unreacted portion of the metal film from the electrode surface; and
a step of removing the base electrode in a thickness direction from a polysilicon portion other than the silicide portion and forming a gate electrode that includes both of the silicide portion and the polysilicon portion in the surface portion of the electrode surface.

18. The manufacturing method for the semiconductor device according to claim 17, further comprising:
a step of forming a base mask selectively exposing the base electrode on the base electrode prior to the forming step of the metal film,
wherein the forming step of the metal film includes a step of forming the metal film that covers both of the base electrode and the base mask, and
the forming step of the silicide portion includes a step of causing the polysilicon portion exposed from the base mask to react with the metal film.

19. The manufacturing method for the semiconductor device according to claim 17,
wherein the removing step of the base electrode includes a step of removing only the polysilicon portion.

20. The manufacturing method for the semiconductor device according to claim 17,
wherein the removing step of the base electrode includes:
a step of forming a mask that covers the silicide portion and exposes the polysilicon portion on the base electrode; and
a step of removing the polysilicon portion by an etching method through the mask.
